(19) United States
(12) Patent Application Publication
(10) Pub. No.: US 2024/0290898 A1
(43) Pub. Date: Aug. 29, 2024

(54) Adjustable Electromagnetic Energy Converter

(71) Applicant: THE REGENTS OF THE UNIVERSITY OF MICHIGAN, Ann Arbor, MI (US)

(72) Inventor: Mojtaba AKHAVAN-TAFTI, Ann Arbor, MI (US)

(21) Appl. No.: 18/439,628

(22) Filed: Feb. 12, 2024

Related U.S. Application Data
(63) Continuation of application No. 16/677,912, filed on Nov. 8, 2019, now Pat. No. 11,935,978.
Application No. 16/677,912 is a continuation-in-part of application No. PCT/US2018/049880, filed on Sep. 7, 2018.
(63) Continuation-in-part of application No. 17/408,925, filed on Aug. 23, 2021.
(63) Continuation-in-part of application No. 17/672,813, filed on Feb. 16, 2022, now abandoned.
(60) Provisional application No. 62/555,686, filed on Sep. 8, 2017.
(60) Provisional application No. 63/069,261, filed on Aug. 24, 2020.
(60) Provisional application No. 63/150,362, filed on Feb. 17, 2021.

(51) Int. Cl. H01L 31/048; H01L 31/0216; H01L 31/05; H01L 31/054; H01L 31/055; H02S 10/40; H02S 20/30; H02S 40/22; H02S 40/42

(52) U.S. Cl. CPC H01L 31/048; H01L 31/0216; H01L 31/0504; H01L 31/0543; H01L 31/0547; H01L 31/055; H02S 10/40; H02S 20/30; H02S 40/22; H02S 40/42; H02S 40/425

(57) ABSTRACT

An adjustable electromagnetic energy converter comprises a body of transparent insulating material, a plurality of stacked identical electromagnetic energy converting cells, and a heat transfer system. Methods are herein provided for determining a configuration to which to adjust the converter and optimizing its performance. The methods comprise first determining electrical outputs of a first and a second configuration of the converter, comparing the electrical outputs, and determining whether to adjust the converter from the first configuration to the second configuration. To optimize the performance of the converter, the following configuration characteristics can be adjusted: electromagnetic energy collection area or orientation of the body of transparent insulating material, angle between adjacent cells, angle between the cells relative to the incoming electromagnetic energy, or spacing between adjacent cells.

### CROSS-REFERENCE TO RELATED APPLICATIONS

This application is a continuation-in-part of U.S. application Ser. No. 16/677,912, filed Nov. 8, 2019, which is a continuation-in-part of International Application No. PCT/US2018/049880, filed on Sep. 7, 2018, which claims the benefit of U.S. Provisional Application No. 62/555,686, filed Sep. 8, 2017.

This application is also a continuation-in-part of U.S. application Ser. No. 17/408,925, filed Aug. 23, 2021, which claims the benefit of U.S. Provisional Application No. 63/069,261, filed Aug. 24, 2020.

This application is also a continuation-in-part of U.S. patent application Ser. No. 17/672,813 filed on Feb. 16, 2022, which claims the benefit of U.S. Provisional Application No. 63/150,362, filed on Feb. 17, 2021.

The entire disclosure of the above applications is incorporated herein by reference.

### FIELD

The present disclosure relates to a device and method to improve energy conversion to power mobile or stationary devices.

### BACKGROUND AND SUMMARY

This section provides background information related to the present disclosure which is not necessarily prior art. This section also provides a general summary of the disclosure, and is not a comprehensive disclosure of its full scope or all of its features.

Photovoltaic solar panels are commonly used for conversion of light energy into electricity for mobile objects may it be ground-based or air/space-based. Electromagnetic (EM) energy is widely used for powering and propelling satellites (i.e. solar sail).

With electronic circuits shrinking, energy delivery and storage are becoming more challenging. Laser communication/power delivery has been proposed as a way to create more compact and, in the case of the present teachings, 3D structures. Current solutions include monochromatic laser-illuminated flat cells, which provide lower power density output than that provided in accordance with the principles of the present teachings.

Laser power beaming uses a laser to deliver concentrated light to a remote receiver. The receiver then converts the light to electricity, much like solar powered photovoltaic (PV) cells convert sunlight into electricity.

Key differences between laser and solar illuminations are i) laser can be much more intense than the sun, ii) laser light can be directed to any place using adaptive optics, iii) laser can operate continuously and/or controlled pulses, and iv) photovoltaics can be optimized to operate with monochromatic laser emission.

Power beaming technologies receive energy from a transmitter. The transmitter power is supplied from an electrical outlet, generator, a light concentrator, and/or a power storage unit (e.g., batteries and fuel cells). The wavelength and the shape of the beam are defined by a set of optics. This light then propagates through air, the vacuum of space, and/or through fiber optic cable until it reaches the receiver. The receiver then converts the light back into electricity/heat/etc.

Wireless power delivery requires physical installations at only the transmitting and receiving points, therefore, lowering the cost while enhancing the reliability of the system. Consequently, laser power beaming has numerous advantages over solar power.

In some embodiments, the present teachings provide a device that is more efficient (power per surface area), less expensive, compact, lightweight, portable, advanced (uses the state-of-the-art technologies to increase efficiency, lower the size and weight of machines by replacing traditional energy storage/delivery by wireless compact devices), etc. than traditional converters.

Previous proposed devices and methods have addressed the technologies, materials, and fabrication processes and the cost analysis needed to achieve wireless energy delivery; however, electromagnetic energy converter and method of the present teachings aim to assemble together the existing, well-researched building blocks to enable a more affordable, more efficient and sustainable solution to the energy conversion/harvest problem.

The present teachings also provide methods for fabricating multi-dimensional solar structures that can be easily manufactured using off-the-shelf solar cells and cheap casting materials such as epoxy resin. The resulting solar structures are found to generate several times the power output of conventional solar panels per occupied surface area. The ease of manufacturing and compact nature of these structures make them particularly attractive for urban settings where available surface areas to mount large solar structures are limited and, therefore, expensive. We also find that the weight and the aerodynamics of these multi-dimensional solar structures can be modified for transportation applications. Presently, bulky conventional solar panels are rarely used aboard mobile vehicles.

Further areas of applicability will become apparent from the description provided herein. The description and specific examples in this summary are intended for purposes of illustration only and are not intended to limit the scope of the present disclosure.

### BRIEF DESCRIPTION OF DRAWINGS

The drawings described herein are for illustrative purposes only of selected embodiments and not all possible implementations, and are not intended to limit the scope of the present disclosure.

FIG. 1 illustrates a perspective view of an enclosed electromagnetic (EM) energy converter according to the principles of the present teachings.

FIG. 2 is a schematic view illustrating the principles of operation of the present teachings.

FIG. 3 illustrates a perspective view of an open-face electromagnetic (EM) energy converter according to the principles of the present teachings having a liquid or solid converter.

FIG. 4 illustrates a perspective view of an electromagnetic (EM) energy converter according to the principles of the present teachings having a matrix of electric poles that conducts converted EM energy.

FIG. 5 illustrates a perspective view of the electromagnetic (EM) energy converter of FIG. 4.

FIG. 6 illustrates a perspective view of a pair of electromagnetic (EM) energy converters coupled in series according to the principles of the present teachings.

FIG. 7A illustrates a perspective view of a plurality of electromagnetic (EM) energy converter coupled in parallel according to the principles of the present teachings.

FIG. 7B illustrates a perspective view of an electromagnetic (EM) energy converter mounted around a fiber optic transmitting EM energy and information.

FIG. 8 illustrates a perspective view of an electromagnetic (EM) energy converter mounted to an EM receiver dish according to the principles of the present teachings.

FIG. 9 illustrates a second perspective view of the electromagnetic (EM) energy converter of FIG. 8 mounted to the EM receiver dish according to the principles of the present teachings.

FIG. 10 illustrates a perspective view of an electromagnetic (EM) energy converter mounted to an EM receiver dish according to the principles of the present teachings.

FIG. 11 illustrates a second perspective view of the electromagnetic (EM) energy converter of FIG. 10 mounted to the EM receiver dish according to the principles of the present teachings.

FIG. 12 illustrates a perspective view of an electromagnetic (EM) energy converter having a roll-able construction according to the principles of the present teachings.

FIG. 13 illustrates a perspective view of the electromagnetic (EM) energy converter of FIG. 12 having a roll-able construction according to the principles of the present teachings.

FIG. 14 illustrates a perspective view of an adjustable electromagnetic (EM) energy converter according to the principles of the present teachings.

FIG. 15 illustrates a perspective view of the adjustable electromagnetic (EM) energy converter of FIG. 14 according to the principles of the present teachings.

FIG. 16 illustrates a perspective view of an electromagnetic (EM) energy converter mounted to an unmanned aerial vehicle (UAV) according to the principles of the present teachings.

FIG. 17 illustrates a perspective view of an electromagnetic (EM) energy converter of FIG. 16 mounted to an unmanned aerial vehicle (UAV) according to the principles of the present teachings.

FIG. 18 illustrates a perspective view of an electromagnetic (EM) energy converter and the principles of operation of the present teachings.

FIG. 19A is an NREL PV system cost benchmark summary (inflation adjusted), 2010-2018.

FIG. 19B is a modeled trend of soft cost as a proportion of total cost by sector, 2010-2018.

FIG. 20 is the circuit diagram for Experiment 1. The solar cell is represented by a diode and two voltmeters measure across the resistor in parallel. The two voltmeters represent that Ni USB 6009 and a handheld digital voltmeter.

FIG. 21 shows the manual output measurements graphed as voltages vs. power. The power was calculated using the equation P=V2/R. This power equation was used because the automatic system could not measure current at the time.

FIG. 22 shows the automatic output measurements graphed as voltage vs. power.

FIG. 23 is the circuit diagram for Experiment 2.

FIG. 24 is the solar panel behavior and various light intensities.

FIG. 25 is the maximum power point analysis for various light intensities. The points on the graph were created by multiplying the current and voltage ordered pair to get power and then graphed against voltage.

FIG. 26 is a cell holder with a PV cell with a diffuser over the cell.

FIG. 27 is Voltage vs. Power Output colored by degrees away from normal light.

FIG. 28 shows Power Output by degrees from normal light. This test was with no diffuser to determine how power changes by changing angle.

FIG. 29 shows Power Output by degrees from normal light. This test was with a 42.8% transparent diffuser to see how changing the power is affected by transparency of the diffuser. This is the diffuser with the lowest transparency that was tested.

FIG. 30 shows the characteristic curves of different colored LEDs on a PV cell at 425 (×100 lux).

FIG. 31 shows maximum power point analysis for various light sources. The points on the graph were created by multiplying the current and voltage ordered pair to get power and then graphed against voltage.

FIG. 32A provides a schematic for three parameters: layers' angles from incoming electromagnetic radiation θ, layers' relative angle α, and layers' relative distance D. The layers A and B are selected from a list consisting at least of photovoltaic cells and optical layers such as mirrors.

FIG. 32B is the setup for the plural PV cell tests.

FIG. 33 shows voltage vs. power for one and two PV cells.

FIG. 34 is the power per surface area exposed to the LED for one PV cell in the dual PV setup. The power per surface area is for each cell.

FIG. 35 shows power per surface area exposed to the LED for one PV cell divided by the power per surface area of a single, flat PV cell.

FIG. 36 shows the zenith angle vs. power for the two PV cell setup. This test had no reflective material over any of the cells. The points are colored blue if the ratio of 2 cell power over 1 cell power is greater than 2 and red if it is less than 2.

FIG. 37 shows the zenith angle vs. power for the two PV cell setup. Each power per area measurement is of a single cell in the two cell setup. The points are colored blue if the performance of a single cell in the two cell test is greater than the performance if the single cell test.

FIG. 38 is the setup of the resin tests. The power is measured across both PV cells for each test.

FIG. 39 shows the normalized power per area for a flat, single cell in the resin cell setup. This test has no resin in the container.

FIG. 40 shows the normalized power per area for a flat, single cell in the resin cell in the resin cell setup with foil. This test has no resin in the container and the container in covered in reflective aluminum foil.

FIG. 41 is the normalized power per area (PPA) for 1000 mL Clear Resin.

FIG. 42 is the normalized power per area (PPA) for 1000 mL Clear Resin and foil.

FIG. 43 shows the normalized output power of the three tests added together, i.e., cumulative power per area (PPA).

FIG. 44 shows the individual normalized output power percent for each layer in the resin bath at 60 degrees. The line shows the cumulative sum of power for all three layers, i.e., cumulative power per area (PPA).

FIG. 45 shows a schematic of three layers (Layer A, B, and C) selected from a list of PV cells, dielectric material, and reflective material. The layers can be separated by a spacing d to allow for the propagation of electromagnetic energy between layers. The layers are disposed in a medium. In some embodiments, the internal surface of the EMEC is coated by a reflective material.

FIG. 46 shows a schematic view of an EMEC wherein the transparent body is a dispersive material whose diffusivity varies distally along the structure. The diffusivity gradient can be adjusted to insure that the PV cells, denoted as Layer A and Layer B, generate similar power output. Similar output cells can be connected in parallel or in series for reduced power waste and reduced cost of electronics to harvest the cells.

FIG. 47 provides a schematic view of two layers, PV cell, reflective sheet, etc. stacked in a transparent body of diffusive material, the layers labelled Layer A and Layer B. Spacers and/or fillers, shown as starts, can serve three immediate purposes: 1) to fill the medium to reduce the amount of diffusive material needed to reduce weight and/or cost, 2) to use as spacers such that they hold the layers at a constant distance from each other, and 3) to serve as diffusive and/or reflective surfaces. The spacers can be rods, sheets, or particles. They can be composed of dielectric or conductive materials.

FIG. 48 shows a schematic consisting of three PV layers, Layer A, B, and C. The layers are disposed in a transparent medium. The housing encasing the layers and the medium, labelled as External Layer, is either reflective to trap the electromagnetic energy inside the EMEC until it is converted and/or a diffusive layer to disperse the incoming electromagnetic energy for a diffused radiation and to avoid shading across the EMEC. In the case of reflective external layer, the reflectors can be a combination of surfaces, as shown with black triangles positioned from the layers at distance a, to control the propagation of electromagnetic radiation inside the EMEC. The Layers A and B are separated and/or filled with a layer, shown in grey shading, with a layer of thickness d whose distal cross section is at an angle with the propagating electromagnetic radiation. The layer serves to bring the radiation into the void between Layers A and B until it is converted.

FIG. 49 shows a schematic consisting of three PV layers, Layer A, B, and C. An optical surface, i.e., a semi-reflective mirror, a lens, or a wave guide, is positioned at angle with respect to the propagating electromagnetic radiation. The optical surface deflects a fraction of the incoming electromagnetic radiation toward the space between PV cells Layer A and Layer B to convert to electricity. The remaining fraction of the electromagnetic radiation propagates through the optical surface. The optical surface can be processed after the EMEC production, such as bubblegram methods.

FIG. 50 shows a schematic consisting of four layers, shown as white rectangles, separated by diffusive layers, shown as grey shaded rectangles. The diffusive layers serve to also guide the incoming electromagnetic radiation toward in between the white layers.

FIG. 51 shows a schematic consisting of three layers, Layer A is a PV cell, Layer B is a reflective surface, and Layer C is a PV cell. In some embodiments, Layers A and C are transparent and/or diffusive photovoltaics. The gradient grey material illustrates a body of, in this case, 5 layers of transparent diffusive material of different refractive indices to guide the incoming electromagnetic radiation, as shown with bending arrows, toward the spacing between the Layers A and B. Individual layers can be addressed using a matrix of wave guides that direct the incoming electromagnetic radiation independently. In some embodiments, the different wave guides are fiber optics, while in other embodiments, the wave guides are covered with reflective material to avoid cross-propagation. In some embodiments, the transparent material layer is an Indium tin oxide (ITO) coated glass, where the glass serves to guide and/or diffuse light, while the conductive material, in this case ITO, serves to conduct electricity and/or heat.

FIG. 52 shows a schematic consisting of three PV layers, Layer A, B, and C disposed fully in a transparent body of material, labelled as ‘Medium’. The medium is circulated inside the EMEC and is extracted to cool and/or heat in a heat transfer system, depicted as a coil encased in a radiating array to conduct heat between the medium and the ambient environment. The heat transfer system may be packaged with the EMEC or coupled as an independent device. In some embodiments, the EMEC structure floats above water while the water is further used to cool the system. In some embodiments, the temperature regulation is done using a geothermal method.

FIG. 53 shows a schematic consisting of four PV layers, Layer A and and C disposed fully in a transparent body of material, labelled as ‘Medium’. Layers A and C are positioned back to back. Between the two layers, there exists a layer, Labelled as Layer B, such as a pipe, a sheet or a heat coil. Layers B are filled with heat transferring liquid and/or pressurized vapor, shown in solid grey. The purpose of these layers is to transfer the heat associated with the energy conversion process and/or to regulate the temperature of Layers A and C for optimum performance efficiency. In some embodiments, the heat transfer is active and is done with the help of a pump, motor, and/or an air compressor, as shown with the grey circle.

FIG. 54 shows a schematic view of an example application of the EMEC. The UAV carries an onboard EMEC, consists of a plurality of PV cells disposed in a diffusive, transparent body of insulating material. In some embodiments, the EMEC is enclosed within a reflective housing which further encloses the onboard power storage and control systems. The EMEC is, in some embodiments, power by the solar radiation from above where the dome-like lens serves to concentrates the incoming light and to enhance the angle at which the light comes in, in this case, spanning ˜90 degree from the UAV's axis of symmetry. In some other embodiments, the UAV can be further powered by a concentrated source of electromagnetic radiation from below, such as monochromatic laser light, concentrated solar radiation, or medium-cross section (e.g., 5-inch) polychromatic light beam, such as a focused flash light.

FIG. 55 shows a schematic view of an example application of the EMEC. The compact EMEC which consists of a plurality of PV cells disposed in a diffusive, transparent body of insulating material is installed on an orchard between plants. The co-habitability enables saving on the soft costs associated with dedicating large pieces of land, i.e., real estate, to conventional solar panels, solely.

FIG. 56 shows a schematic view of an example application of the EMEC. The compact EMEC which consists of a plurality of PV cells disposed in a diffusive, transparent body of insulating material is installed beneath the farming grounds and/or in an apartment basement in an urban setting. In some embodiments, the EMEC medium extends above ground to collect light. In other embodiments, a wave guide is used to collect and bring in light from above the ground and/or an apartment rooftop. The EMEC structures may also contain power storage and control systems onboard or can be connected to other neighboring EMEC structures and to a local power grid. In some embodiments, the wave guide can also serve as a shade for plants or a greenhouse. In some embodiments, the EMEC structure is under water which can further help with cooling the structure. In some embodiments, the heat transfer is radiative, such as in space applications.

FIG. 57 shows a schematic view of an example application of the EMEC. The compact EMEC which consists of a plurality of PV cells disposed in a diffusive, transparent body of insulating material is installed above a light post. The EMEC converts ambient light, such as solar radiation in an outdoor setting, into electricity. The electricity can be stored by charging onboard power storage and control systems. The converted light can also be used to power an onboard lighting system. In some embodiments, the plurality of PV cells are oriented at similar angles from each other, such as the configuration shown in the drawing. In some other embodiments, the PV cells are positioned such that the opening cross section is identical between cells to insure that all cells receive the same amount of light and, therefore, generate similar power outputs. This will allow for simple electrical circuits and help to reduce manufacturing and maintenance costs.

FIG. 58 shows a schematic view of an example application of the EMEC. The EMEC structures are independent devices. Multiple independent EMEC devices can be connected such that an incoming electromagnetic radiation is shared between devices. In some embodiments, the transparent medium of the EMEC devices are in contact such that they enable the propagation of the electromagnetic radiation between EMEC devices. In some embodiments, the light propagation is improved by the application of a junction material with refractive properties that optimize the crossing of the electromagnetic radiation between different media. In some embodiments, the junction/connection between EMEC devices is made by wave guides, such as fiber optics.

FIG. 59 is a normalized power drop as the angle from normal is increased for the polycarbonate film and acrylic diffusers. This table is for 425 lux and shows how the total power of the system drops at different rates for different diffusers—425 was chosen as a baseline as it is a median value. The standard deviation of the 100% transparency test is 1.017.

FIG. 60 is a normalized power drop as the angle from normal is increased for the polycarbonate diffusers.

FIG. 61 shows normalized power drop relative to no diffuser on the PV cell as the angle from normal is increased for the polycarbonate film and acrylic diffusers. This table is for 425 lux and shows how the total power of the system is influenced by the use of each diffuser. 425 was chosen as a baseline as it is a median value.

FIG. 62 shows normalized power drop relative to no diffuser on the PV cell as the angle from normal is increased for the polycarbonate diffusers.

FIG. 63 shows a normalized power drop as the angle from normal is increased for different LED colors.

FIG. 64 and FIG. 65 together show a normalized power drop as the angle from normal is increased for different LED colors.

FIG. 66 and FIG. 67 together show a normalized power drop to a cell with no diffuser as the angle from normal is increased for different LED colors.

FIG. 68 and FIG. 69 together show a normalized power drop to a cell with no diffuser as the angle from normal is increased for different LED colors.

FIG. 70 is the power ratio between two and one cell setups. The green cells are where 2 cell power (P2) over 1 cell power (P1) is greater than 2. Red cells are where P2/P1 is less than 1.

FIG. 71 is a single PV cell in the dual PV configuration with a reflective surface over the other holder.

FIG. 72 is the power ratio between one cell with a reflective surface and one cell setup.

FIG. 73 is the power ratio between two cells with a reflective surface on one cell and two cells with no reflective surfaces.

FIG. 74 is the power ratio between two cells with a reflective surface on one cell and two cells with no reflective surfaces.

FIG. 75 is a plural-colored test for 1-Cell Normalized Green LED Test for the single cell measurement divided by the white LED's power output for each cell in the table.

FIG. 76 is a plural-colored test for 1-Cell Normalized Blue LED Test for the single cell measurement divided by the white LED's power output for each cell in the table.

FIG. 77 is a plural-colored test for 2-Cell Normalized Green LED Test measuring across a single cell normalized to white LED tests under the same conditions as FIG. 75 and FIG. 76.

FIG. 78 is a plural-colored test for 2-Cell Normalized Blue LED Test measuring across a single cell normalized to white LED tests under the same conditions as FIG. 75 and FIG. 76.

FIG. 79 is a plural-colored test made by taking the values from Table 16 FIG. 77 over the values from FIG. 75.

FIG. 80 is a plural-colored test made by taking the values from Table 17 FIG. 78 over the values from FIG. 76.

FIG. 81 illustrates an adjustable electromagnetic energy converter. The heat transfer system 31 can be passive, including radiative heating sink, desiccant, or vent.

FIG. 82 illustrates an adjustable electromagnetic energy converter. The converter can have one or a plurality of degrees of freedom, including rotational and translational.

FIG. 83 illustrates an adjustable electromagnetic energy converter. The converter can be adjusted by being rotated or moved around.

FIG. 84 illustrates an adjustable electromagnetic energy converter. Spacing between the plurality of cells can be adjusted. The plurality of cells can further collapse into a storable housing. It also illustrates a collapsible electromagnetic energy converter.

FIG. 85 illustrates an adjustable electromagnetic energy converter. The body of transparent housing is encased with in a lattice structure for support.

FIG. 86 illustrates an adjustable electromagnetic energy converter. The plurality of cells is mounted on an extensible rods and nodes scissor structure. Spacing between and angle of the plurality of cells can be adjusted.

FIG. 87 illustrates an adjustable electromagnetic energy converter. Angle of the plurality of cells can be adjusted.

FIG. 88 illustrates a method for determining a configuration to which to adjust an electromagnetic energy converter.

FIG. 89 illustrates a method for optimizing converting electromagnetic energy to electricity of an electromagnetic energy converter.

FIG. 90 illustrates an adjustable electromagnetic energy converter. The converter further comprising an adjustable layer. The adjustable layer is placed outside the body of transparent material.

FIG. 91 illustrates an adjustable electromagnetic energy converter. The converter further comprising an adjustable layer. The adjustable layer is placed inside the body of transparent material.

FIG. 92 illustrates a method for optimizing converting electromagnetic energy to electricity of an electromagnetic energy converter. The adjustable electromagnetic energy converter further comprises an adjustable layer.

FIG. 93 illustrates a three-dimensional electromagnetic energy converter. The converter further comprising a plurality of reflective layer. The heat transfer system 31 can be active, including heat circulation and fan.

FIG. 94 illustrates a modular electromagnetic energy converter.

FIG. 95 illustrates a retrofit, modular electromagnetic energy converter.

FIG. 96 illustrates a hybrid, retrofit, modular electromagnetic energy converter. A hybrid converter is further coupled with the electric grid. A hybrid converter can be utilized as an auxiliary power unit.

FIG. 97 illustrates a collapsible electromagnetic energy converter.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of electromagnetic energy converter 14 in use or operation in addition to the orientation depicted in the figures. For example, if electromagnetic energy converter 14 in the figures is turned over, elements described as “below” or “beneath” other elements or features would then be oriented “above” the other elements or features. Thus, the example term “below” can encompass both an orientation of above and below. Electromagnetic energy converter 14 may be otherwise oriented (rotated 90 degrees or at other orientations) and the spatially relative descriptors used herein interpreted accordingly.

Various projects have investigated in depth the applications of wireless energy conversion/harvest technology. The present teachings address the unmet need for converting wave/particle energy of varying intensities to power electronic/thermal/mechanical devices without the need for physical connections (e.g., wires).

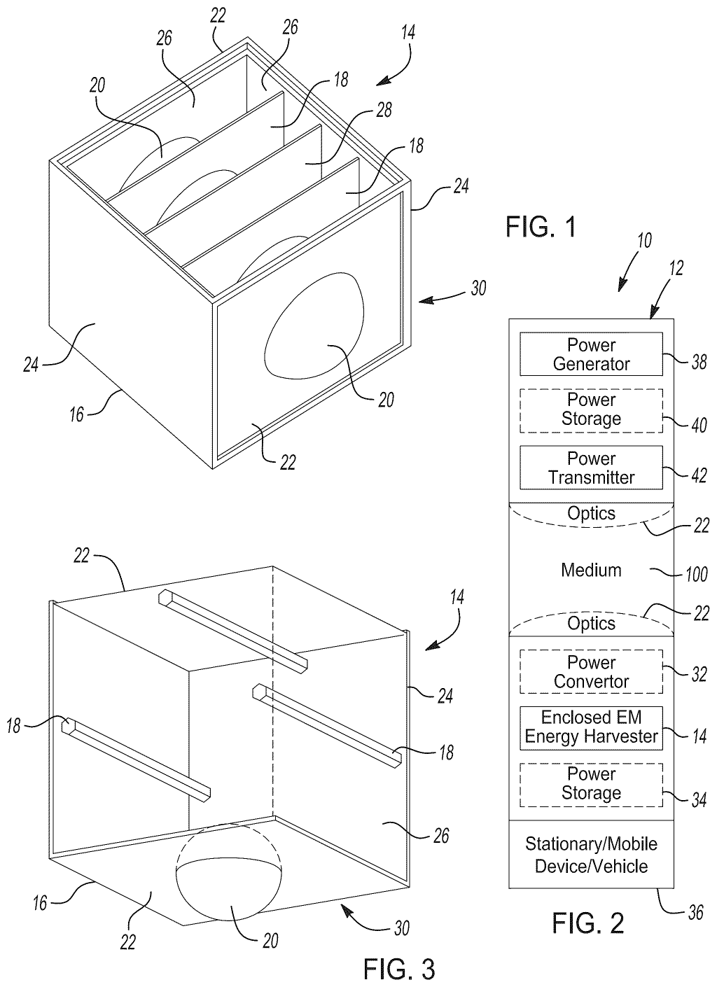

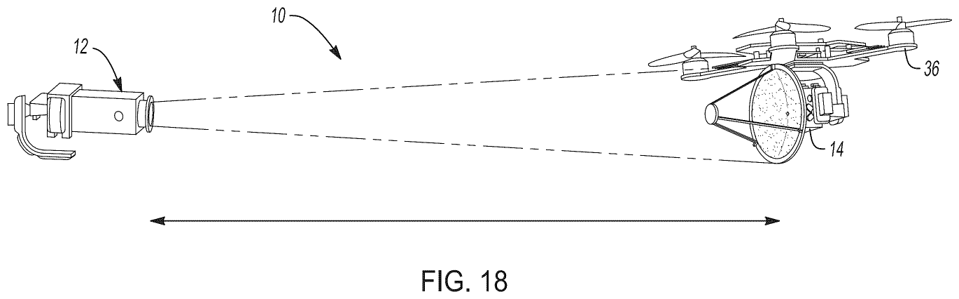

With particular reference to FIGS. 1-18, in some embodiments, the present teachings provide an electromagnetic energy converter system 10 (see FIGS. 2 and 18) having an energy source 12 and an electromagnetic (EM) energy converter 14 to convert mono and/or polychromatic wave and/or particle energy from energy source 12 to electricity and/or heat in electromagnetic energy converter 14. In particular, the present teachings incorporate a third dimension to traditional energy conversion devices to increase conversion efficiency (i.e. watts per square meter).

In some embodiments, energy source 12 can comprise high-power lasers, particle accelerometers, or other synthetic electromagnetic energy sources radiating waves such as but not limited to radio waves, microwaves, infrared emission, visible emission, ultraviolet emission, X-rays, and Gamma rays to illuminate electromagnetic energy converter 14. In some embodiments, energy source 12 can be a naturally-occurring source, such as but not limited to the sun, luminescence, thermal radiation, plasma radiation, radioactive radiation, and vibration. Moreover, energy source 12, in some embodiments, is ground-based, air-based, and/or space-based. The electromagnetic energy used in the present teachings can be of various waveforms including but not limited to short pulses, sine waves, modified sine waves, square waves, and arbitrary waves. The electromagnetic energy used in the present teachings is also selected from a list of monochromatic, polychromatic, polar, non-polar, coherent, non-coherent, collimated, and divergent waveforms.

In some embodiments, electromagnetic energy converter 14 comprises an enclosure case or housing 16 having one or more cells 18 (e.g., a photovoltaic cell, a thermophotovoltaic cell, a thermionic converter, a thermoelectric converter, a piezoelectric converter, an electrochemical converter, or a bio-electrochemical converter) disposed at least partially within housing 16. In some embodiments, cells 18 can comprise, but not limited to, inorganic cells, organic cells, amorphous cells, polycrystalline cells, monocrystalline cells, organic light emitting diodes (OLEDs), quantum dots, perovskite cells, thermophotovoltaic cells and the like. In some embodiments, cells 18 are comprised of materials in gas, liquid, or solid phases or a combination thereof. In some embodiments, cells 18 are in the form of films, slabs, sheets, rods, particles, solution, mixture or the like. These substances are used to convert (monochromatic and polychromatic) EM energy to electricity. It should be understood that electromagnetic energy converter 14 can comprise a plurality of cells 18 being of different types or of similar types with different bandwidths or operational and physical characteristics.

In some embodiments, electromagnetic energy converter 14 can comprise one or more lenses or optical inputs 20 for receiving and manipulating mono and/or polychromatic wave and/or particle energy from energy source 12. In some embodiments, housing 16 can be substantially rectangular shaped having opposing end faces 22 and side faces 24. In some embodiments, one or both end faces 22 can include one or more lenses 20. It should be understood that lenses or optical inputs 20 are optional in some embodiments and thus wave and/or particles can be introduced in alternative ways, such as but not limited to through holes, or non-transforming mediums (such as non-optical material).

In some embodiments, electromagnetic energy converter 14 can comprise a plurality of internal layers or materials 26 disposed along one or more (e.g. all) internal surfaces of housing 16 to direct or manipulate the wave or particle energy within the housing 16 to enhance contact with cells 18. In other words, in some embodiments, electromagnetic energy converter 14 can comprise an internal layer 26 disposed on an interior facing surface of one or more of end faces 22 and side faces 24. In some embodiments, internal layer 26 is a diffusive and/or dispersive and/or luminescent medium. For example, in some embodiments, internal layer 26 can comprise a diffusive material/composite, such as but not limited to polymers including acrylic resin, polycarbonate, and polymethyl methacrylate, curable polymers, casting polymers, and reinforced polymers. In some embodiments, internal layer 26 can comprise a dispersive medium, preferably a transparent matrix into which a dispersing material is placed. Each dispersing medium has distinct dispersive powers and is comprised of dispersive material such as but not limited to small light-scattering particles such as titanium dioxide crystals and metallic mirrors. In some embodiments, internal layer 26 can comprise a luminescent material, such as but not limited to inorganic luminescent materials such as quantum dots, light-emitting dopants and organic and fluorescent Dyes. Luminescent materials can be used to convert the incoming wave and/or particle from one type and/or wavelength to one compatible with electromagnetic energy converter 14 and, specifically, cells 18. It should be understood that internal layer 26 can include a combination of transparent, refractive, diffusive, dispersive, and luminescent characteristics. In some embodiments, internal layer 26 comprises one or more highly-reflective and/or non-absorbing materials to increase conversion efficiency of electromagnetic energy converter 14. It should be understood that electromagnetic energy converter 14 can comprise a plurality of layers or materials 26 being of different types or of similar types with different operational characteristics.

In some embodiments, electromagnetic energy converter 14 can comprise one or more active, adaptive, and/or optoelectronic optical systems, generally referenced as 30. Such systems can comprise lenses or waveguides 20 and/or additional one or more optical layers 28 disposed within or outside housing 16. In some embodiments, optical layer 28 can be disposed between adjacent cells 18 as illustrated in FIG. 1. Optical layer 28 can comprise diffusive and/or dispersive and/or luminescent medium material, such as but not limited to metallic mirrors. In some embodiments, optical system 30 is an active system that actively manages transmission and/or reflection of EM wave and/or particle into electromagnetic energy converter 14 and to cells 18. In some embodiments, optical system 30 is housed outside the convertor and is comprised of active and/or adaptive optics 46 to prevent deformation due to external influences such as wind, temperature, mechanical stress or to compensate for atmospheric effects.

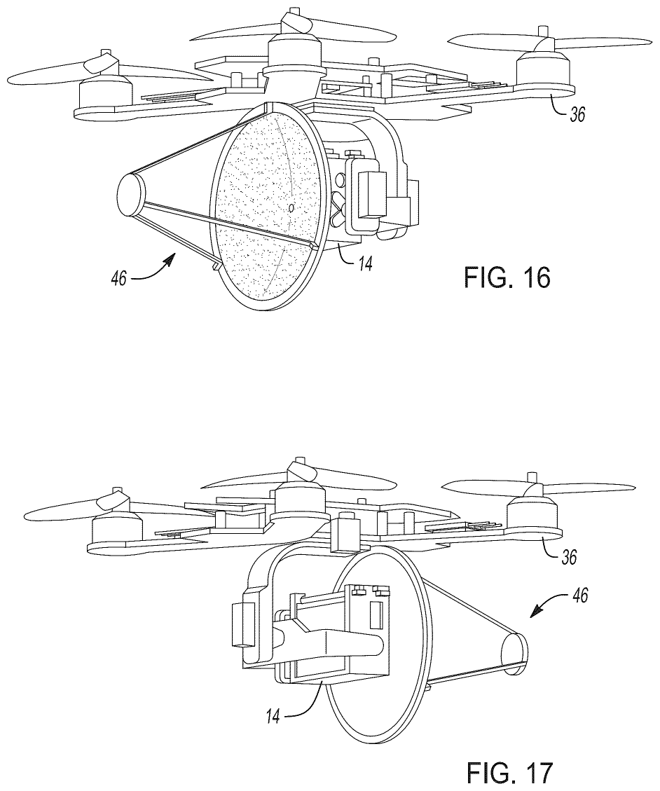

With particular reference to the schematic of FIG. 2, electromagnetic energy converter system 10 is shown having energy source 12 and an electromagnetic (EM) energy converter 14 operably coupled across a medium 100. It should be understood that medium 100 can comprise any medium operable to transmit wave and/or particle energy, such as but not limited to air, gas, liquid, solid, vacuum, fiber optic, and the like. As illustrated in FIG. 2, electromagnetic energy converter system 10 can comprise an optional power converter 32 and a power storage system 34. In some embodiments, power converter 32 is configured to convert and/or filter wave and/or particle energy to another form, frequency, and/or type. In this way, power converter 32 can be used to specifically convert ultraviolet beam to, for example, visible beam or other useable form. In some embodiments, optical filters are used to alter the wave into a uniform waveform such as polar or collimated waveforms. In some embodiments, a diffraction medium (e.g., diffraction grating or prism) is used to selectively choose a narrow bandwidth. In some embodiments, shutters control EM radiation intervals for improved safety and also to enable short-duration pulses of EM radiation. Additionally, it should be understood that power storage 34 can be operably coupled to electromagnetic energy converter 14 to store and/or otherwise manage the use of the produced electricity output from electromagnetic energy converter 14. In some embodiments, electromagnetic energy converter 14 and optional power converter 32 and/or power storage 34 can be carried or otherwise supported by a stationary member (i.e. physical support or foundation) and/or a mobile device (e.g. unmanned aerial vehicle (UAV), aircraft, boat, vessel, vehicle, train, satellite, or any structure requiring or benefit from energy usage, or storage, and/or retransmission), collectively referenced at 36. It should be noted that particular application in a UAV is illustrated in FIGS. 16-18.

With continued reference to FIG. 2, likewise, energy source 12 can comprise a power generator 38, an optional power storage system 40, and a power transmitter 42. In some embodiments, energy source 12 comprises, but is not limited to, a diffuse laser 12.

With reference to FIG. 3, in some embodiments, electromagnetic energy converter system 10 can comprise a gas, liquid or solid electromagnetic energy converter 14 disposed through a part or an entirety of the internal volume of housing 16. In this regard, gas, liquid or solid electromagnetic energy converter 14 generally fills a remaining volume within housing 16 unoccupied by associated structure. In some embodiments, as illustrated in FIG. 3, cells 18 can comprise rod-shaped elements to conduct the EM energy converted into electric current, such as but not limited to reflective rod elements.

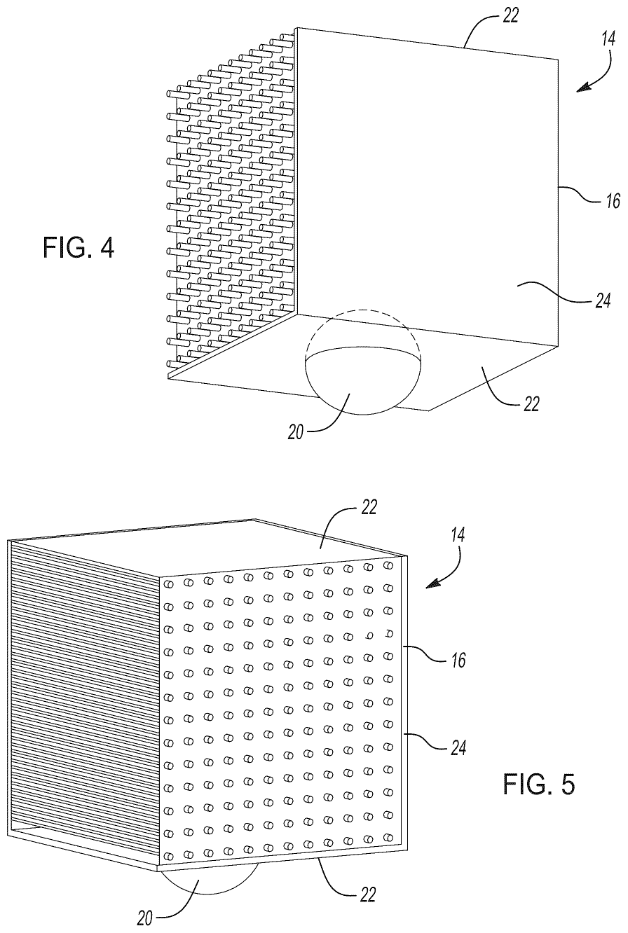

In some embodiments, as illustrated in FIGS. 4 and 5, electromagnetic energy converter 14 can comprise a matrix of electric poles that conducts the converted EM energy. An electric circuit, such as schematically illustrated in FIG. 2, can comprise diodes, capacitors, and other electric components to regulate, store, and/or consume the EM energy converted into electric current.

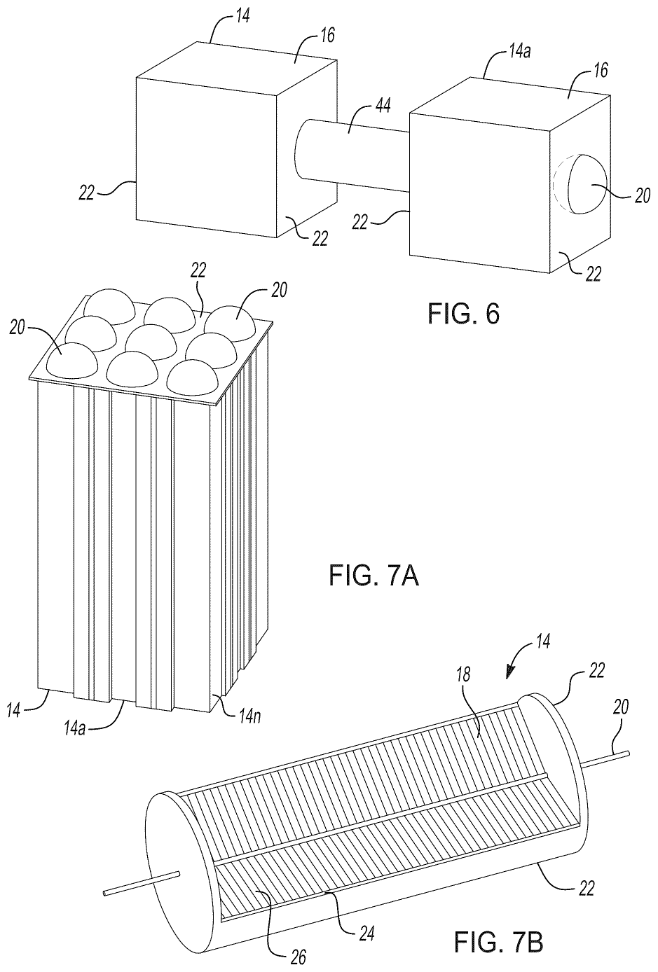

With particular reference to FIGS. 6 and 7A, in some embodiments, electromagnetic energy converter system 10 can comprise a plurality of electromagnetic energy converters 14, 14a, . . . 14n to enhance the degree to which the EM beam is converted to electricity. In such embodiments, electromagnetic energy converters 14, 14a may be coupled in in series (FIG. 6) and/or in parallel (FIG. 7A). With reference to FIG. 6, electromagnetic energy converters 14, 14a can be operably and physically coupled via an optical interface or waveguide 44 to permit and facilitate the transmission and communication of waves and/or particles between electromagnetic energy converters 14, 14a. In some embodiments, optical interface 44 can be part of optical system 30 and can comprise, but is not limited to, a fiber optic cable. It should be understood that waves and/or particles can travel uni-directionally or multi-directionally between electromagnetic energy converters 14, 14a. With reference to FIG. 7A, in some embodiments, electromagnetic energy converters 14, 14n can be arranged such that each of electromagnetic energy converters 14, 14a, 14n is parallel to an adjacent electromagnetic energy converter and each may include an individual lens 20 or a common lens. Moreover, in some embodiments, each electromagnetic energy converter 14, 14a, 14n can remain self-contained, thereby preventing sharing of wave and/or particle input energy, or may permit transmission of wave and/or particle input energy to adjacent converts.

With reference to FIG. 7B, in some embodiments, electromagnetic energy converter 14 can comprise a combination of cells 18, different concentrations (radial gradient) of EM energy-dispersive material within a light-transmissive medium 26 enclosed within a housing 22, conductive film, reflective surfaces to reflect the EM energy back into the EM energy-dispersive material within a light-transmissive medium. The EM energy transmits into EM energy convertor through a fiber optic 20. The fiber optic can be stripped of its cladding over a distal length. A fraction of the EM energy enters the EM energy converter while scattering and propagating in the radially-gradient EM energy-dispersive medium. The EM energy is reflected off the reflective end faces 22 and side faces 24 back into the dispersive medium. In some embodiments, multiple refractive layers with different refraction indexes are used to selectively guide EM-waves. In general, with the combination of the above elements the directionality and intensity distribution of the EM wave entering the EM convertor may be controlled. The remaining fraction of EM energy propagates through the fiber optic out of the EM convertor on the other end. The outgoing fraction of EM wave may be used to communicate information.

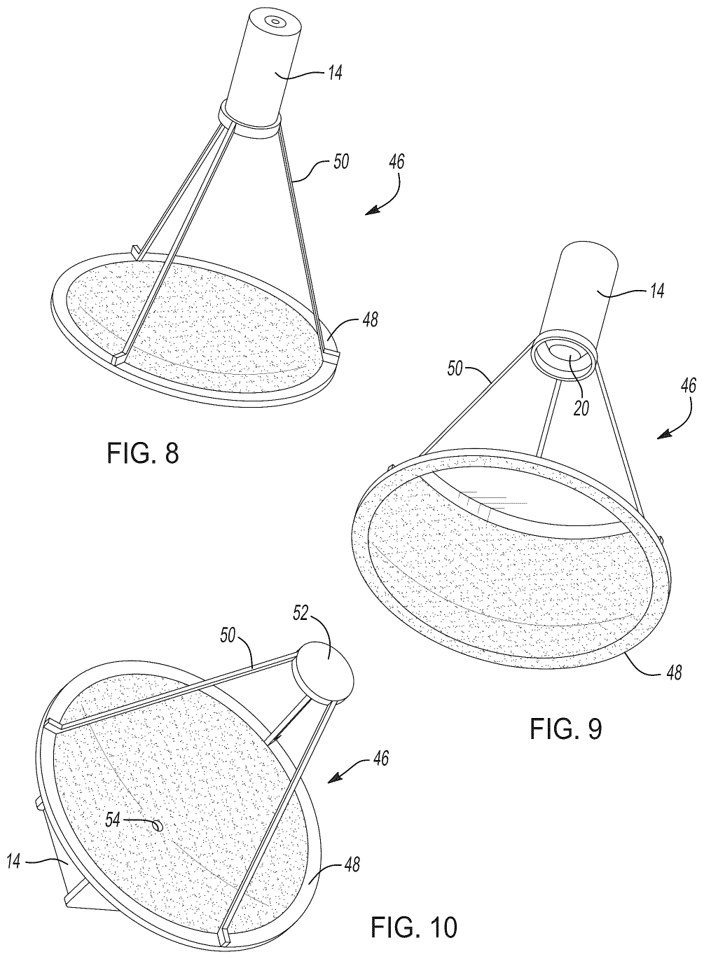

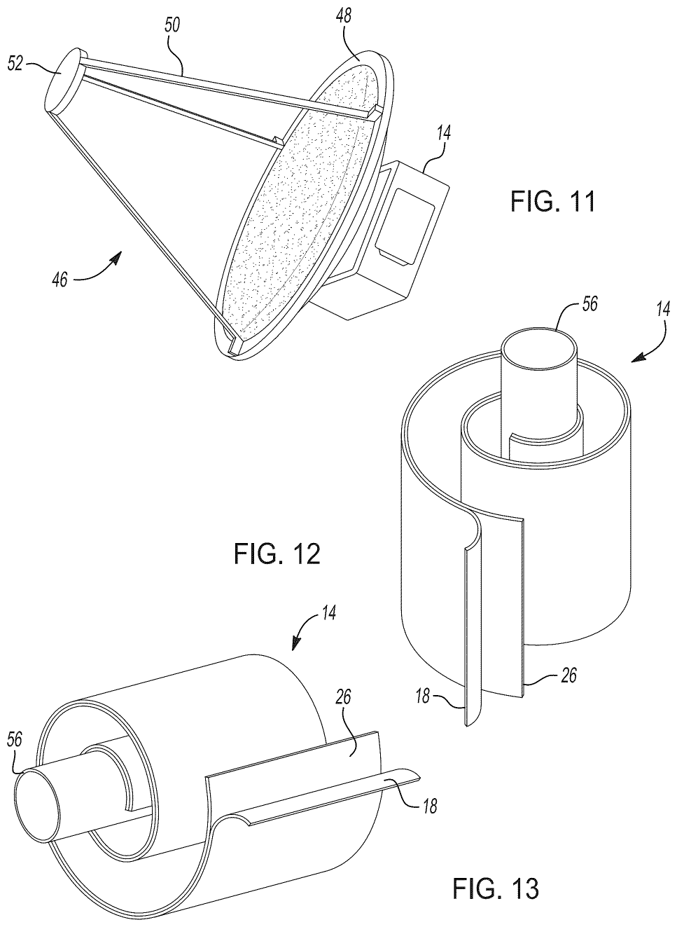

With reference to FIGS. 8 and 9, in some embodiments, electromagnetic energy converter 14 can be mounted on or supported by an EM receiver dish 46. EM receiver dish 46 can comprise a dish member 48 for receiving energy transmitted from energy source 12 or other source (i.e. naturally occurring source). In some embodiments, dish member 48 is a parabolic dish supporting electromagnetic energy converter 14 via legs 50 configured to focus the received energy directly to an input (e.g. lens 20) of electromagnetic energy converter 14. In some embodiments, to minimize loss of energy, a single-bounce configuration of EM receiver dish 46 can be used (i.e. energy received is bounced a single time before focused into electromagnetic energy converter 14). Similarly, with reference to FIGS. 10 and 11, in some embodiments, EM receiver dish 48 can comprise electromagnetic energy converter 14 mounted behind dish member 48 and a supplemental active and/or adaptive optics 30 such as a concentrator dish 52 supported by legs 50 is used to focus the energy transmitted to electromagnetic energy converter 14 to a through hole 54 formed in dish member 48 coupled to lens 20 of electromagnetic energy converter 14. In this way, energy can be focused, albeit via two bounces, to electromagnetic energy converter 14. As seen in FIGS. 16-18, in some embodiments, electromagnetic energy converter 14 (singly or with EM receiver dish 48) may be mounted, supported, and carried by vehicles, such as UAVs and the like. In some embodiments, electromagnetic energy converter system 10 can comprise an accurate and precise tracking and feedback system 62 for high-precision and reliable energy delivery. In some embodiments, adaptive optics 30 can be employed to compensate for potential environmental turbulences.

With reference to FIGS. 12 and 13, in some embodiments, electromagnetic energy converter 14 can comprise a ribbon architecture comprising a centrally disposed fiber optic 56 having a ribbon of cells 18′ and conductive material (e.g., film), together with a reflective or diffusive layer 26. In other words, in some embodiments, electromagnetic energy converter 14 can comprise roll-able sheets including a photovoltaic material, dispersive medium, reflective medium, conductive (and, in some embodiments, dielectric) material, and waveguides (i.e., refractive medium). The EM energy propagates through the waveguide and can be stripped of its cladding over a distal length. The EM energy is introduced into the converter while scattering and propagating in a dispersive medium. The EM beam is reflected off the reflective surfaces.

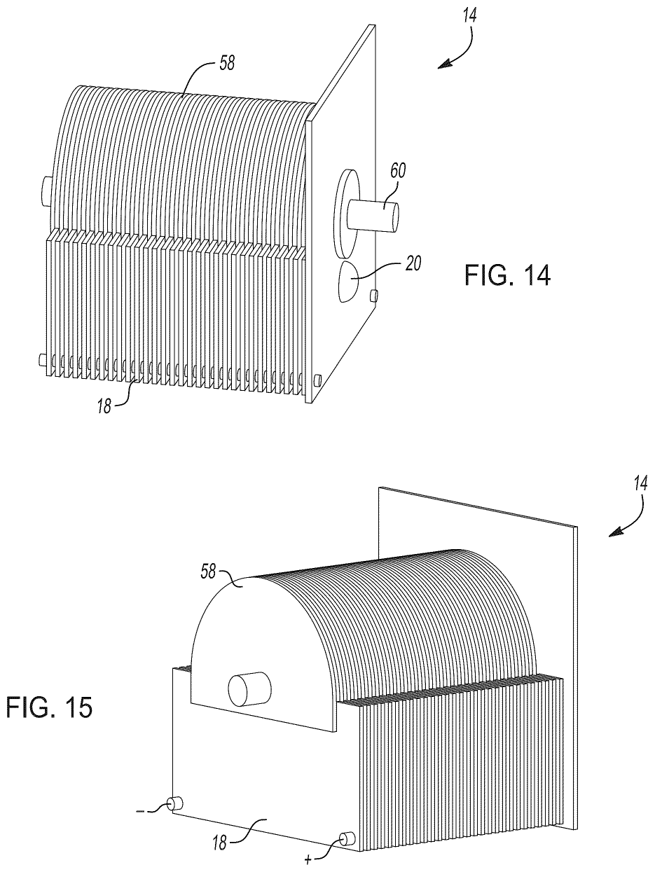

In some embodiments, as illustrated in FIGS. 14 and 15, a generally adjustable electromagnetic energy converter 14′. The output of adjustable electromagnetic energy converter 14′ is a function of the relative positions of an array of disks 58 interspersed within cells 18 (disposed in parallel). The output of electromagnetic energy converter 14′ is changed via rotation of disks 58 to obstruct or otherwise reveal cells 18 to incoming EM wave and/or particles. The relative position of the array of disks is changed by rotating a pin member 60 operably coupled to disks 58 that selective, partially, and/or completely obstructs or otherwise reveals cells 18 to EM wave and/or particles entering lens 20. In some embodiments, the array of disks 58 is coated with refractive and/or reflective materials.

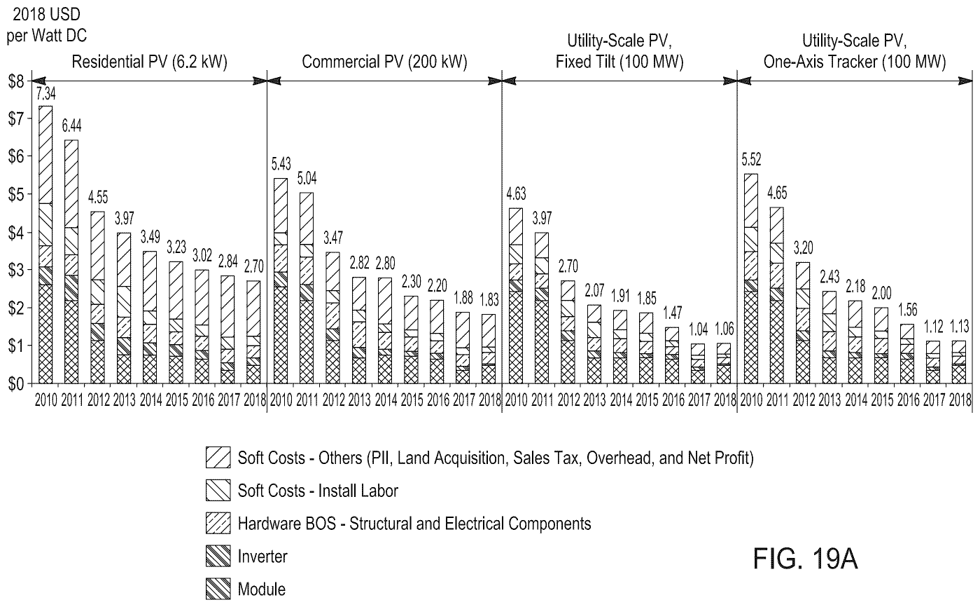

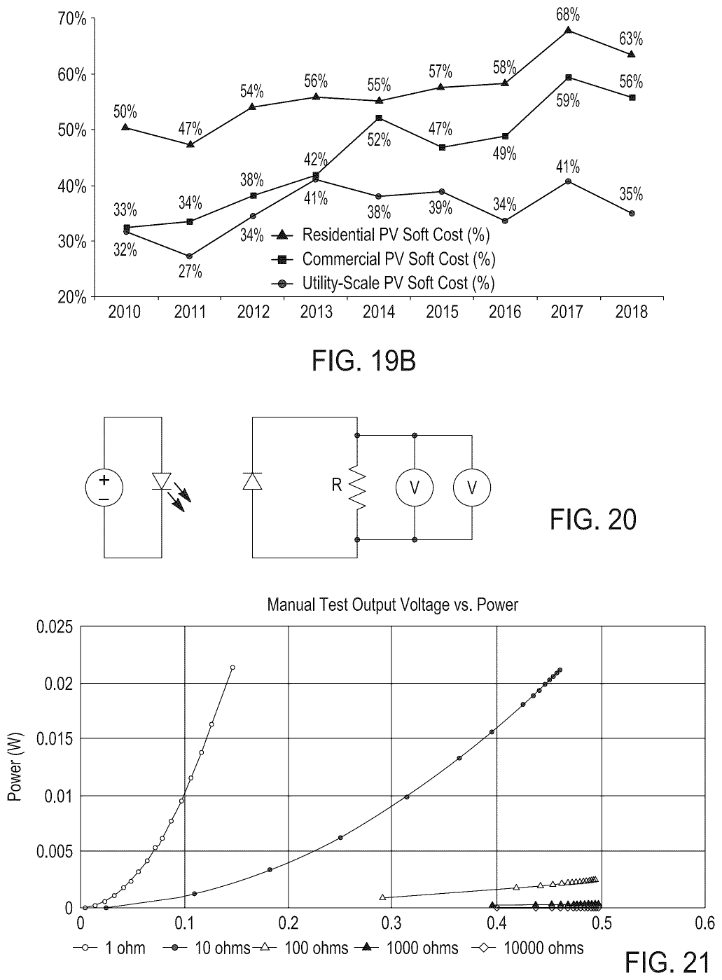

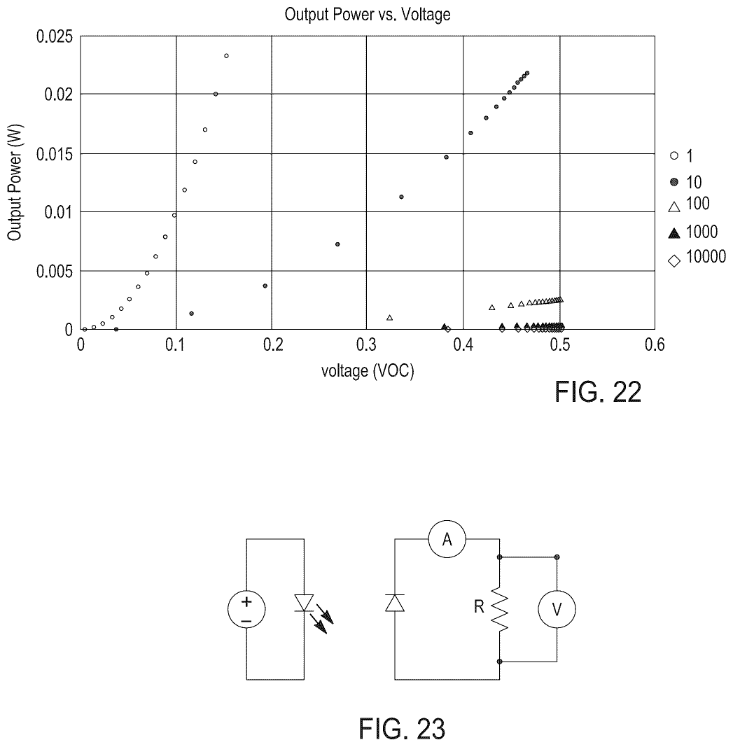

According to the National Renewable Energy Laboratory (NREL), the overall cost of solar modules has been reducing in the United States and across the world over the past decade. As indicated in FIG. 19A, the overall cost of Residential PV arrays has reduced from $7.34/watt in year 2010 to $2.70/watt in year 2018. The cost reduction is mainly due to the decreasing cost of solar modules, thanks to automation.

On the other hand, the soft costs, which include expenses such as land acquisition, install labor, and overhead costs have remained steadily high throughout the past decade. In fact, as FIG. 19B suggests, the overall contribution of soft costs, especially the cost of the real estate atop which solar modules are installed, has been slowly rising. The soft costs accounted for nearly >60% of the overall cost of solar modules. Therefore, it is concluded that future improvements to solar modules must address the unmet need for compact (small footprint) and highly efficient solar modules whose high power density will reduce the amount of land required to generate electricity. The soft cost is also believed to impact the cost of hardware, such that module efficiency improvements will reduce hardware cost of reducing the number of modules per occupied land size.

One of the main contributors to the relatively high module cost per energy density of existing solar modules are: 1) costly tracking systems, and 2) module shadowing. Tracking systems allow solar modules to track the Sun throughout the day, hence, maximizing the power output of solar modules per day. Solar modules will need to be installed with large separation to avoid shading. Shading causes an overall reduction in system performance. In addition, shading is responsible for heating of solar module components and lowering their expected lifetime. Future solar modules will achieve lower costs, and therefore greater adoption, by designing compact and relatively high power density solar modules without the need for expensive solar tracking systems. These compact and highly efficient solar modules will need to be further immune to shadowing.

### EXPERIMENTAL SECTION

An electromagnetic energy convertor (EMEC) device is optimized via adjusting three main system characteristics: 1) number of photovoltaic (PV) cells, 2) relative PV cell angle, 3) medium transparency diffusion coefficients. Other adjustable parameters include: PV cell stacking density, light intensity, light frequency, load resistance, medium dielectric constant (i.e., refractive index), EMEC weight, and light collection aperture.

In some embodiments, the PV cell is an off-the-shelf silicon-based material. In other embodiments, the PV cell comprises an organic material (e.g., OLED and perovskite material) to convert electromagnetic energy to electrical current. In some other embodiments, the PV cell is not opaque. In some embodiments, the PV cell is coated with a reflective layer 28 to reduce light absorption. In some embodiments, the PV cell is specifically selected to operate within a narrow range of wavelengths. In other embodiments, the PV cell operates within one (or more) range of EM frequencies. In some embodiments, the PV cell is coated in a dielectric material to avoid short-circuit between cell terminals (or discharging). In some embodiments, the dielectric-coated PV cell is submerged in a high-specific heat fluid, such as deionized water.

In some embodiments, the fluid medium circulates and can exchange heat. In some embodiments, the medium within which the PV cells are at least partially deposited is a gas mixture. In some embodiments, the medium is an insulating material and is a mixture of materials of more than one state of matter. For instance, in some embodiments, air packets are introduced with in a solid matrix of resin to reduce system weight. In the following experiments, a photovoltaic cell is first characterized. The cell is then used in combination with other cells while the 3 main system characteristics are adjusted. The EMEC overall output is compared with a cell of the same occupied surface area. Therefore, relative performance is defined as the ratio of the power output of the EMEC per occupied surface area and the power output of flat cells occupying the same surface area.

### Experiment 1: Cell Power Output Characterization

In order to determine the EMEC efficiency, i.e., η=P_out/P_in×100%, knowledge of the input electromagnetic power and the output electric power is essential. The EMEC device's power output was measured using P=IV to ensure consistency. The voltage was measured across a single resistor in series with the LED using the automatic measurement algorithm and manually using a multimeter. The voltage was measured for resistor values from 1Ω to 10 kΩ. Various loads were tested to again ensure that the power dissipated behaved predictably for calibrating the measurement algorithm.

### Methods

The USB microcontroller used for the measurement algorithm was the NI USB-6009. The light source was a Chanzon 100 W LED and emitted illuminance from (25-775)×100 lux of natural white (4000 K) light. As shown in FIG. 20, the Chanzon LED is connected to a DC power source. The power source is controlled by an Arduino. In order to calibrate the NI instrument voltage reading, V1, voltages across a resistor connected in series with the photovoltaic (PV) cell were also measured using a manual voltmeter, V2.

The solar cell tests were consistent in automated measurements using the automatic measurement algorithm and manual measurements using a multimeter. The tests were run 3 separate times and averages were calculated for error analysis purposes. Both measurements could not exceed 0.5 V for output voltage because of the characteristics of the solar cell.

The similar results indicate that the automated measurements using the automatic measurement algorithm are accurate and, thus, will be used for all future experiments of similar configuration. The graphs of voltage vs. power simply state that the automatic measurements are consistent with a standard voltmeter. The current of the system was not measured using the multimeter, but was calculated using the Ohm's Law (V=RI). Both the voltage and current will need to be measured across the EMEC device in order to find the max power dissipated for further experiments.

### Experiment 2: Solar Panel Output Specifications

The purpose of this experiment was to measure the outputs for the solar panel and various light intensities in order to find maximum output for the solar panel. The power of the solar panel is given by P=IV. The maximum power point or P_{Max}, is given by the highest product of current and voltage points as P_{Max}=max(IV).

The maximum power point (MPP) will give the voltage needed to create the greatest power possible. From this point, the optimal load resistor can be chosen to achieve the greatest power output.

Both the current and output voltage were calculated manually using two multimeters, as shown in FIG. 23. Light intensity was measured from 25-775×100 lux in intervals of 75×100 lux. The resistor values were measured from 0Ω to 4 kΩ. This range was chosen to ensure that open circuit voltage, V_{OC}, and short circuit voltage, I_{SC}, were recorded. V_{OC} is a characteristic of the solar panel that is the voltage difference across the panel with no current flowing. This is important to characterize because it tells us the highest potential difference across the solar panel's terminals. V_{OC} was measured by hooking up the panel across a voltmeter. A 4 kΩ resistor gets us accurately close to V_{OC} with no current flow. I_{SC} is a characteristic that occurs when there is no voltage drop across the terminals. I_{SC} is important to measure because it tells us the highest current that can flow in the circuit for various light intensities. Taking out the resistor and connecting the panel wires will result in I_{SC}. This is equivalent to having the 0Ω resistor. These behaviors of the solar panel will be useful to know for further test.

### Results and Discussion

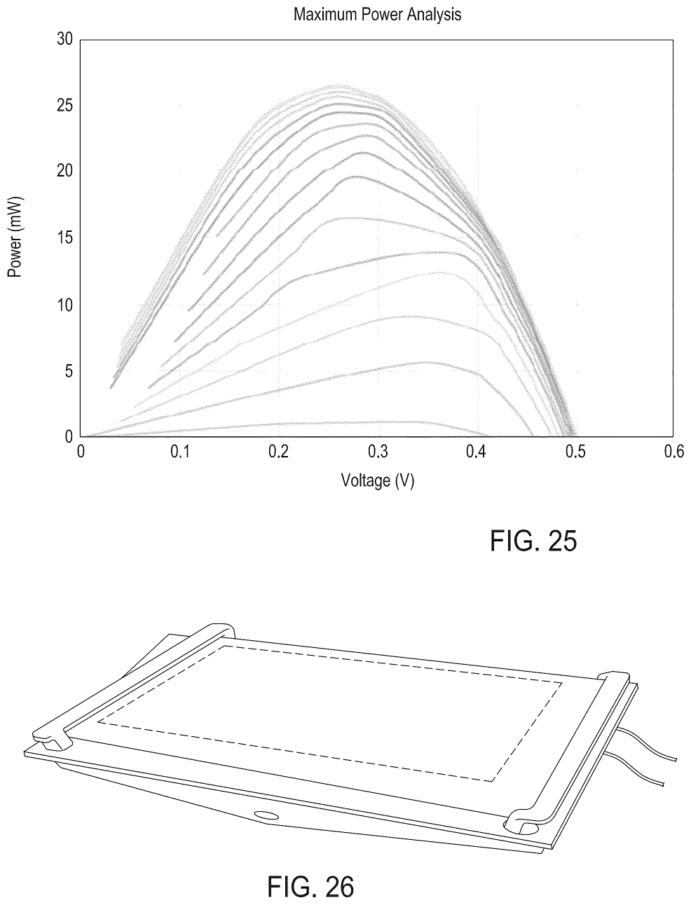

The current and voltage measurements of the cell behaved consistently. The max voltage of the solar cell is 0.5V and none of the tests reached above it. This confirms that the V_{OC} of the cell is 0.5 V. The short circuit current values ranged from 4 mA to 185 mA. The lower the light intensity, the longer the constant current portion of the graph is. The knee of the graph is at lower voltages and higher currents for higher light intensities and vice versa for lower light intensity. This can be seen in FIG. 25.

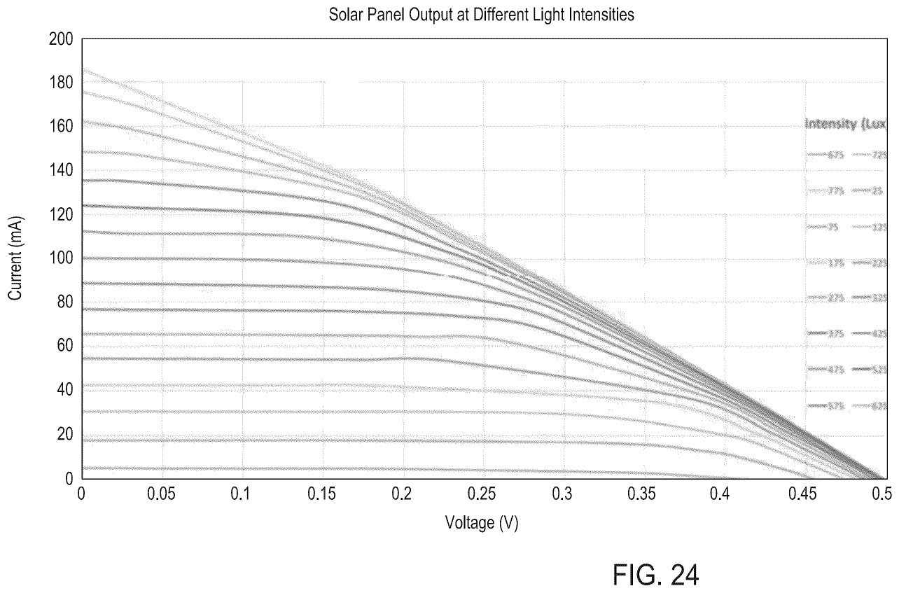

FIG. 24 indicates that the short circuit current of this particular photovoltaic cell will not exceed 200 mA for light intensities less than 775 lux. This can help us categorize the types of equipment to use. If a multimeter cannot take over 200 mA for a certain reading, we know that it will be safe to use for a single cell. The voltage will range from 0.4-0.5 V open circuit and will never pass 0.5 V. This can help us in the same way as the current.

FIG. 25 provides a voltage vs. power profile for the particular cell. The profile can help with efficient use of the photovoltaic cell. A single cell can produce around 26 mW. As the light intensity grows, the additional benefit of power generation decreases showing diminishing benefit of each increasing light intensity. This occurs because of the cell's characteristics of I_{SC} and V_{OC} not allow anymore current, and therefore power generated, after V_{OC} is reached. The maximum power point can be determined for each light intensity to find the resistance that gets closest to that point. Understanding MPP can help with maximizing the efficiency of the system.

### Experiment 3: Transparency and Angle Tests

Light diffusers can be used with solar cells to spread out the light to all of the cells in the array to improve efficiency (per surface area). A solar array has many solar cells ran in series (or parallel) with each other to increase power generation. If part of the array is not receiving light, the efficiency of the array drops drastically. This experiment compares light diffusers to see if light can be spread out to every cell to ensure no dead/shadowed cells and avoid a large drop in power generation.

### Methods

Various light diffuser samples were tested under light intensities from 25-775 (×100 lux) with a series resistance of 100Ω, as shown in FIG. 26. Each light intensity was also tested at varying degrees away from normal light exposure. Each lux value was tested from 0-180° from normal in 10° increments. Different angles were tested to further understand characteristics about the solar cell to maximize efficiency and find out the best angle to put the cells. Angles were tested with the diffusers to see the relationship between different transparencies and degrees from normal.

The thickness of the holder is 4 mm and 1.75 mm where the PV cell sits. Including the thickness of the cell and the glue that sits underneath the cell, the diffuser is around 1.5-2 mm away from the cell's surface for these tests.

### Results and Discussion

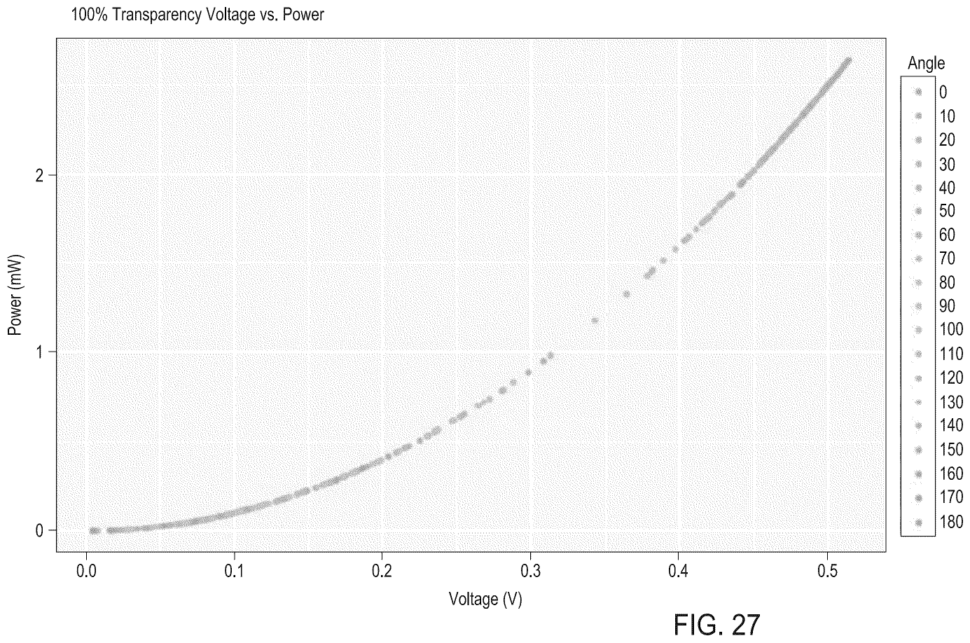

FIG. 27 shows the voltage vs. power graph for the PV cell without a diffuser. The distribution shows that there is a correlation between angle from the light and output voltage. The lower angles have a higher output voltage and create more power and the higher angles have a lower output voltage and create a lower power output. This relationship is true most cases when the light intensity is held constant. This graph shows that power depends on degrees from the light, to go along with the light intensity dependency.

This graph details how power output of our cell changes by changing the angle to the light source. The power output stays pretty consistent before 90 degrees from light, but then has a large drop at 90 degrees. The power output continues to fall until 160 degrees, and then rises for the final two measurements. The changing intensity values stays consistent with Experiment 3 in that the higher intensity, the higher power output. An angle closer to normal is more important than light intensity for angles less than 90 degrees. After 90, there is almost a constant increase in power as light intensity is increased in the same size steps.

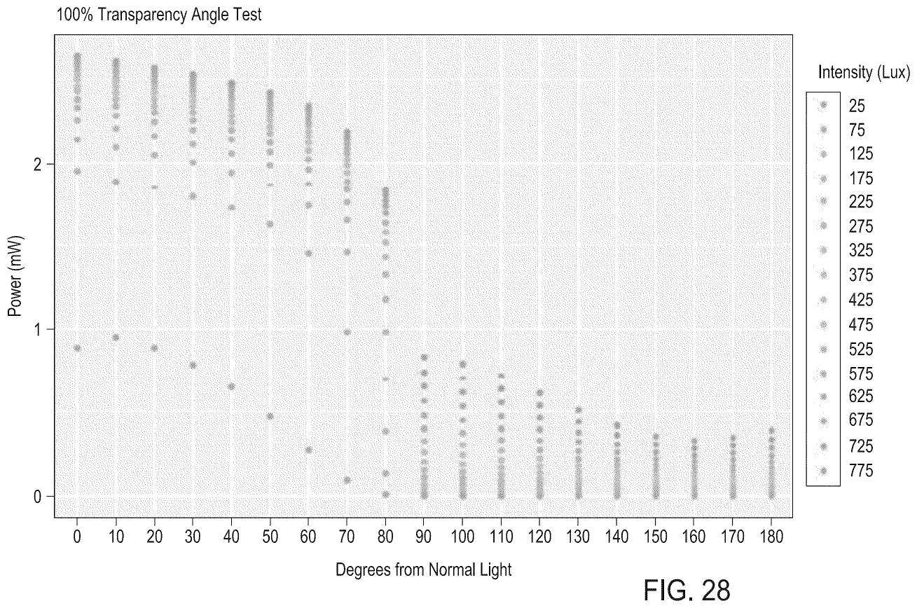

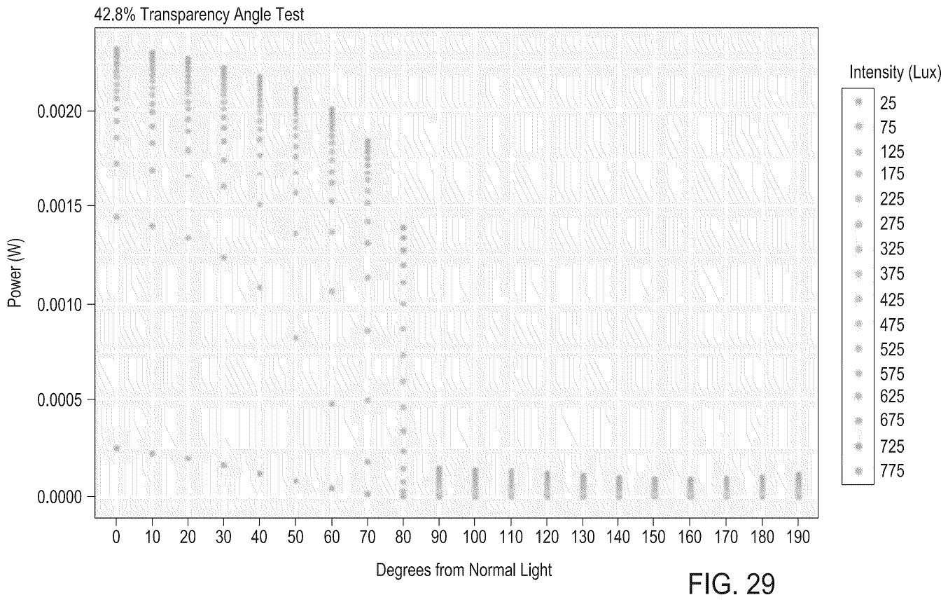

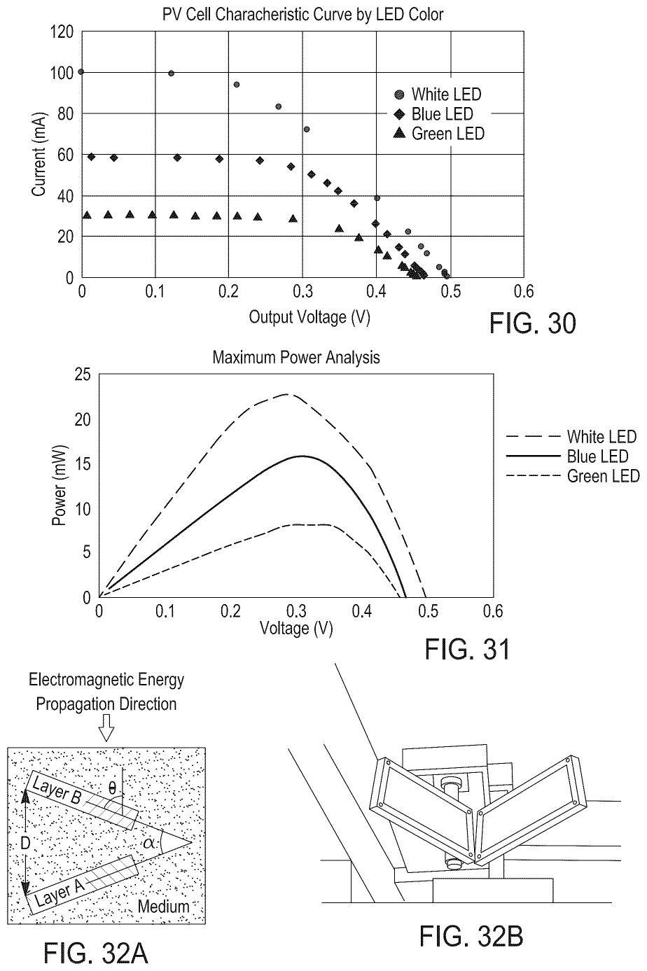

This test was ran with the Makrofol DE 1-4 020209 from the diffuser sample kit. The diffuser was tested and found to be 42.8% transparent. The power output drops more drastically past 90 degrees than the test with no diffuser. The power is nearly zero past 90 degrees for all following degrees. The power is also not as consistent at the top as the power starts to fall down approaching 90 degrees. It is also important to note that the axis for Power is in watts and FIG. 28 is in milliwatts. The diffuser blocks more light from reaching the cell and therefore less power is produced.

The takeaway of Table 1 is to show the different rates of change in power output for different diffusers. There is no real pattern to the decrease in power output across the range of diffusers. Most diffusers decrease substantially after 90 degrees as seen in FIGS. 26-27, but some diffusers decrease more steadily, like 91.6% and 87.7%. In a couple specific cases, some diffusers actually increase power when they are turned further from the light source. This happens for 91.6% at 110 degrees and 91.5% at 100 degrees. Most of the diffusers increase slightly after the turn from 170 to 180 degrees, when the cell is facing directly away from the light. The diffusers made out of polycarbonate film, (93, 42.8, 77, 87.6, and 82), all experience sharp drops in power output around the 90 degree mark. The rest of the diffusers are made out of acrylic and experience more gradual drops in power output, except for 64.8%. 64.8 is different in color (white) than the other acrylic diffusers and could the reason for sharp drop at 90 degrees.

Table 2 is a continuation of Table 1 for the polycarbonate diffusers. All of the polycarbonate diffusers have the same thickness and the same surface texture. The first four (89.1, 55.6, 53.2, and 52) are considered translucent cool for their color and the rest are translucent warm. The diffusers all drop in power output around 90 degrees. The behavior of the diffusers are more consistent across the table as they are all made of the same material. The polycarbonate diffusers start to become useful at the 90 degree mark, as these diffusers hold their power output better than using no diffuser.

Table 3 shows the benefit or harm of using a diffuser at certain angles in terms of total power output. Most of the diffusers increase the power output for angles below 90. The differences in the diffusers really show for angles at or above 90. Some diffusers increase the power output whereas some decrease it. The polycarbonate film diffusers decrease power output after 90 degrees. This tells us that using no diffuser past 90 degrees is better than using a polycarbonate film diffusers. Most acrylic diffusers improve power output past 90 degrees. The diffusers that performed the best, (94.2, KSH 93, 91.6, and 87.6), are all made out of acrylic. The 87.6 diffuser, made out of polycarbonate film, increases the power output at 90 degrees, but then decreases in performance similar to other polycarbonate film diffusers. Again, the transparency is not the only factor in changing the power output. Some more transparent diffusers are outperformed by less transparent diffusers, and some less transparent diffusers are outperformed by more transparent diffusers. Proof of this is in the difference in performance between the two 93% transparent diffusers.

Table 4 is a continuation of Table 3 for the polycarbonate diffusers. The polycarbonate diffusers all perform the best after the 90 degree mark. All diffusers except the 52% significantly increase the power of the PV cell at the 90 degree mark to the 110 degree mark. The polycarbonate film diffusers are their most useful in this range and can increase the power output of the cell. These tests will further help maximize power of the EMEC device based on the orientation and angle to the light.

The goal of the diffuser experiments is to find the best set of conditions to use the PV cell to maximize power output. These tests can serve as a reference when designing the black-box device. Power decreases as the cell is rotated away from direct sunlight. Certain diffusers can improve the performance of the cell at certain angles. These combinations can be used with diffused light to create more power from PV cells not in direct light.

The polycarbonate diffusers can be used at lower incident angles to retain efficiency. Acrylic diffusers should be used at higher incident angles past 90 degrees to optimized cell efficiency.

### Experiment 4: Colored LED Test

Solar cells generate electricity when light hits the cell and causes electrons to be released from the cell, creating a potential difference, known as the photovoltaic effect. The energy of the ejected electrons is directly related to the wavelength of the light that hits the cell. This experiment examines this relationship and how different colored light sources affect the characteristic curve of a PV cell.

### Methods

The tests were run using the same circuit setup as in Experiment 2. The LEDs that were tested were green, blue, red, and white light. All the tests were ran at 425 lux. The resistors values were set from 0.3Ω to 4000Ω in order to get the full range of the characteristic curves.

### Results

FIG. 12 shows the various characteristic curves for the different colored LEDs. The wavelength of the light appears to have a significant effect on the V_OC and I_SC characteristics of the cell. The colored LEDs bring down both V_OC and I_SC of the cell. The green LEDs pulls the current and voltage down further than the blue. It is also important to note that blue has a shorter wavelength than green in the visible light spectrum.

FIG. 31 shows the maximum power for the different LEDs. The white light has the highest potential power output followed by blue light and green light. These results also follow the wavelength pattern of the visible light spectrum.

The color of the light is another factor that can be manipulated to achieve desired characteristics of the cell. In order to achieve the maximum power of the cell, white light is the best light source for selected PV cell.

### Experiment 5: Colored LED with Diffusers

In Experiments 3 and 4, it was observed that diffusers and LED colors can have a significant impact on the power output of a PV cell. This experiment examines their relationship using both the diffusers and colored LEDs together. The purpose of the experiment is to see how the diffusers prevent light from reaching the cell at different wavelengths and to find the best combination of diffusers and LEDs to maximize power.

### Methods

Various light diffuser were tested under light intensities from 24 lux to 775 lux with a series resistance of 100Ω. The cell was tested from 0-180 degrees from normal light for each diffuser. The tests were repeated for all of the different colored LEDs.

### Results

Tables 5 and 6 shows the benefit or harm of using a diffuser at certain angles in terms of total power output by LED color. The overall power output trend of the diffusers is constant over different colored LEDs. The power drops substantially around 90 degrees for the polycarbonate film diffusers, just like for the white LED, whereas other diffusers have more gradual drops. The starting reference power values are all higher for the blue LED. The green LED performs worse at angles past 100 degrees for most diffusers. The 180 degrees values are all under 0.5% for the green and over 0.5% for the blue.

Table 5 shows a large difference in power output around the 90 degree mark. All of the diffusers are worse than reference at 80 and 90 degrees for the green light. After 90 degrees, the results are less consistent. The 5 best performing diffusers past 90 degrees for the green LED (KSH 63, 91.6, 91.5, 79.1, and 61.5) are all made out of acrylic. The worst performers past 90 were made out of polycarbonate film except for 64.8, which is made out of acrylic. 64.8 performed poorly for the white LED test as well, whereas the other acrylic diffusers performed better.

Table 6 is for the blue LED tests. The effect on power output is not consistent across all diffusers. There is not a large drop around the 90 degree mark for most of the diffusers. The diffusers that have a transparency in the 90s performed the worst for the blue LED. This was not the case for the green LED, as KSH 93 performed the best out of all the diffusers. Diffusers below the 90% transparency mark increased power output for the most part past 90 degrees.

### Experiment 6: Plural PV Cell Characterization

The EMEC device will contain multiple PV cells connected together that create a series of cells to maximize the power of the device. Understanding how the cells work together is vital to ensuring that the design and use of the device are in the best way possible. FIG. 32A provides a schematic for three inter-dependent parameters: layers' angles from the incoming electromagnetic energy θ, layers' relative angle α, and layers' relative distance D. The layers A and B are selected from a list consisting at least of PV cells and optical layers such as mirrors.

The angle θ defines the angle at which each layer is oriented with respect to the incoming electromagnetic energy, e.g., light and can vary between 0 and 360. At θ=0 degrees, the cell is oriented perpendicular to the incoming electromagnetic radiation. Traditional solar cells generate maximum power when oriented at θ=0 degrees.

The relative angle α is defined as the angle between individual layers. For instance, in some embodiments, two PV cells are oriented to face each other α=180 degrees. In other embodiments, layer A is a PV cell coupled with a Layer B, a reflective surface at an angle α=90 degrees. In this embodiment, the two layers are oriented at θ=45 degrees, resulting in doubling the light intake of Layer A by reflecting the light from Layer B. PV cells in traditional 20 solar panels are oriented at θ=α=0 degrees.

The relative distance D refers to the stacking density of the layers. The relative distance D will determine the light intake cross section of Layer A and Layer B. Smaller D will result in smaller amount of light entering between the two layers.

In some embodiments, the medium, shown in grey, is resin. The resin is liquid in some embodiments, while a solid, i.e., hardened, in other embodiments. The transparency and the diffusivity of the medium is modified in some embodiments using color pigments, such as dyes, and air bubbles. In some embodiments, the resin medium is thinned by adding acetone.

### Methods

Two PV cells were set up in series with each other, as shown in FIG. 32B, and the voltage across both of the cells was measured.

The cells were placed in holders connected to 200 step motors. The motors were controlled using an Arduino Uno and the Arduino IDE and the voltage was measured across a 100Ω resistor using the NI USB-6009. The cells started flush against each other, and were then open in steps of 10.8 degrees from 0-180 degrees. These measurements were picked on the limits of the stepper motors. Each step from the motor is 1.8 degrees and 5 steps gives 9 degrees to try and mimic the single cell test angles. The cells were equidistant from the light source at all times and since both cells are of the same design, we assumed that the potential across each cell was equal.

### Results

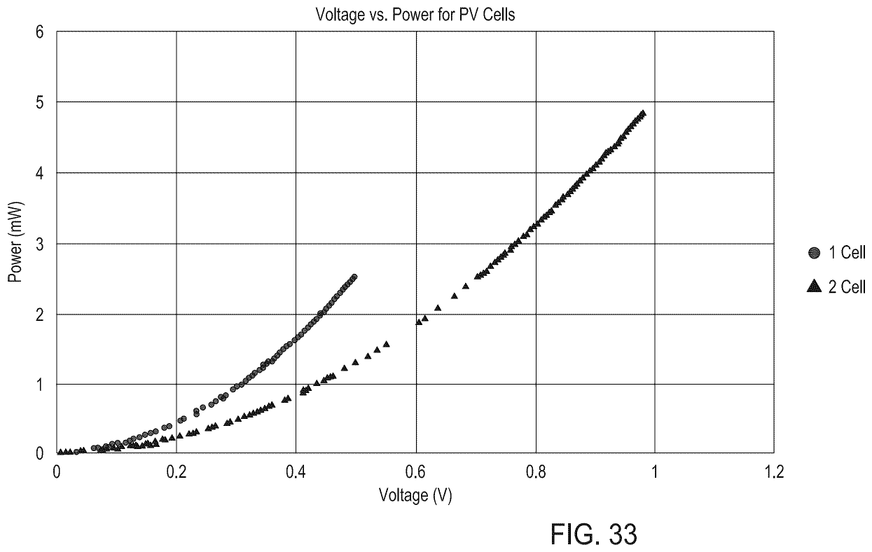

The voltage for the two cell setup is the total voltage, so the voltage of a single cell is the voltage divided by 2, as shown in FIG. 33. The plural cell setup results in doubling the maximum voltage across the resistor. These points occur at the open circuit voltage and is therefore a characteristic of the cell. The voltage almost reaches 1 V for the two cells and the single cell reaches around 0.5 V. The total power of the device is doubled as a result. The overall power distribution of the one cell setup grows twice as fast as the two cell setup.

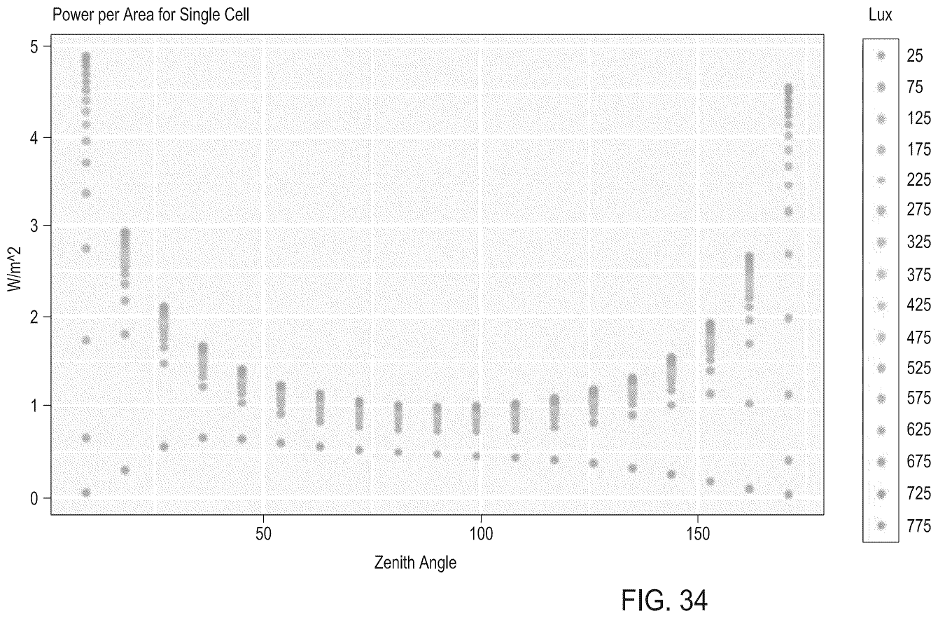

As shown in FIG. 34, the power per surface area (PPA) for the two cells ranges up to 5 W/m² per cell. The angle is taken from normal to receiving light. The points that are almost always paired up are just on either side of normal.

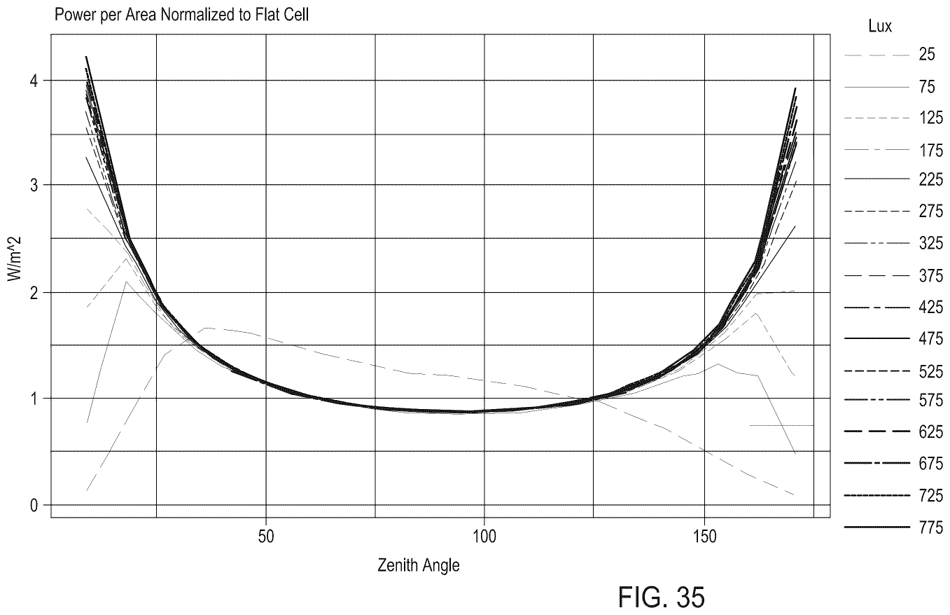

FIG. 35 shows the best way to utilize area inside the EMEC to produce the most power. PV cells normal to receiving light produced the most power (FIG. 9). Changing the angle of the cell reduces power, but can utilize a given area in a better way. The cells can produce up to 4 times the power per area than a flat cell at 90 degrees from normal (0 or 180 degrees from zenith). Multiple cells should be utilized vertically or close to vertical to maximize power per area.

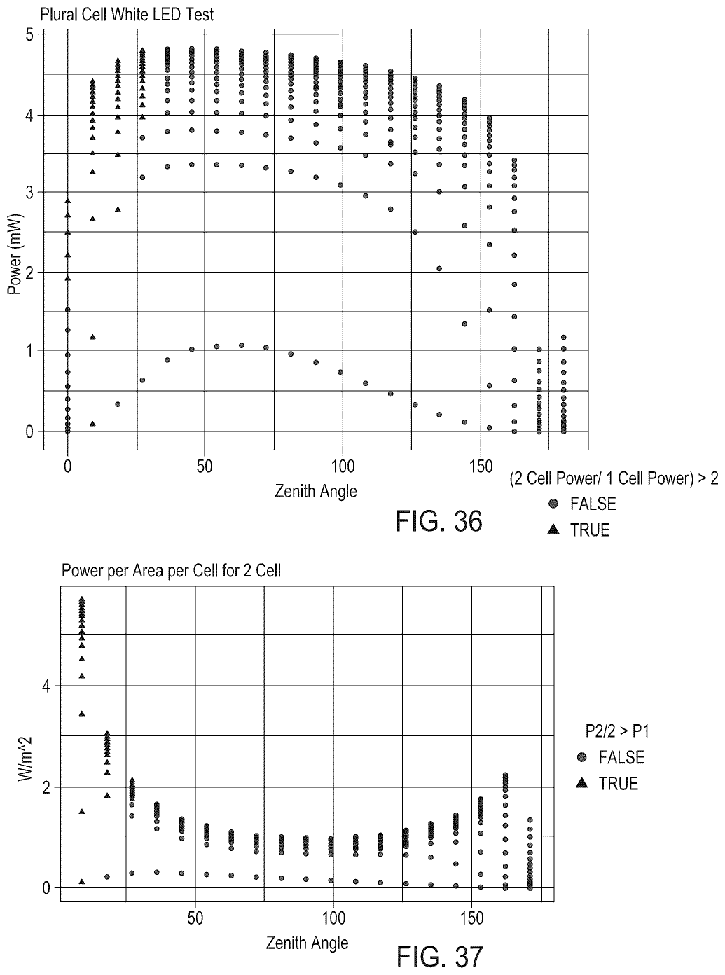

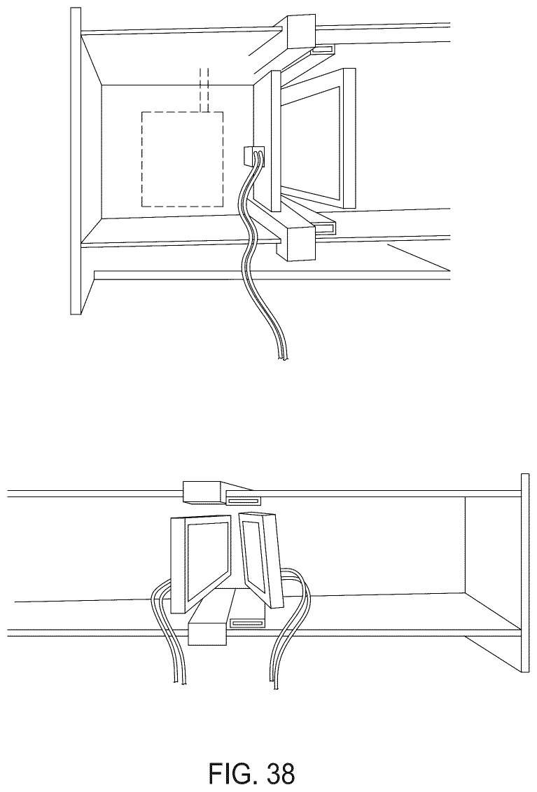

FIG. 36 shows the power output for the two cell setup by angle. The blue points are the points where the interaction of multiple cells is beneficial. the blue points are locations in which adding a second PV cell more than doubles the power output. The conditions in which this happens is for high light intensities and small zenith angles. This is a result of the reflection of light between the cells which occurs in a larger amount when they are closer together. The result is less predominate at higher angles because of a larger angle of incidence and the cells are already operating close to their V_{OC} points.

Table 9 is the same data as FIG. 35 just listed out in a table. The cells had no reflective material over them and the power ratio is listed in each cell. The conditions where the two cells system receives extra benefit (power more than doubles) from a second cell occurs for small angles. For the medium and higher angles, there is not this extra benefit of adding a second cell. The red cells are where adding a second cell actually decreases performance of the system. This occurs because the cells are connected together. The drop in performance of a single cell in the series will drop the power in other cells in the series.

The orientation of the cells cannot avoid this fact. If the cells are lined in series, one cell not receiving light acts as a resistor and drops the voltage across the cell. A parallel connection is not the solution either. In parallel, the cells share the same voltage value across each cell. A shaded cell will bring down the total voltage and drop the voltage of each path as a result. However, a series connection is the best solution, as the power output is affected less by shading than in a parallel connection. Bypass diodes can also be utilized to skip any cell in series that is being shaded.

The gain in power output by adding a second PV cell can be seen in FIG. 37. These are the blue points where each cell in the e plural cell setup outperforms a single cell. These locations again occur at small angles, where the cells are the closest to each other. These conditions are where light reflects off the cells into each other and increases power, as seen in FIG. 36. The final zenith angle of 171 has a large drop in power per area compared to the single cell in FIG. 34. This is the first angle that shows a significant decrease in power by adding a second cell. There is less light at 171 degrees and the PV cells are not working efficiently. This hurts the setup as a whole and decreases potential power output from a second cell.

The purpose of Table 12 is to characterize the reflective surface used in following reflectivity tests. The reflective surface used was 35% tint, silver vinyl surface used for automobile windows. The power of the single cell is boosted at small angles. This is expected as the cells are closest to each other and the chance for reflectivity is the greater. The cell also increases in performance at the 180 degree mark. This reflectivity test for the cell helps understand the impact of using this specific vinyl and the optimal zenith angle and lux combination.

Table 11 shows the base effectiveness of using a reflective cover over the cell for a single cell setup. The power decreases for all cases except for zenith angles of 180. The only benefit of using a reflective surface on a single cell in the orientation would be at 180 degrees. The purpose of this test was to characterize how the reflective surface works and the results of using it in power output.

Table 12 shows the benefit or hindrance of putting a reflective surface on one cell in the two cell setup. The benefit of the reflective surface only occurs at zenith angles of 171 and 180 degrees. These angles are when the cells are facing directly away from each other. Therefore, there is no light that is being reflected from one cell to the other. The added benefit at these angles have to do with the performance of the reflective vinyl as seen in Table 11. There is no reflective benefit for small angles, where the cells are closest together and interacting the most.

Table 13 compares the power for a two cell setup and a two cell setup with reflective vinyl over both of the cells. The power is reduced in all situations and conditions.

The reflective surface does not appear to have increased power substantially for any of the cell layouts. Other reflective materials or other transparencies could be tested to find the best way to utilize the cell with a reflective layer 28.

### Experiment 7: Plural PV Cell with Colored LEDs

Experiment 7 shows the effect of using a green and blue LED in the plural PV cell setup in Experiment 6. This test will see how the power is affected by different wavelengths of light and to see how consistent the results are for single cell colorized tests. This characterization will help maximize power output of the cell combination.

### Methods

The cells were tested in the same way as in Experiment 6, from 0-180 degrees using a green LED, blue LED, and white LED. The first test used only one PV cell to create a baseline for the cell in this configuration for different colored LEDs. The second test tested two cells in series with voltage measured across one of the cells. This test also used the three different colored LEDs. Since the white LEDs had the highest power output in Experiment 4, the results of the colored LEDs were compared and normalized to the white light power measurement.

The results are included in Tables 14-19. The first test resulted in the two tables “1 Cell Normalized Green LED Test” and “1 Cell Normalized Blue LED Test.” These tables are from the single cell measurement and divided by the white LED's power output for each cell in the table.

The green LED does not have much benefit over the white, as almost all the points result in a number less than 1, or a decrease in power output. The blue LED can be seen to increase the power output for small angles and could be a result of the absorbance of blue light. Blue light has a low absorbance and has a greater chance of reflecting from cell to cell than white light.

The next two tables were created from the two cell tests measuring across a single cell. These values were normalized to white LED tests under the same conditions. Neither of the tables have a significant benefit over white light in this setup. The green LED is not beneficial under any conditions and the blue is slightly beneficial around 160 degrees.

The final two tables were made by taking the values from the second set of tables over the values from the first set of tables. These tables show the power output percent increase change from adding a second cell for each LED color. The purpose of these tables is to show how much more blue or green light can be utilized by adding another cell. These result in an increase in performance of a single cell in the setup.

Both colors increase in power output by adding a second cell for higher zenith angles. As the angle between the cells increases, a second PV cell in the setup will result in substantially increasing performance of each cell.

It is concluded that when using colored LEDs, a two PV cell setup is beneficial for each cell for higher angles. For small angles, blue LEDs should be utilized in a single cell setup. Colored LEDs should never be used for small zenith angles in a two PV cell setup using this specific type of PV cell.

### Experiment 8: Plural Cells in Diffusive Medium

Experiment 3 showed the benefit of using a solid, diffusive material to scatter light and provide light to the PV cells. This experiment using liquid resin as the diffusive material to examine the benefit of scattering light in a liquid material. Resin is beneficial in the design of EMEC devices as the resin can be easily poured over the cells without worrying about the positioning unlike with solid diffusers.

### Methods

The plural resin tests were ran using varying amounts of clear resin. The resin is a solution of resin and ethanol to lower the viscosity of resin. Resin amounts used were from 0 mL to 1000 mL in steps of 200 ml. Each amount of resin had secondary tests that covered the container in a reflective surface (aluminum foil) 28.

The cells started horizontal with a zenith angle of 90 to the light source. The cells were rotated towards each other in steps of 9 degrees until the cells were parallel to each other. The angle measured in the tests was the angle to the horizon of the PV cells (referred to as altitude angle). The power per area numbers were then normalized to the power per area of a flat PV cell with no resin. This normalization shows the benefit of using resin in terms of saving the needed to maximize power from the cells.

### Results and Discussion

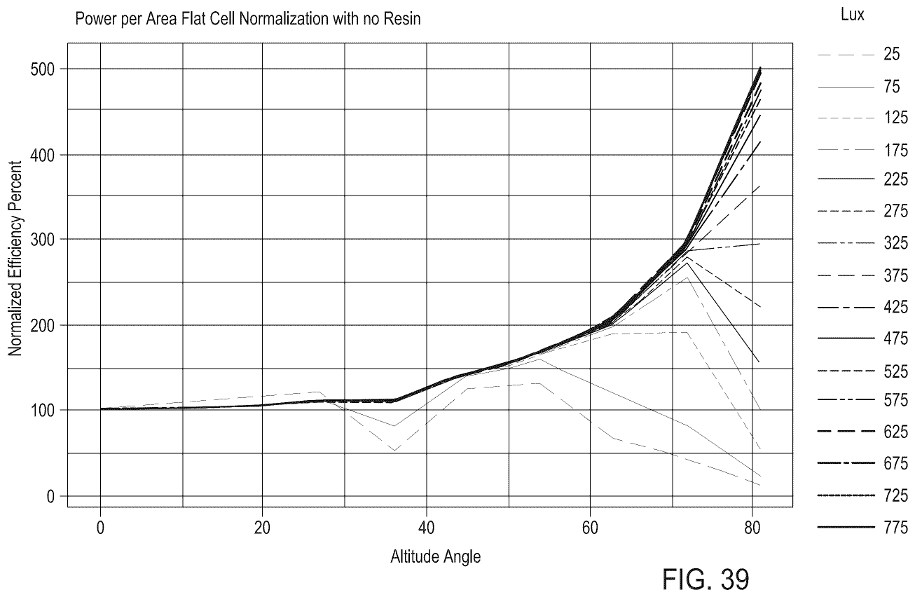

FIG. 39 shows normalized power per area (PPA) for a base cell in the resin container. The maximum PPA for the PV cell is around 5 W/m² when the cell in nearly vertical. This shows similar results to FIG. 16, as the maximum PPA for that uncovered cell was also around 5 W/m².

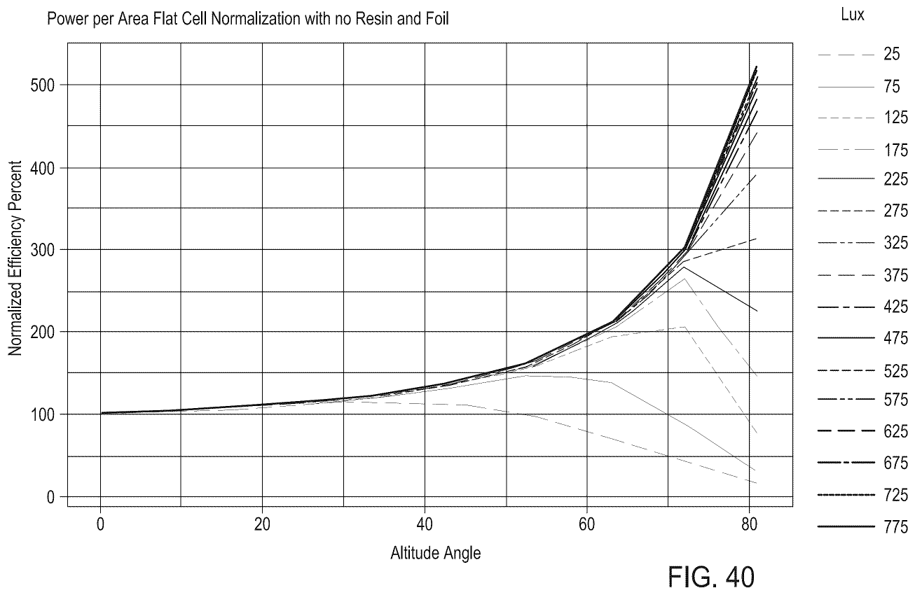

FIG. 40 shows the result of covering the container in aluminum foil. This ensures the container will not absorb any light and deflective it up back towards the cells. This results in the maximum PPA being a little over 5 W/m² at 81 degrees from the horizon. The results are not drastically different from FIG. 39 because the cells are facing upward, towards the light. The light reflected by the foil has a small impact on the upward facing cells. Further figures and charts with foil will be normalized to flat cells in the foil setup as there is a small increase in PPA with using foil.

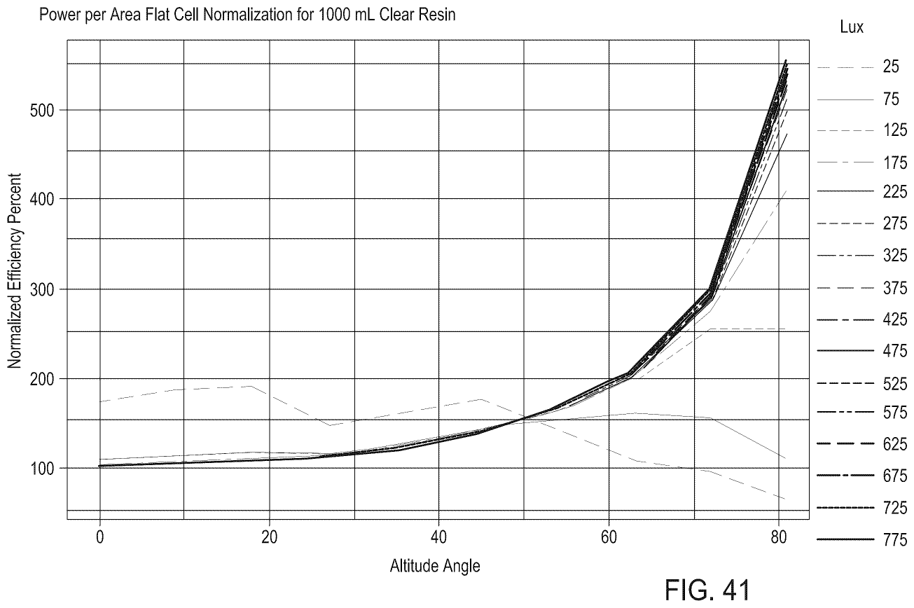

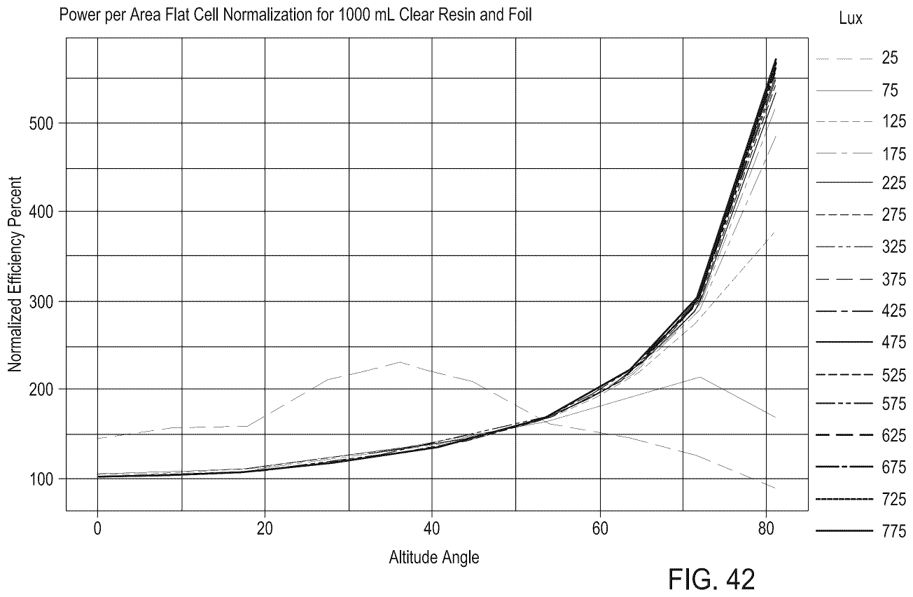

FIGS. 41-42 show the PPA for the maximum amount of resin used with and without resin respectively. The foil test shows a small increase in PPA compared to no foil again as seen in earlier tests. The lower lux intensities, such as 25 and 75 lux, show odd behavior compared to the higher intensities. This is a result from the characteristics of the resin used. The resin is not completely transparent and smaller light intensities have a problem reaching the cells for higher angles. At smaller angles, the light is not diffused as well and easily shines on the flat cell.

The tests show that a diffusive material, such as resin, can save space when using PV cells, therefore, improving power per unit area significantly. The resin allows for light to be diffused throughout the container and to be shared across cells. The resin also allows for the cells to be positioned in ways such that the PPA can be maximized. Maximizing the PPA will allow for more cells to be used in a smaller area and to allow more power from the same amount of space.

### Experiment 9: PV Stacking w/ Resin

Experiment 8 shows the benefit of using resin to maximize the power per area of the solar cell. The resin allows for the soft light to be spread throughout the container, powering multiple cells with necessarily needing direct light.

This experiment shows the potential for using multiple layers of PV cells in varying configurations to maximize the PPA of the entire setup. The purpose of this is to create more power using the same amount of land, resulting in more efficient power production.

### Methods

This experiment uses the same setup as in Experiment 12. The cells are placed in a resin bath of 1000 mL and the bath in covered in foil. Three separate tests were ran with the PV cells in different configurations.

The first test set the PV cells in the same way as in Experiment 12. The cells were facing upwards and rotated in 9 degree intervals. The second test placed the cells on the bottom side of these holders. The light was reflected off the container and reached the upside down cells from the bottom. The third test placed two cells at the bottom of the container with the resin over them. The cell holders were in the same position as the first two tests and rotated in the same manner. The purpose of the holders was to block the light where the face up and face down cells would be.

The power produced by each test were added up and PPA was calculated. This number was then normalized to the PPA of a flat PV cell in the container with no resin.

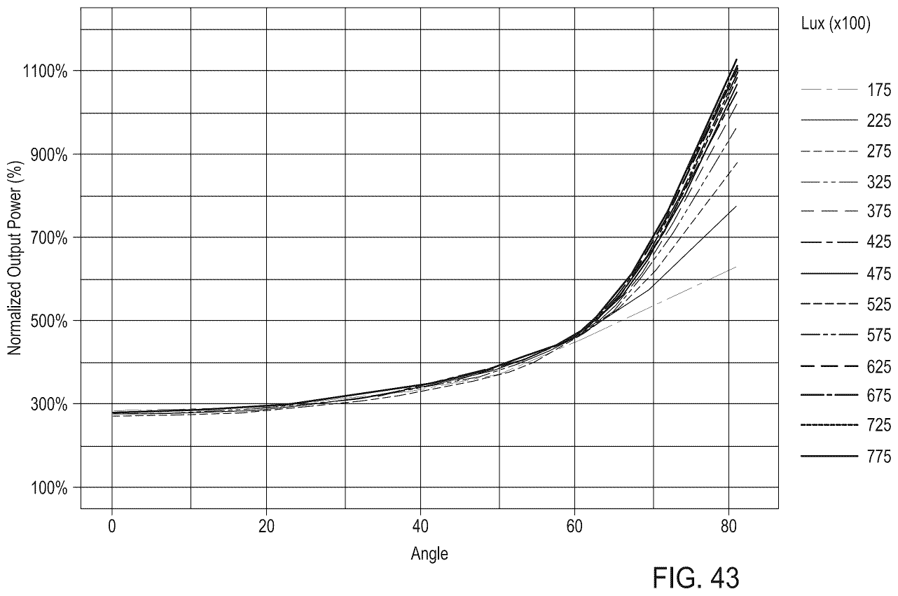

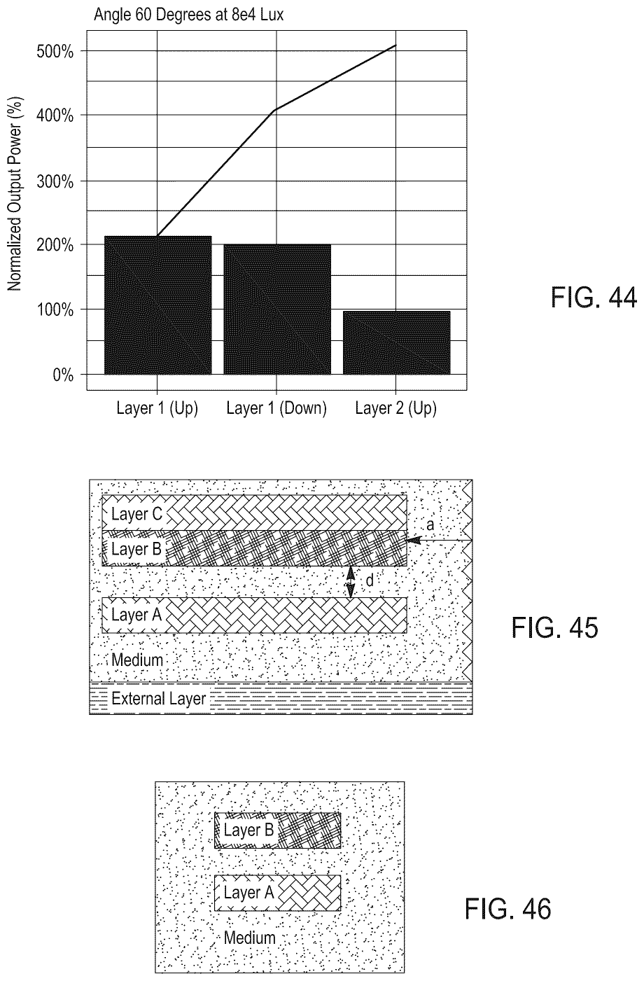

FIG. 43 shows the PPA percentage compared to a flat cell being at 100%. This figure shows that the light can be used to power three different layers of cells to increase the PPA of a cell up to 11 times at higher angles. Even at small angles, using layered cells shows an increase in power produced. This graph shows that the stacking of cells is beneficial in any scenario when using resin.

FIG. 45 shows schematic of three layers (Layer A, B, and C) selected from a list of PV cells, dielectric material, and reflective material. In some embodiments, Layers A, B, and C are PV cells, wherein Layers A and Layer B face each other. Layers B and C are positioned facing away from each other. The spacing between layers A and B is d to allow light to propagate between them. The ratio of spacing, d, and total light intake cross section inside the EMEC, a, can be optimized.

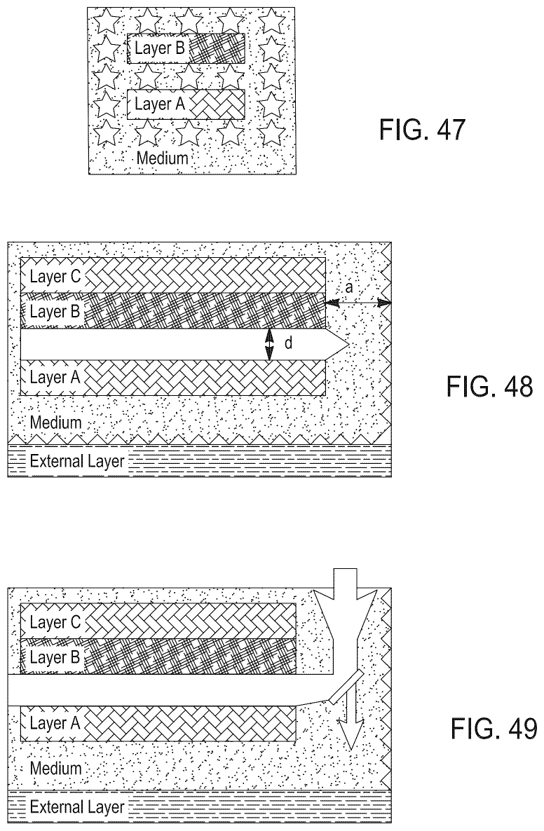

The layers are disposed in a medium. As shown in FIG. 46, the medium can change radially and/or distally inside the EMEC. Some of the properties of the medium include transparency, diffusivity, specific heat, viscosity, freezing point, boiling point, and, absorption. The transparency is within a range 0 to 1, where 0 means no transmission. In some embodiments, medium properties are a function of electromagnetic radiation wavelength. In some embodiments, as shown in FIG. 47, the medium is doped with spacers, marked as stars, whose goal is at least one of the following: 1) to reduce the total weight, 2) to determine the spacing d, and 3) to diffuse the electromagnetic radiation. In some embodiments, the spacers, are air bubbles. In some embodiments, the spacers are clear plastic pellets of (known) uniform diameter. In some embodiments, the medium is a flexible material such as silicon or a gel. In other embodiments, the medium consists of inflexible materials once hardened.

In some embodiments, the internal surface of the EMEC is coated by a reflective material, as illustrated by black triangles in FIG. 48. In this embodiment, the spacing between neighboring PV cells (Layers A & B) is filled with a waveguide of thickness d. The waveguide intake light cross section is intended to capture light with cross section a, propagating in both directions (top to bottom and bottom to top) in the medium. In other embodiments, as shown in FIG. 49, reflective 28 and or diffusive surfaces are positioned near the spacing between neighboring PV cells (Layers A and B) whose purpose is to reflect at least a fraction of the propagating light. The reflected and/or diffused light will then propagate between Layers A and B and is converted to electricity. One example of the reflective surface 28 is a mirror. One example of the diffusive surface is an etching inside the medium. The etching can be created after the hardening of the medium (e.g., epoxy resin+hardener) using laser bubblegram fabrication techniques. A bubblegram (also known as laser crystal, 3D crystal engraving or vitrography) is a solid block of glass or transparent plastic that has been exposed to laser beams to generate three-dimensional designs inside.

In one embodiment, the medium at least partially changes properties. In one embodiment, the medium includes layers of reflective liquid crystal surfaces whose macroscopic properties can be changed under various electric or magnetic perturbations. In some embodiments, the medium can change phase, for instance, from liquid to solid and back to liquid again. For instance, a water-based medium can be cooled to below freezing point temporarily for different dielectric properties.

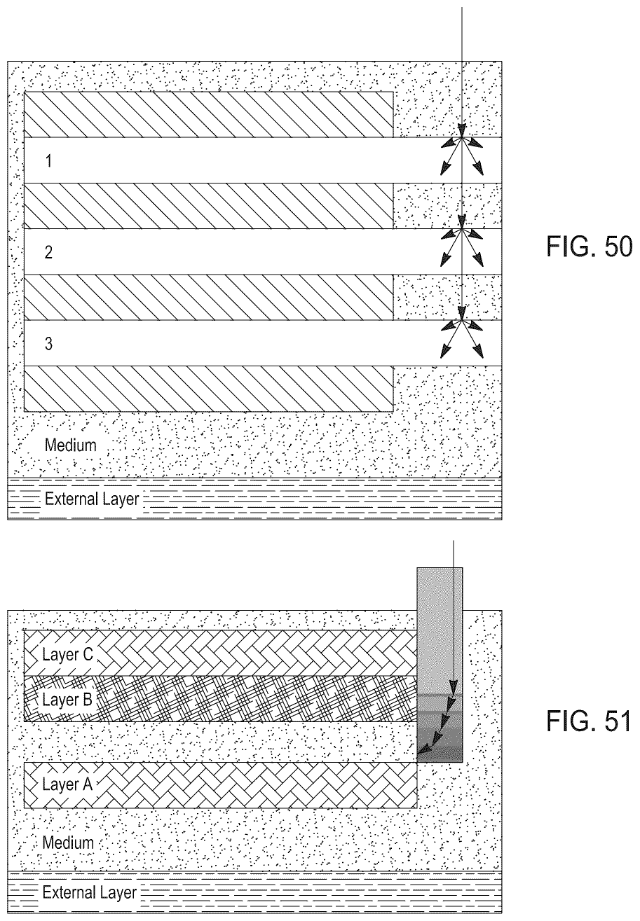

The spacing between Layers A and B can also be filled with diffusing waveguides, as depicted in FIG. 50. In such embodiments, the diffusing waveguide scatters the incoming electromagnetic radiation. Some of the scattered electromagnetic radiation is then propagated within the waveguide and converted to electricity by Layers A and B. In yet other embodiments, similar to FIG. 46, the medium is divided between distally- and radially-varying dielectric material of differing refractive indices, as shown in FIG. 51. The purpose of such waveguide with gradient refractive index profile is to address individual PV cell spacings. In such embodiment, the medium is a waveguide matrix within which light propoxates along an intended path. The purpose of the varying refractive indices is to direct the light by bending it at the interface of neighboring dielectric materials of varying refractive indices.

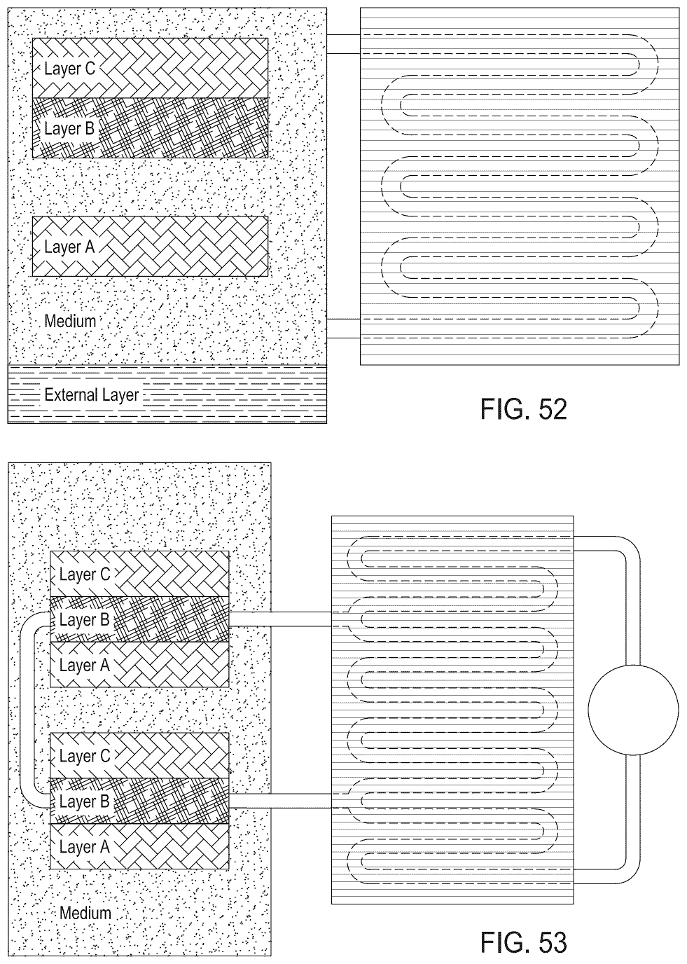

In some embodiments, the medium is of liquid phase and can be circulated. Some of the advantages to liquid medium include: 1) heat dissipation, 2) medium replacement, and 3) PV cell replacement. As shown in FIG. 52, the medium is circulated between the EMEC enclosure and a piping system in order to transfer heat from inside the enclosure and discharging it to the surrounding air (or other surrounding media). Other methods of heat transfer include: convection, conduction, thermal radiation, and evaporative cooling. In one embodiment, the PV cells of the EMEC are coated with dielectric insulating material and submerged in a polar liquid such as deionized water with relatively high specific heat. In this embodiment, the EMEC's transparent insulating body consists of a circulatable polar liquid and the insulating dielectric material. In some embodiments, the liquid is conductive and polar such as water, while in other embodiments, the liquid medium is an insulator, such as epoxy resin. In yet other embodiments, the EMEC medium is a diffusive gas, such as smoke and water vapor, which can be circulated for heat transfer.

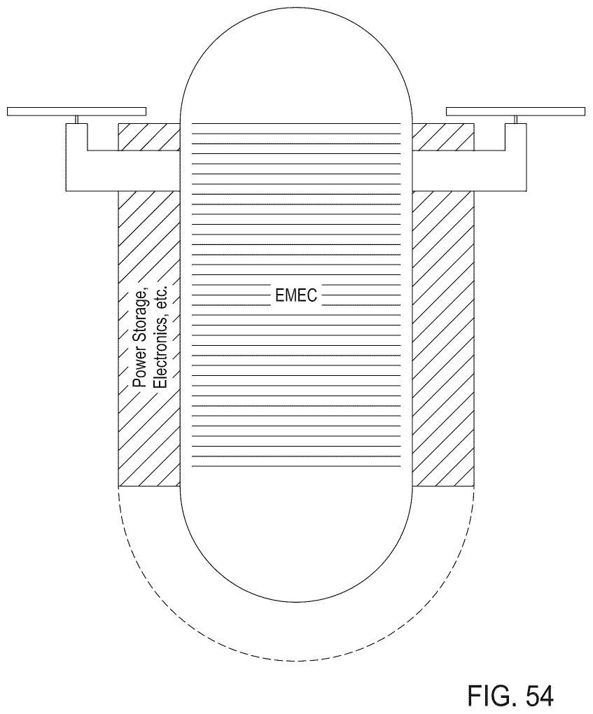

In other embodiments, as shown in FIG. 53, the cooling mechanism involves circulating an evacuated tube of clear or reflective surface 28 partially filled with a fluid such as alcohol or water. Due to the low pressure, the fluid inside the pipe may boil when it absorbs heat from the air inside the EMEC enclosure. The fluid and/or vapor circulates through the pipe between the PV cells inside the tube. Once outside the EMEC enclosure, the fluid (and/or vapor) is cooled by the air outside the enclosure (and condenses). The (condensed) fluid then returns to the bottom of the enclosure and the cycle repeats. In some embodiments, the heat transfer process is active using an air compressor or a fluid circulator pump. In other embodiments, the heat transfer system 31 includes a temperature regulator whose purpose is to regulate the temperature of the PV cells and/or the medium for optimized PV cells power output. This embodiment aims to provide the appropriate temperature for the PV cells whose efficiency is a function of ambient temperature. In some other embodiments, the PV cell and/or the medium temperature is kept at sub-zero degrees Celsius for optimized power output.

In some embodiments, the EMEC is fabricated layer by layer. Examples of such fabrication process include: 3D printing, chemical vapor deposition, roll-to-roll fabrication, laser etching, and chemical curing such as thermosetting and radiation setting.

In some embodiments, the electromagnetic energy intake cross section is modified to enhance or reduce the amount of incoming energy. In some embodiments, the aperture setting is done using active components such as mechanical gates. In some embodiments, the energy intake is controlled with a layer of liquid crystal.

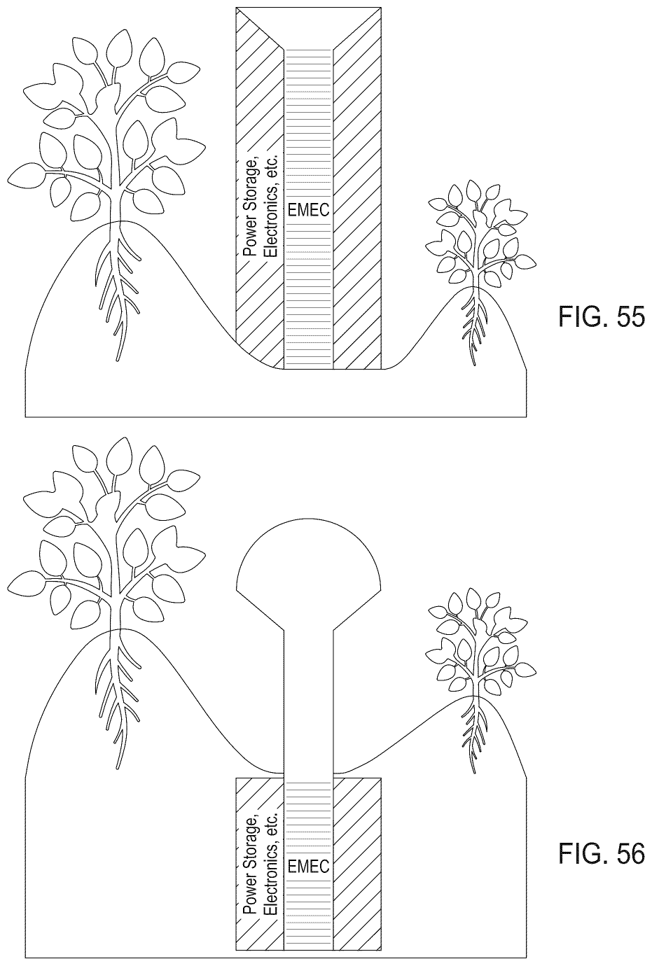

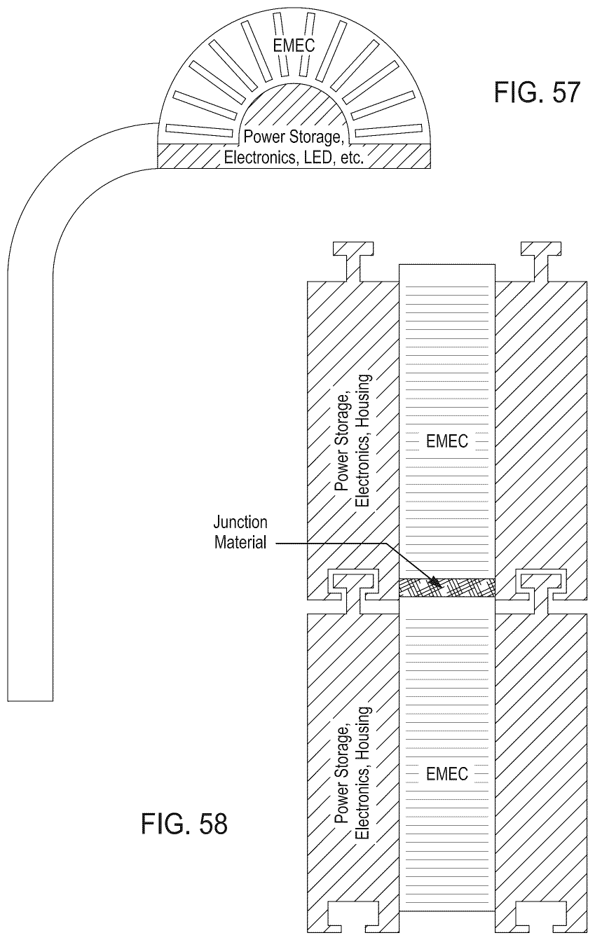

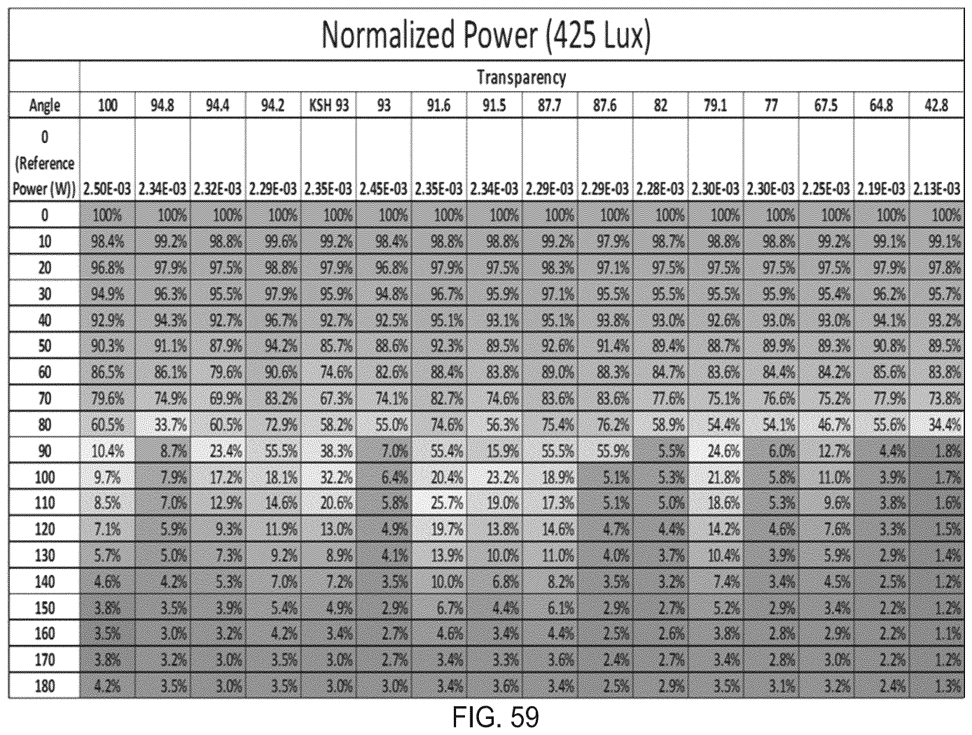

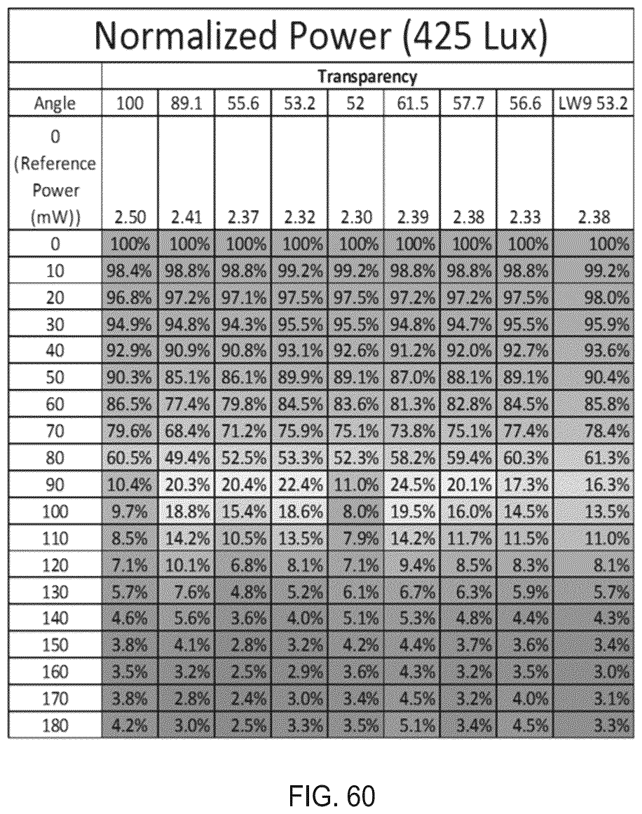

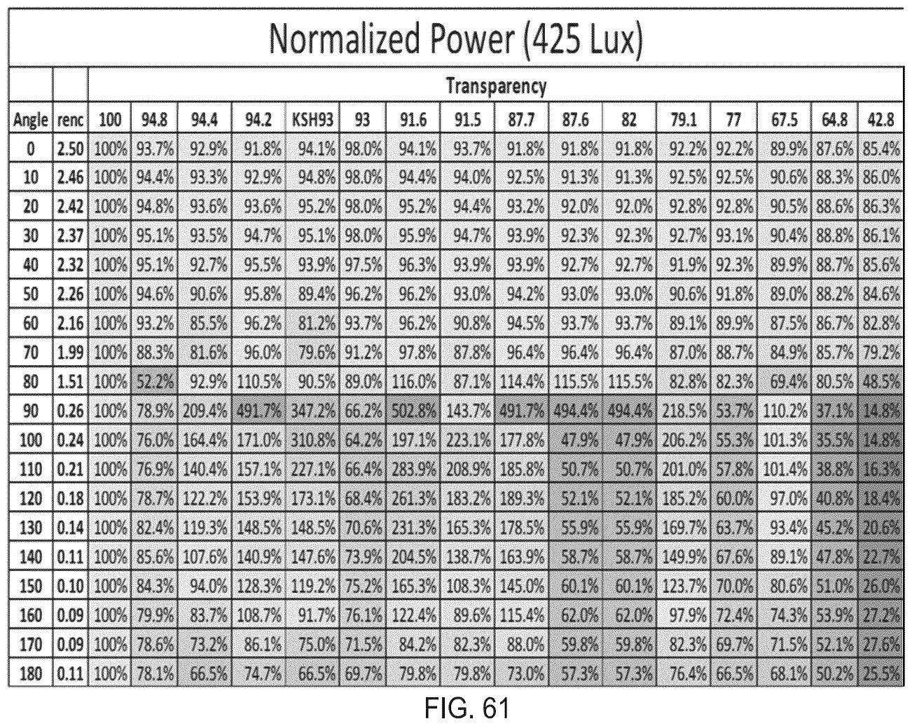

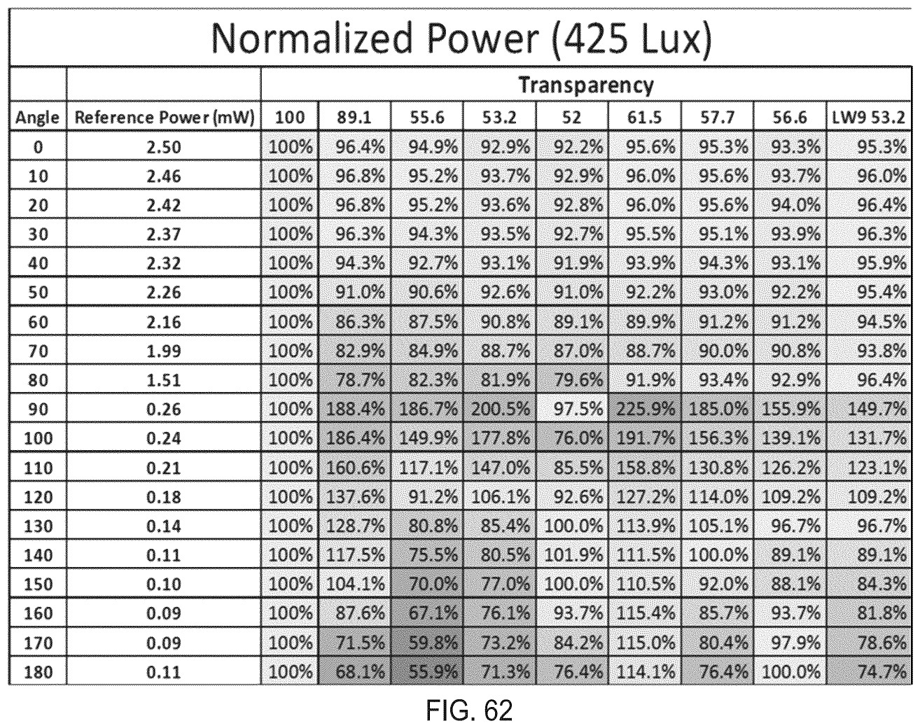

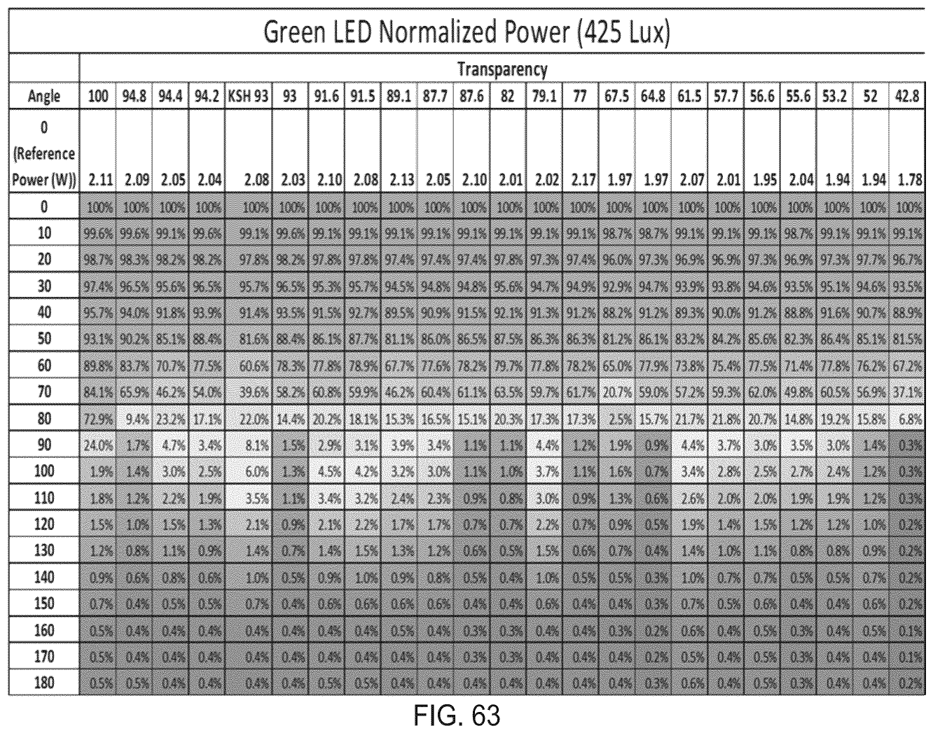

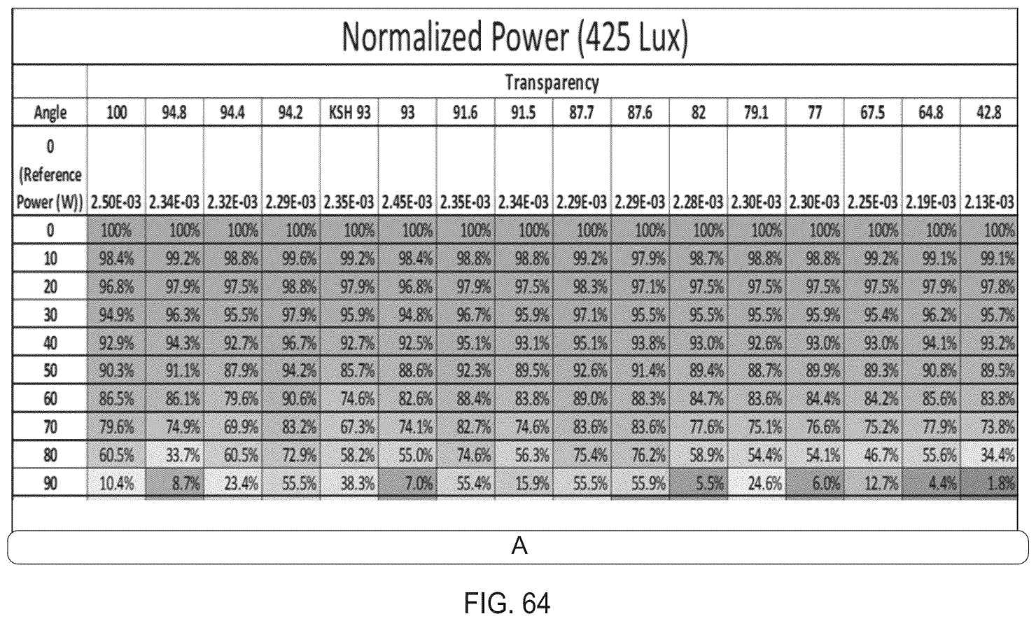

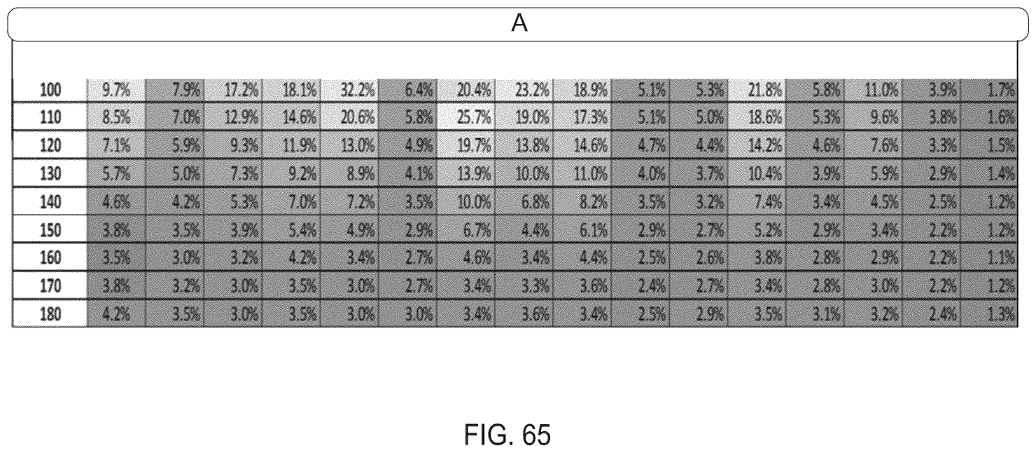

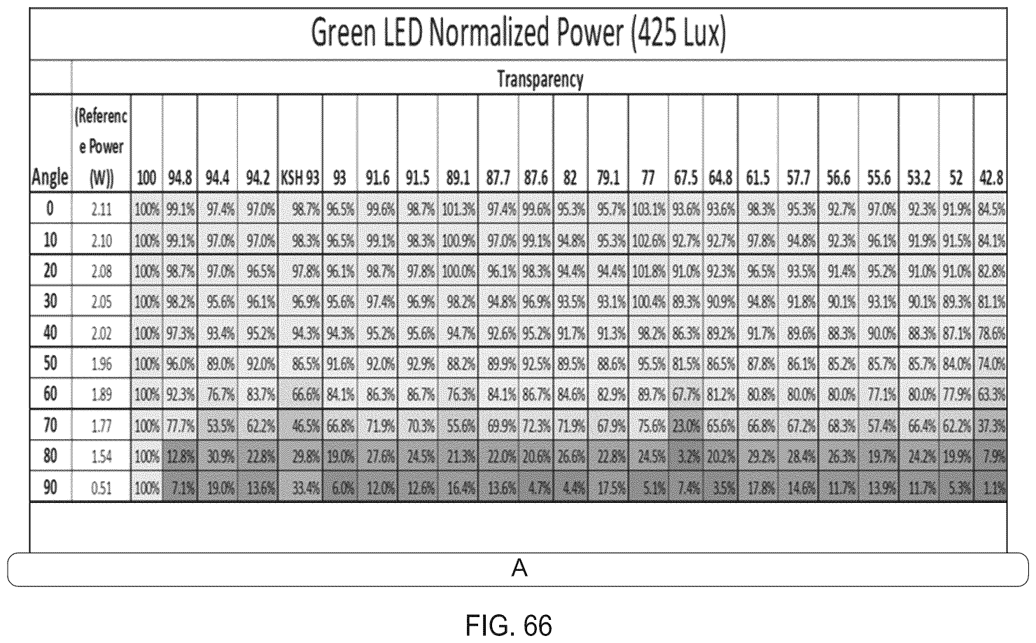

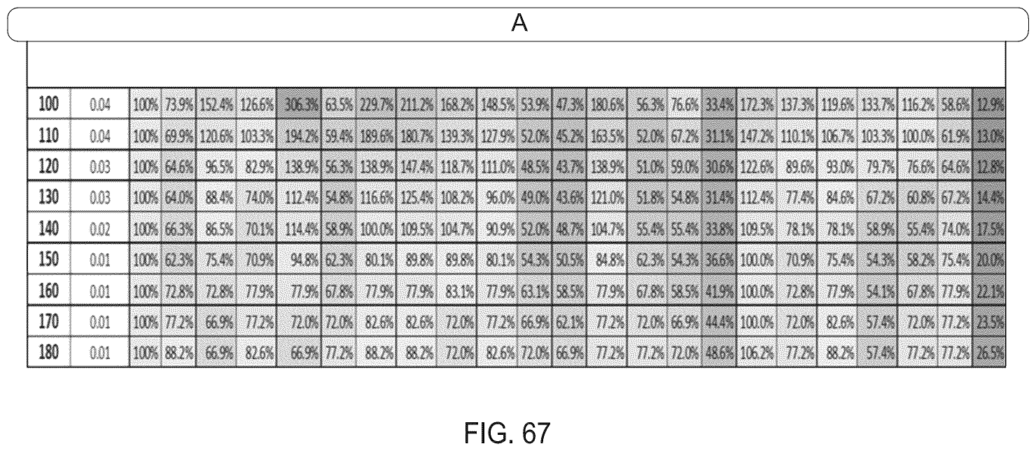

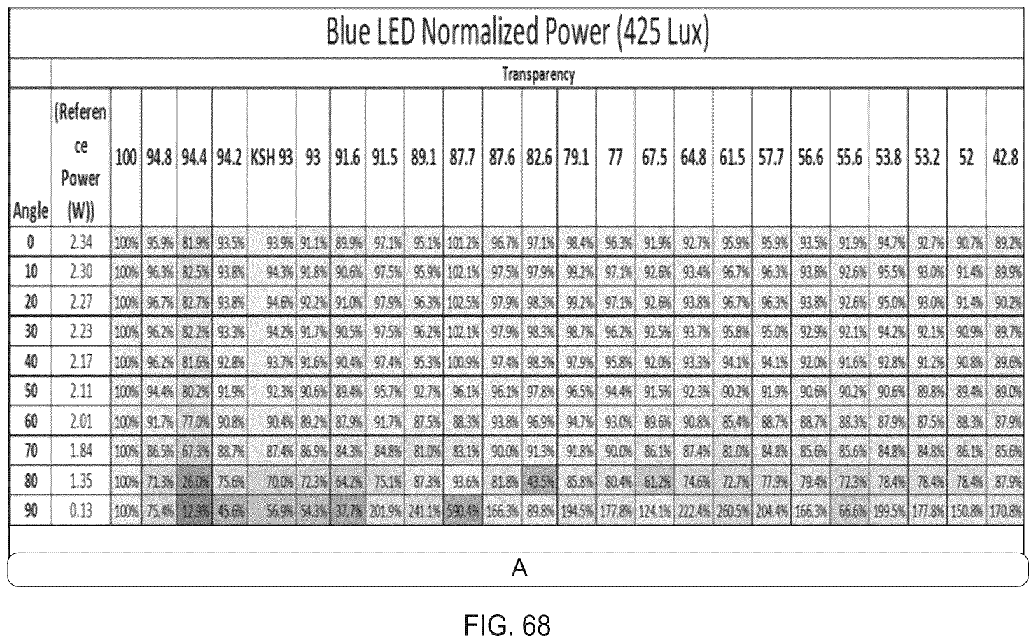

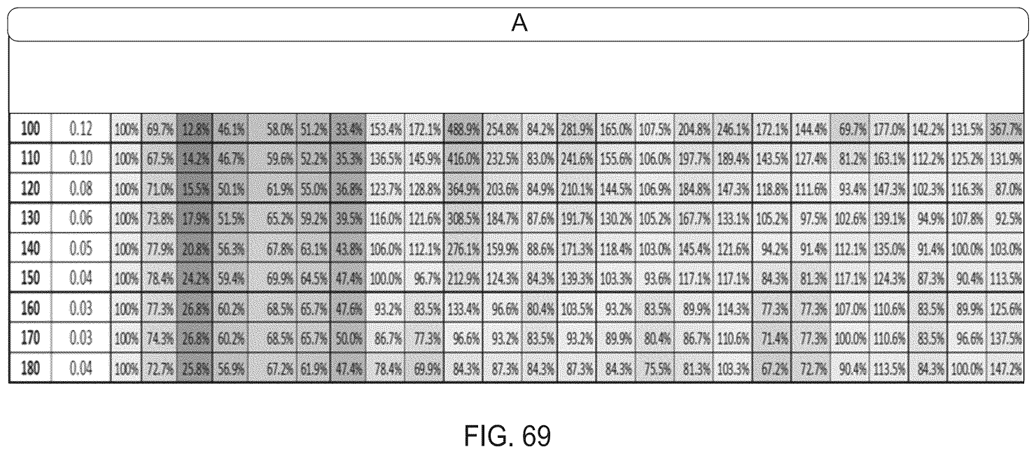

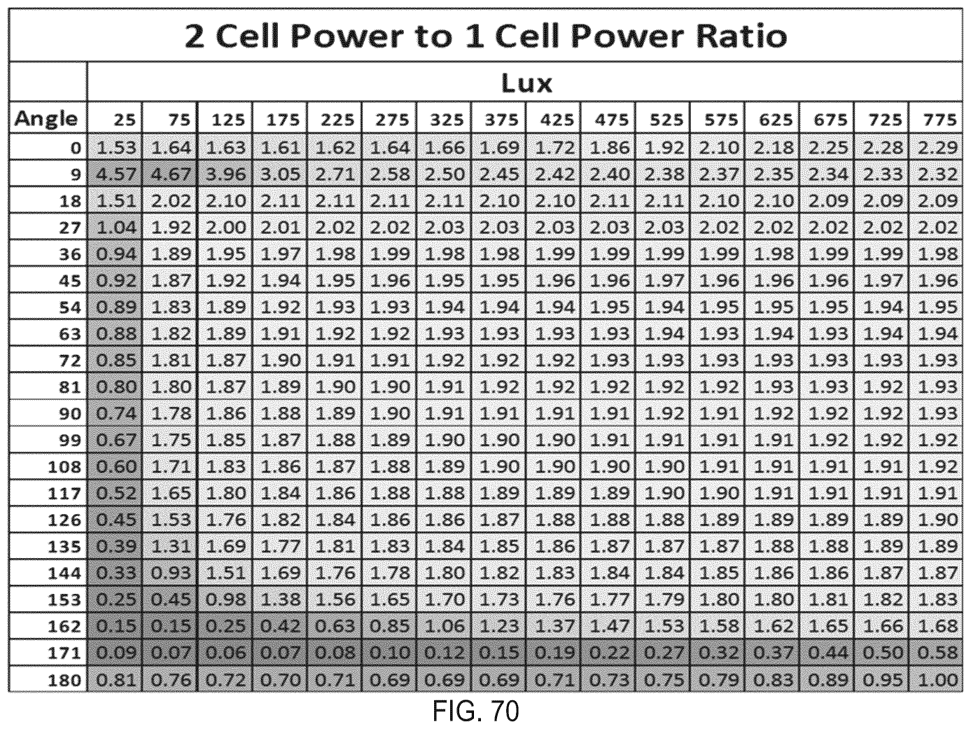

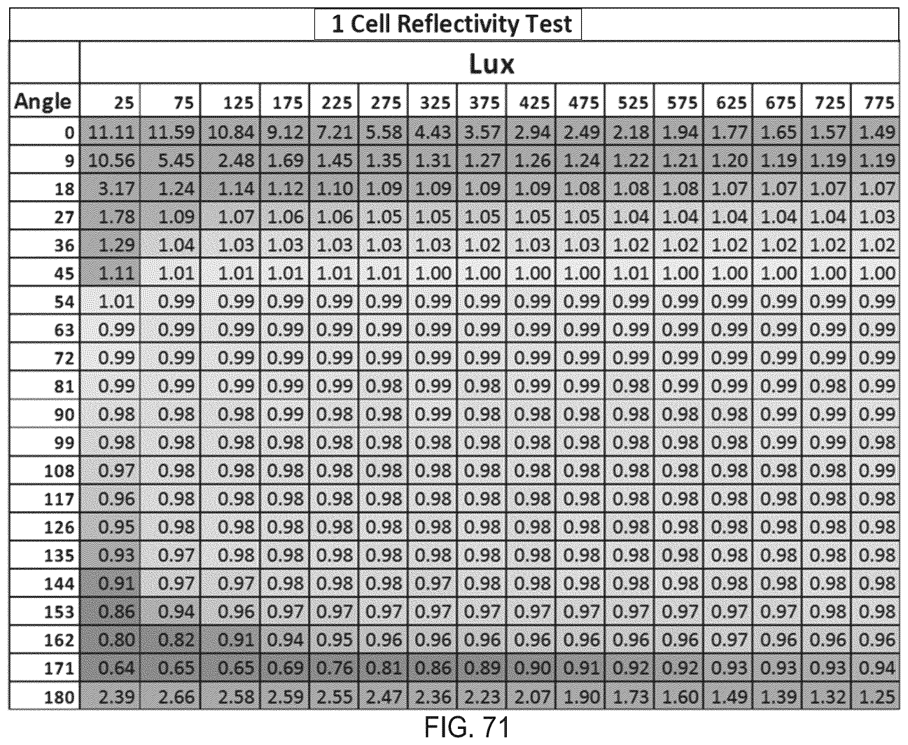

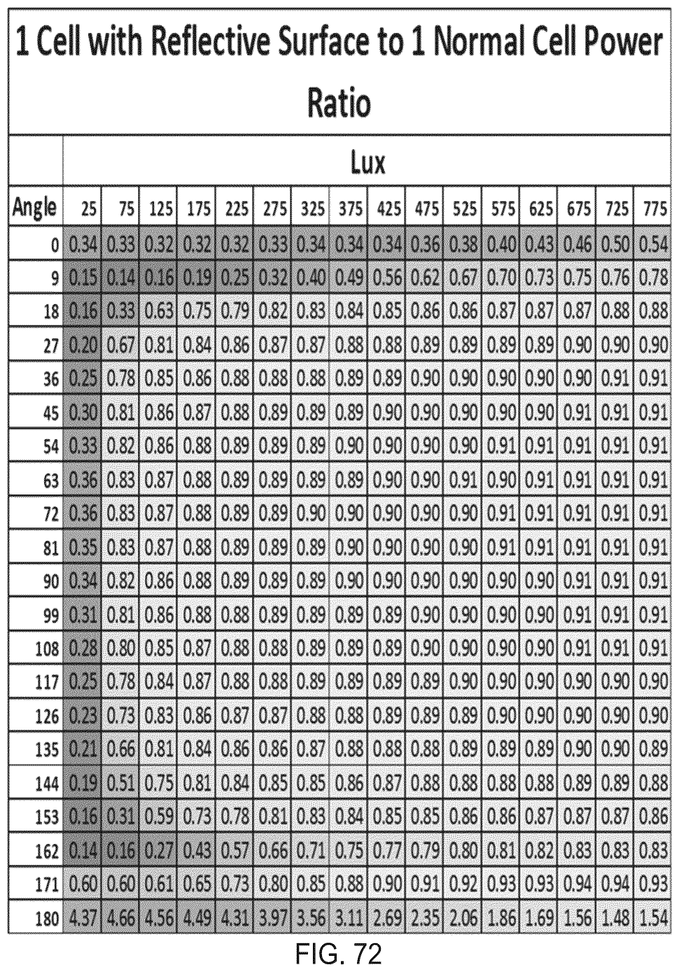

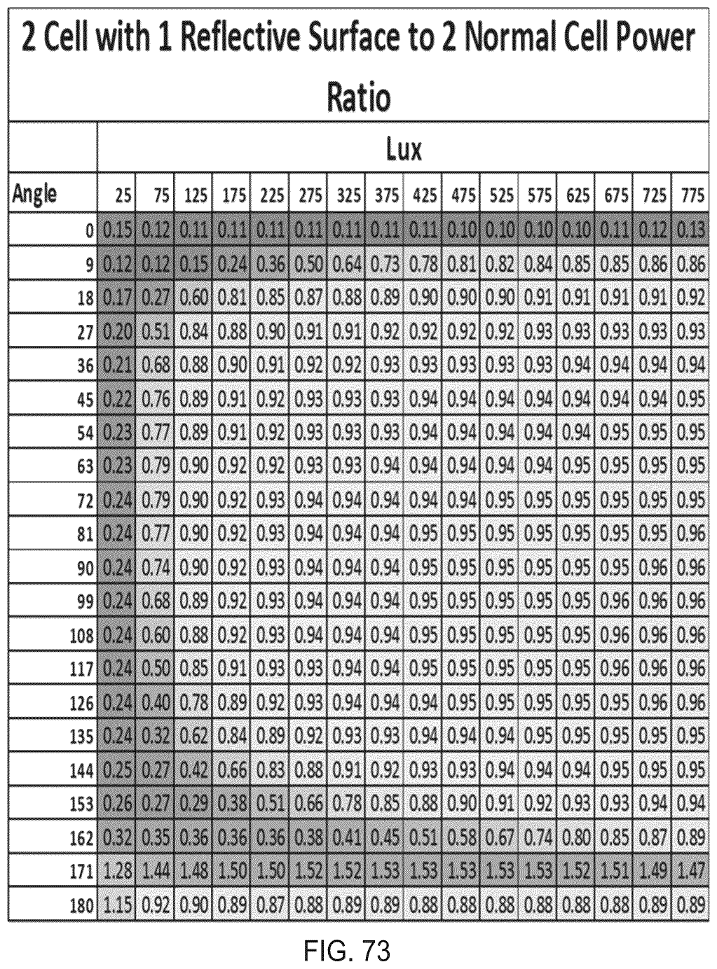

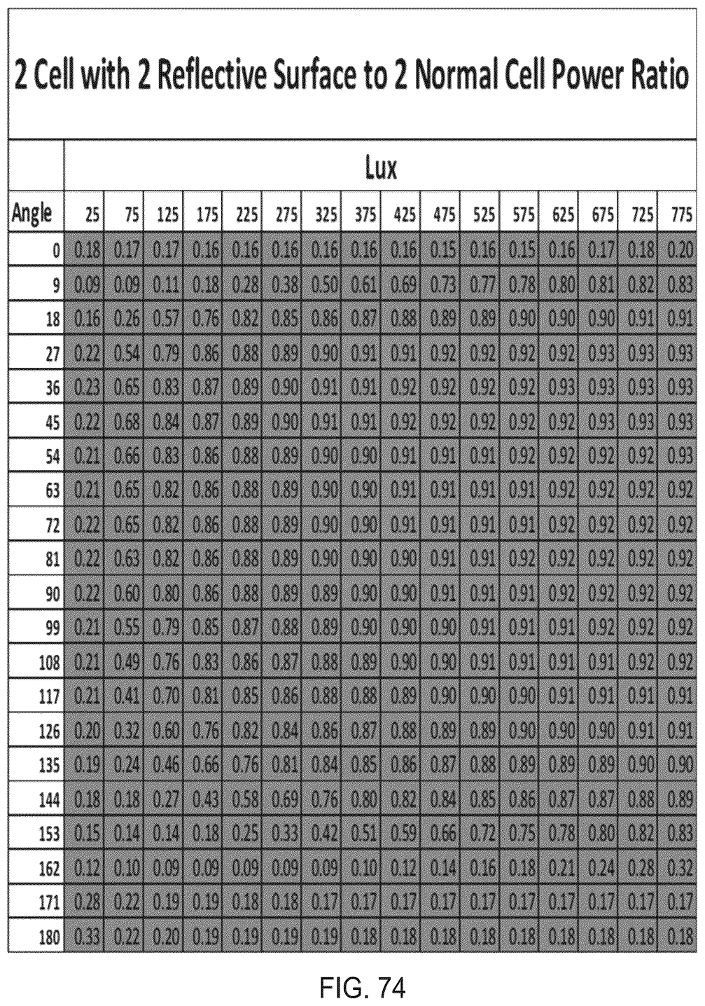

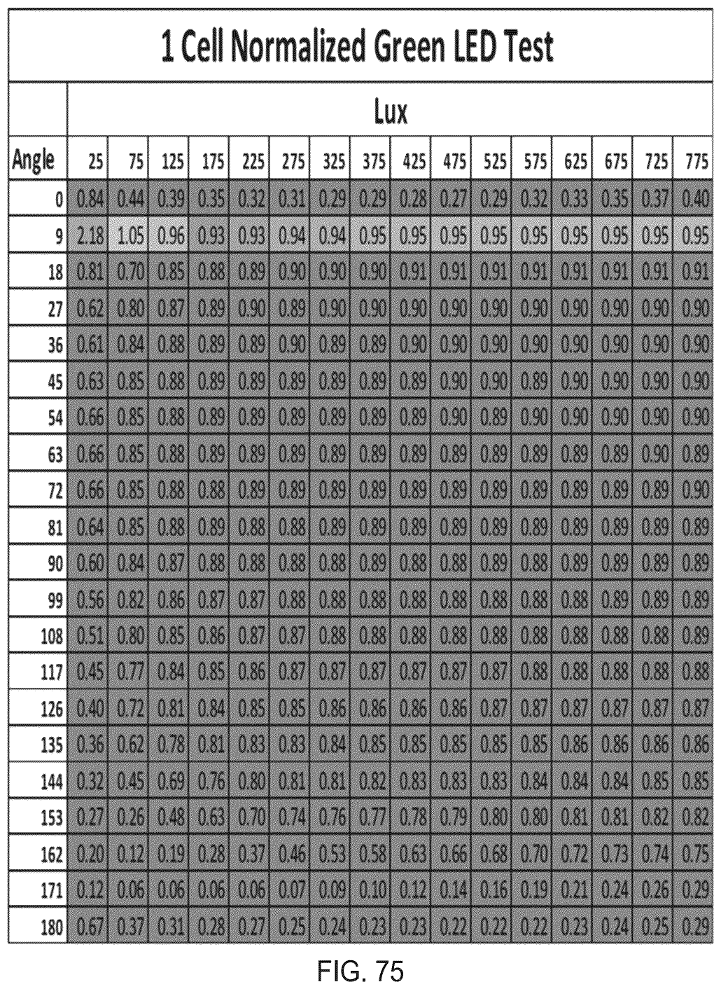

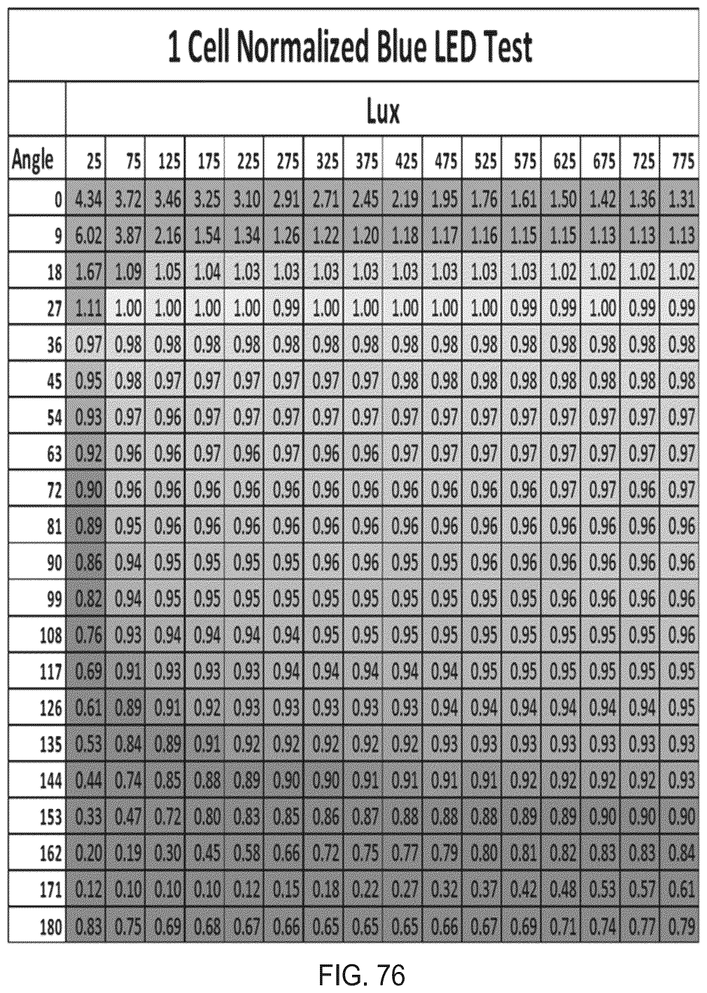

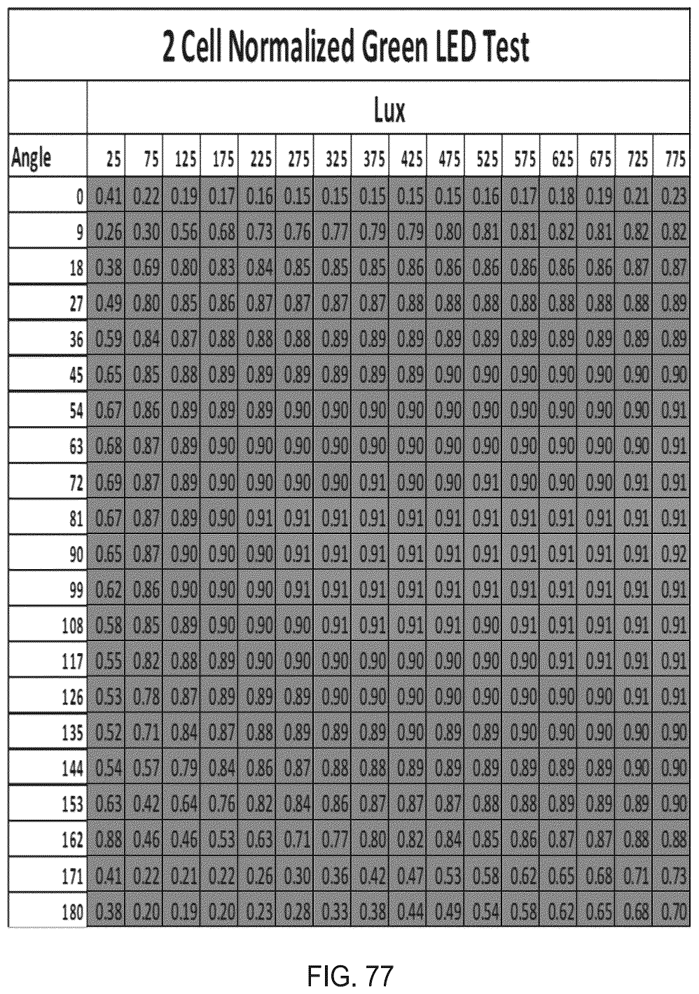

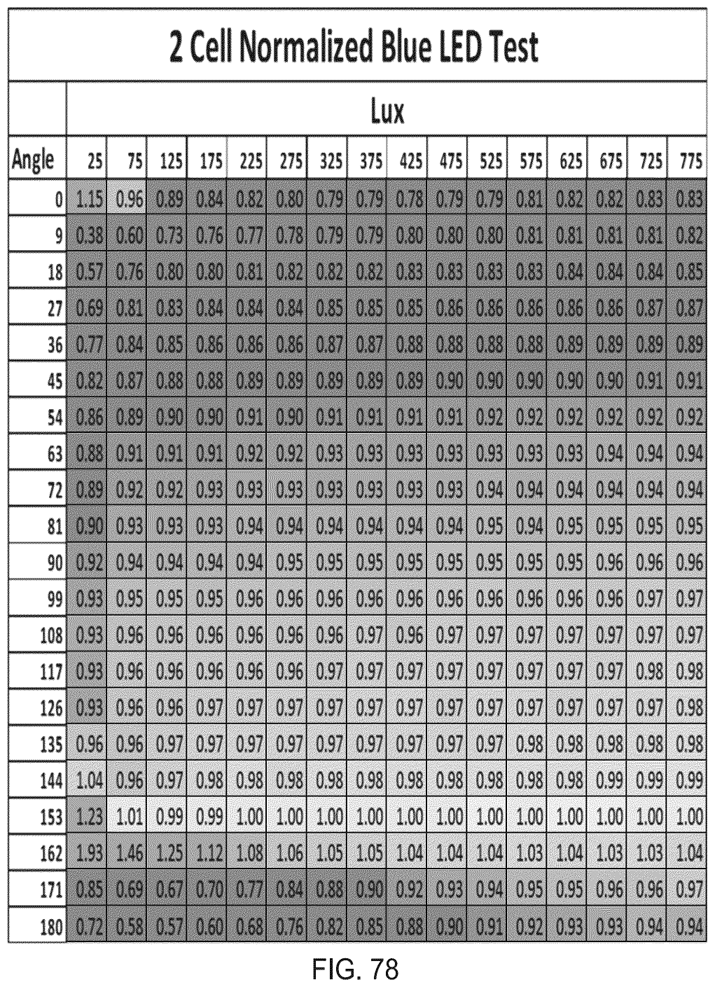

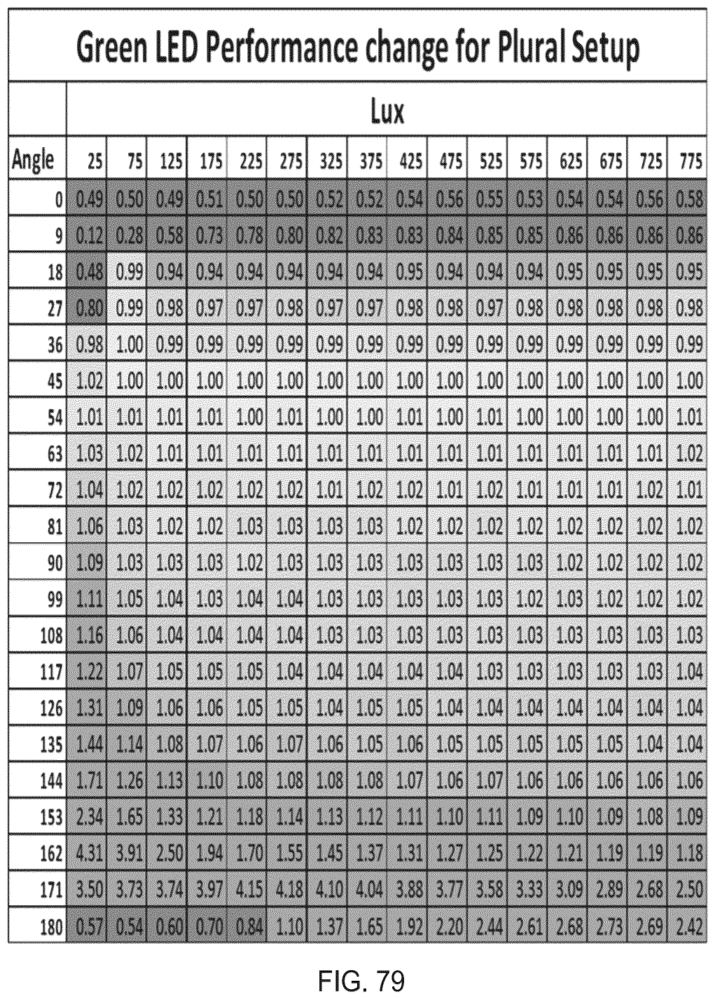

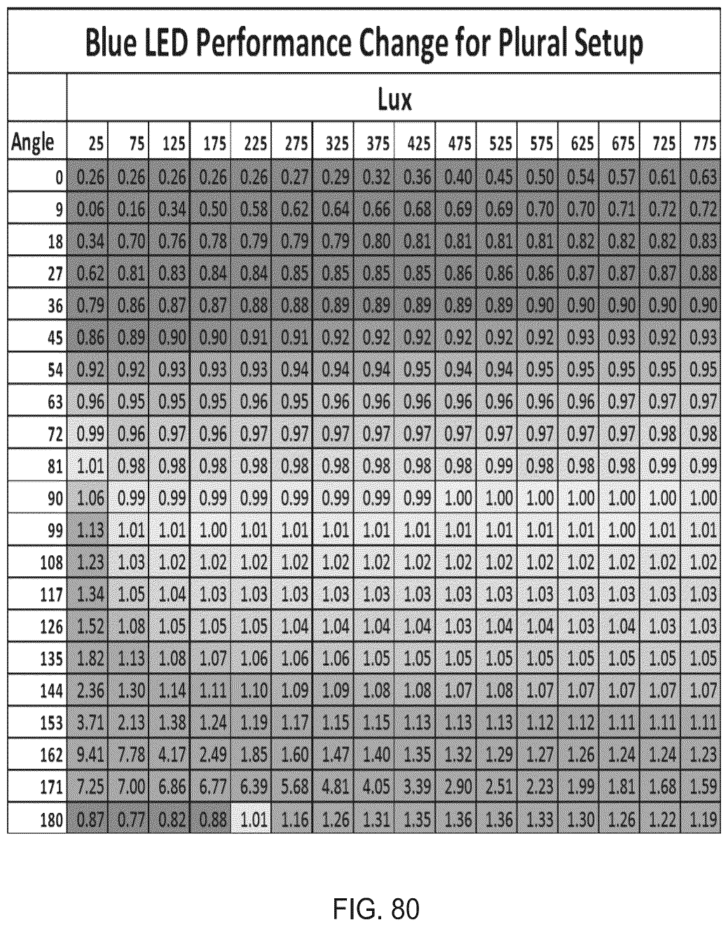

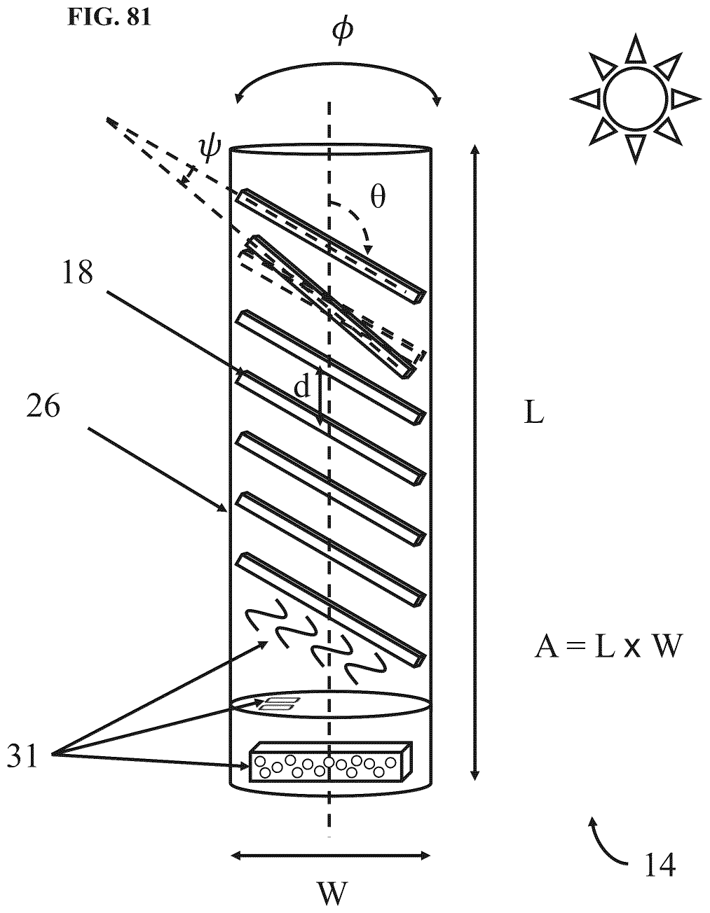

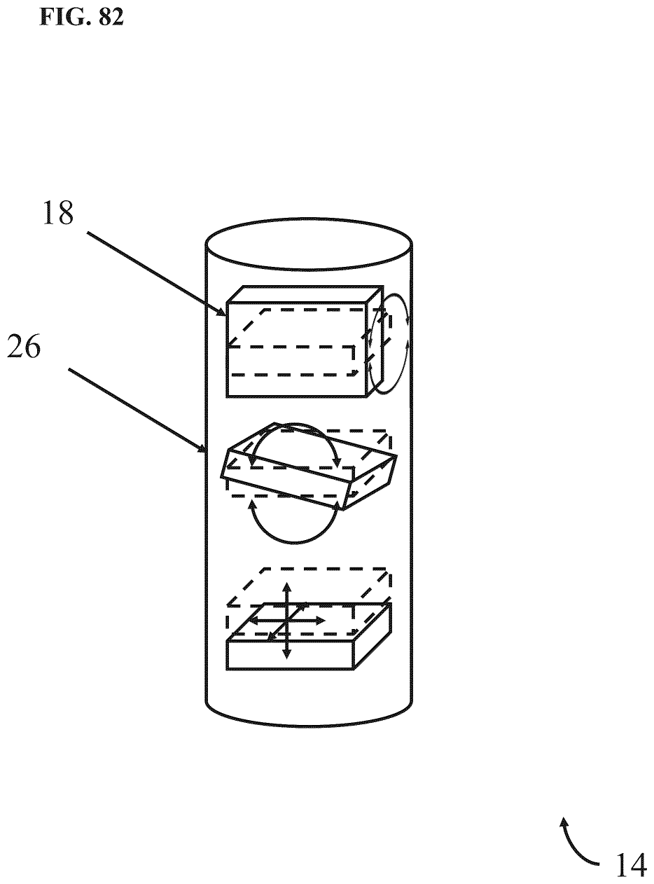

According to the principles of the present teachings, electromagnetic energy converter system and/or electromagnetic energy converter 14 has been disclosed that is particularly suited for use in any one or a number of applications, including, but not limited to, the efficient delivery and/or storage of transmitted power. In fact, electromagnetic energy converter system and/or electromagnetic energy converter 14 can be used, for example, to power compact solar structures, microelectromechanical devices (MEMS), electronic circuits and devices, transportation elements (e.g. buses, trains, cars, aircraft, and the like), space and long distance applications (e.g. satellites in orbit or aircraft in general (airplanes, UAVs, etc.)). The principles of the present teachings replace bulky and fragile solar panels with a reliable, resilient, compact, lightweight device that is mobile and efficient. Some of the applications of the EMEC include:
a. Transportation: as shown in FIG. 54, the EMEC can be implemented into the design of transportation devices such as a UAV. The EMEC will convert incoming radiation (solar radiation and/or concentrated source of electromagnetic energy, such as a laser) into electricity which can be stored and consumed aboard. Similarly, the EMEC devices can be designed with optimized aerodynamics and can be installed aboard vehicles, such as trucks and vessels.
b. Farms: unlike traditional solar farms which occupy vast surface areas to generate power, the compact EMEC, as shown in FIG. 55, can be implanted on farms, between crops, to convert solar radiation to electricity. The electrical power can be stored and consumed onboard, for example for lighting, and or transferred to the power grid.
c. Urban applications: due to limited available land in urban areas to install traditional solar panels, compact EMEC devices can be used to harvest electricity. Solar radiation can be collected and directed into an EMEC enclosure by a waveguide. In one embodiment, a shown in FIG. 56, the EMEC enclosure and electronics are installed underground. Another benefit of underground EMEC installations is thermal management. The relatively-constant soil temperature, specially at depths greater than 30 ft, can be used to regulate the EMEC temperature. In another embodiment, the EMEC is used to convert solar radiation to electricity to power urban lighting structures, such as light posts, as shown in FIG. 57. Similarly, as shown in FIG. 58, multiple EMEC devices can be coupled together. Two important advantages of this design are: 1) easy installation, and 2) easy maintenance. In one embodiment, the EMEC devices are wrapped around an existing light post. In some embodiments, the junction between neighboring EMEC devices is filled with a junction material to manage the propagation of light between EMECs. Faulty EMECs can be easily replaced.

Here, the definitions of some of the terms are re-stated for clarity:
a. Transparent material: a transparent material refers to a type of material that transmits at least in part of the electromagnetic energy spectrum. Transparency can range between 0 (no transmission) and 1 (100% transmission). The non-transmitted electromagnetic energy can be absorbed by the material and/or deflected.
b. Diffusivity: materials with optical diffusivity diffuse or scatter electromagnetic radiation with or without absorption. Repeated scattering of the electromagnetic radiation can change its direction, often referred to as ‘random walk’. Diffusive material can further be diffractive, also known as ‘diffractive diffuser or homogenizer’ to diffract (and refract) an incoming monochromatic electromagnetic radiation for a particular spatial configuration and/or intensity profile. Diffusivity can range between 0 (no scattering) and 1 (complete reflection and or absorption).
c. Insulating material: an insulating material is a dielectric material with known dielectric constant and refractive index (i.e., finite real and imaginary dielectric constant). In some embodiments, the insulating material may also serve as a thermal insulator to reduce heat transfer between the EMEC medium and the surrounding environment. In other embodiments, the insulating material insulates the PV cells from moisture and other conductive and/or oxidizing agents.
d. Plurality of electromagnetic (EM) energy converting cells: electromagnetic (EM) energy converting cells comprise of a photoelectric layer that converts electromagnetic energy to electricity. This layer can be made of a material selected from a list of conductors (e.g., copper), semi-conductors (e.g., silicon crystals and quantum dots), inorganic materials, and organic materials (e.g., perovskite and organic light emitting diodes). The electric current generated in the photoelectric layer of the electromagnetic (EM) energy converting cell is transferred by conductive poles/terminals. The term ‘plurality’ refers to more than one electromagnetic (EM) energy converting cell. The present teachings further exclude a plurality of electromagnetic (EM) energy converting cells wherein electromagnetic (EM) energy converting cells are all positioned at relative angle, α=0, and electromagnetic (EM) energy converting cell spacing d=0. The excluded structure describes a traditional solar panel wherein all PV cells are oriented facing up and positioned in a single plane. The plurality of electromagnetic (EM) energy converting cells can be electrically coupled. In some embodiments, the coupling between the electromagnetic (EM) energy converting cells is done in a series configuration. In other embodiments, the electromagnetic (EM) energy converting cells are connected in a parallel configuration. In yet other embodiments, the electromagnetic (EM) energy converting cells are individually addressed (harvested), while in other embodiments, the cells are addressed as a group wherein the electrical charge from a plurality of cells of similar power output are connected and harvested.
e. Single-Piece encapsulating material: the term ‘encapsulating’ means to at least partially enclose the electromagnetic (EM) energy converting cell of the EMEC in an insulating material. ‘Single piece’ refers to a material or a plurality of materials that can transmit at least some electromagnetic energy wavelengths. In some embodiments, the single-piece insulating material holds the electromagnetic (EM) energy converting cells of the EMEC in position, such as a hardened epoxy resin, while in other embodiments, as described above, the single-piece insulating material consists of a dielectric material to cover the electromagnetic (EM) energy converting cells while the covered cells are immersed in a diffusive and/or heat-transferring liquid material. One common characteristic between the aforementioned single-piece encapsulating materials is that they all serve as a medium within which electromagnetic energy is transmitted until converted to electricity by the plurality of electromagnetic (EM) energy converting cells. Another common characteristic of the single-piece encapsulating materials is that they all prevent the flow of electric current between the positive and negative terminals of electromagnetic (EM) energy converting cells, i.e., short-circuit. In other words, the single-piece encapsulating materials are at least partially electrical insulators within which electric charges do not flow freely, even under the influence of an electric field, i.e., potential difference across the terminals.
f. Power per surface area: the term ‘power per surface area’ refers to the amount of electrical power generated over the footprint, i.e., the occupied surface area by an EMEC. Similarly, the normalized power per surface area is the ratio of EMEC power per surface area and the power output of flat cells occupying the same surface area as the footprint of the EMEC, i.e., (P/A)_{EMEC}/(P/A)_{flat cells}, under similar electromagnetic radiation and environmental conditions.

### Adjustable Electromagnetic Energy Converter:

In reference to FIG. 81, in some embodiments, an electromagnetic (EM) energy converter 14 for converting electromagnetic (EM) energy to electricity, the electromagnetic (EM) energy converter 14 comprises:
a body of transparent insulating material 26; and
a plurality of identical electromagnetic (EM) energy converting cells 18 disposed at least partially within the body of transparent insulating material 26, each of the plurality of electromagnetic (EM) energy converting cells 18 is at least partially stacked relative to others of the plurality of electromagnetic (EM) energy converting cells 18, the plurality of electromagnetic (EM) energy converting cells 18 configured to convert the electromagnetic (EM) energy to electricity; and
a heat transfer system 31,
wherein the body of transparent insulating material 26 is an integral single-piece encapsulating the plurality of electromagnetic (EM) energy converting cells 18,
wherein the body of transparent insulating material 26 is configured to separate the plurality of identical electromagnetic (EM) energy converting cells 18 and to direct or manipulate electromagnetic (EM) energy toward the plurality of electromagnetic (EM) energy converting cells 18.

In some embodiments, an electromagnetic (EM) energy converter 14 for converting electromagnetic (EM) energy to electricity is provided having advantageous construction and method of use. In some embodiments, electromagnetic (EM) energy converter 14 can comprise a photovoltaic unit having a plurality of discrete and non-coplanar, identical electromagnetic (EM) energy converting cells 18. In some embodiments, the plurality of identical electromagnetic (EM) energy converting cells 18 comprises photovoltaic cells 18, such as mono or poly-crystalline solar cells 18.

In some embodiments, a method for optimizing the power per surface area output for an incoming electromagnetic energy flux of an electromagnetic energy convertor device, the electromagnetic energy convertor device having a plurality of electromagnetic energy converting cells 18 disposed at least partially within a single-piece, at least partially transparent, insulating medium with a diffusivity, the method comprising:
adjusting the diffusivity of the medium, and
adjusting at least one of three physical parameters of the plurality of electromagnetic energy converting cells 18, the physical parameters comprising:
angles between electromagnetic energy converting cells 18 and the incoming electromagnetic energy flux, the angles ranging between 0 and 180 degrees,
angles between electromagnetic energy converting cells 18, the angles ranging between 0 and 180 degrees, and
spacing between electromagnetic energy converting cells 18.

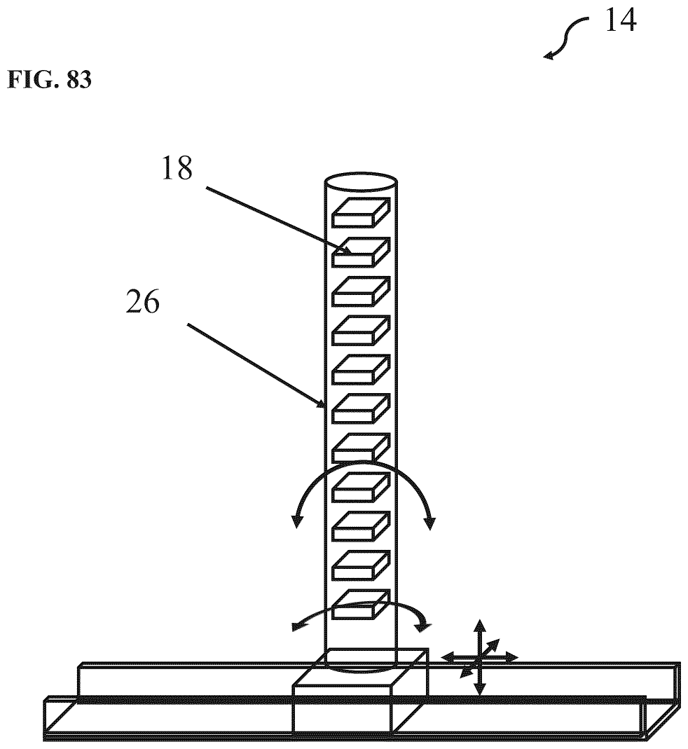

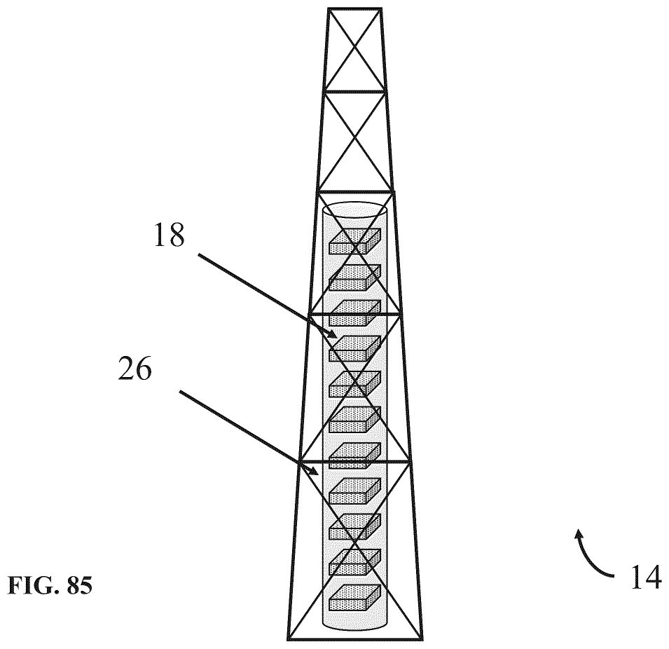

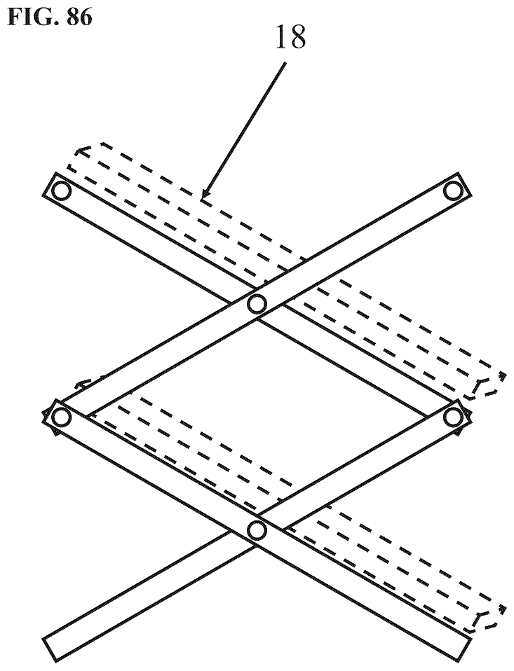

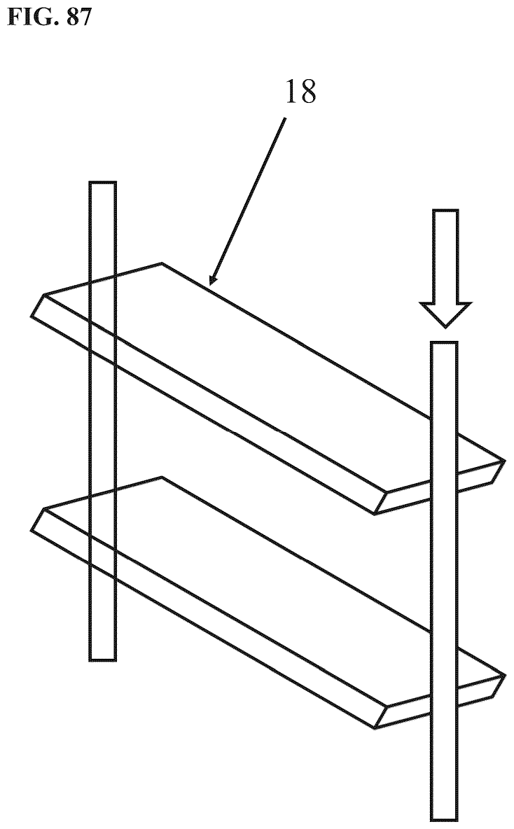

In reference to FIGS. 81-87, in some embodiments, a method for optimizing converting electromagnetic energy to electricity of an electromagnetic energy converter 14, the method comprising:
providing an electromagnetic energy converter 14 having a body of transparent insulating material 26, a plurality of stacked identical electromagnetic energy converting cells 18, and a heat transfer system 31, the electromagnetic energy converter 14 defining an electromagnetic energy collection area of the body of transparent insulating material, an orientation of the body of transparent insulating material 26 relative to an incoming electromagnetic energy, an angle between each adjacent electromagnetic energy converting cell of the plurality of stacked identical electromagnetic energy converting cells 18, an angle between the plurality of stacked identical electromagnetic energy converting cells 18 relative to the incoming electromagnetic energy, and a spacing between each adjacent electromagnetic energy converting cell of the plurality of stacked identical electromagnetic energy converting cells 18; and
adjusting the electromagnetic energy converter 14 from a first configuration to a second configuration.

In reference to FIG. 81, in some embodiments, the “electromagnetic energy converter configuration characteristics” comprise:
1) an electromagnetic energy collection area A of the body of transparent insulating material 26: in some embodiments, the electromagnetic energy collection area A of the body of transparent insulating material 26 is adjusted to increase or decrease the amount of incoming electromagnetic energy. In some embodiments, the collection area remains unchanged. In some areas, the body of transparent insulating material 26 is adjusted via changing either the width w, height h, or cross section.
2) an orientation ϕ of the body of transparent insulating material 26 relative to an incoming electromagnetic energy: In some embodiments, either the position or the orientation of the body of transparent insulating material 26 is adjusted to increase, decrease, or keep unchanged the electromagnetic energy collection area of the body of transparent insulating material 26. In some embodiments, the orientation is adjusted via rotational, translational, or oscillatory motion.
3) an angle ψ between each adjacent electromagnetic energy converting cell of the plurality of stacked identical electromagnetic energy converting cells 18: in some embodiments, the plurality of stacked identical electromagnetic energy converting cells 18 are linked in a zigzag format, thus adjusting the orientation of one cell, may adjust the orientation of other cells 18 in the plurality of stacked identical electromagnetic energy converting cells 18. In some embodiments, one or a plurality of cells 18 are adjusted via translational, rotational, or oscillatory motion. In some embodiments, the adjustment results in a change in the angle between each adjacent electromagnetic energy converting cell of the plurality of stacked identical electromagnetic energy converting cells 18. In some embodiments, only one or a plurality of cells 18 are adjusted to compare electricity output of different configurations.
4) an angle θ between the plurality of stacked identical electromagnetic energy converting cells 18 relative to the incoming electromagnetic energy: In some embodiments, the angle between at least one or a plurality of stacked identical electromagnetic energy converting cells 18 is adjusted relative to the incoming electromagnetic energy. In some embodiments, the change in either the orientation or position of at least one or a plurality of stacked identical electromagnetic energy converting cells 18 causes the incident electromagnetic energy to change. Therefore, adjusting the angle between the at least one or a plurality of cells 18 may result in a change in electricity output.
5) a spacing d between each adjacent electromagnetic energy converting cell of the plurality of stacked identical electromagnetic energy converting cells 18: In some embodiments, the spacing between at least two or a plurality of stacked identical electromagnetic energy converting cells 18 causes a change in the amount or incidence angle of incoming electromagnetic energy cells 18 for each or the plurality of stacked cells 18. In some embodiments, changing the spacing between the cells 18, causes a change in the orientation of at least one of the cells 18. In some embodiments, the cells 18 are connected via rod and node scissor configuration.

In some embodiments, the electromagnetic energy converter 14 of the method for optimizing converting electromagnetic energy to electricity of an electromagnetic energy converter 14 receives input electromagnetic energy as solar radiation. In some embodiments, the input electromagnetic energy is synthetic light. In some embodiments, the input electromagnetic energy has an intensity greater or smaller than solar radiation. In some embodiments, the input electromagnetic radiation has a bandwidth or peak frequency that is different from solar radiation.

In some embodiments, the electromagnetic energy converter 14 of the method for optimizing converting electromagnetic energy to electricity of an electromagnetic energy converter 14 further comprises a solar tracking system, the solar tracking system comprising electrical drives and mechanical gear trains, configured to adjust the electromagnetic energy converter 14 from a first configuration to a second configuration. In some embodiments, solar tracking mechanism is configured to adjust either the orientation or position of a solar cell. In some embodiments, solar tracking mechanism is configured to adjust either the orientation or position of the transparent body.

In some embodiments, active solar tracking mechanism is used. In some embodiments, the active solar tracking is relayed by a central processing unit. In some embodiments, the active solar tracking mechanism comprises mechanical componentry, such as gears, actuators, active or adaptive optics, or hydraulics. In some embodiments, the solar tracking mechanism comprises a power storage unit. In some embodiments, multiple electromagnetic energy converters 14 utilize the same active solar tracking mechanism. In some embodiments, the active solar tracking mechanism is configured to move the position of the electromagnetic energy converter 14. In some embodiments, active solar tracking adjusts the electromagnetic energy converter 14 along one axis. In some embodiments, active solar tracking adjusts the electromagnetic energy converter 14 along more than one axis.

In some embodiments, passive solar tracking is used. A passive solar tracking mechanism often does not require an external energy source to adjust the configuration of the electromagnetic energy converter 14. In some embodiments, the passive solar tracking mechanism uses heat to operate. In some embodiments, solar heat provides the energy to empower a passive solar tracking system. In some embodiments, wind power is used to passively track the Sun. In some embodiments, shape memory materials, such as alloys, or thermal memory materials, such as wax, are used. In some embodiments, a passive solar tracking mechanism uses actuators to adjust the configuration of the electromagnetic energy converter 14. In some embodiments, stored potential energy is used for solar tracking. In some embodiments, stored potential energy refers to chemical energy, gravitational energy, mechanical energy, or nuclear energy.

In some embodiments, the method for optimizing converting electromagnetic energy to electricity of an electromagnetic energy converter 14 further comprises determining electromagnetic energy input of the electromagnetic energy converter 14. In some embodiments, the electromagnetic energy input of the electromagnetic energy converter 14 is determined using reference data. In some embodiments, reference data refers to time of the day or time of year. In some embodiments, reference data refers to collected electromagnetic energy input data. In some embodiments, electromagnetic energy input data is collected to train a solar tracking mechanism. In some embodiments, reference data refers to official data, that includes National Renewable Energy Laboratory datasets. In some embodiments, reference data refers to a model of an electromagnetic energy source. In some embodiments, the electromagnetic energy input of the electromagnetic energy converter 14 is determined using measurement. In some embodiments, a light sensor is used to characterize the electromagnetic energy input. In some embodiments, a cell of the plurality of cells 18 is used to determine the input electromagnetic energy. In some embodiments, one or a plurality of cells “dummy” 18 is used to determine the input electromagnetic energy.

In some embodiments, the method for optimizing converting electromagnetic energy to electricity of an electromagnetic energy converter 14 further comprises determining maximum power point of the electrical output of the electromagnetic energy converter 14, the maximum power point determination configured to improve conversion efficiency of the electromagnetic energy converter 14. In some embodiments, maximum power of an electromagnetic energy converting cell 18 varies with radiation characteristics including intensity and frequency, as well as ambient and cell temperatures. In some embodiments, a charge controller is used to track and extract maximum power from the plurality of electromagnetic energy converting cells 18. In some embodiments, the charger controller maximizes the amount electrical current extracted from the cells 18 and stored in a power storage unit. In some embodiments, the charge controller extracts power from the electromagnetic energy converter 14 at peak voltage capacity. In some embodiments, extraction voltage is determined based on current-voltage characteristics of one or a plurality of the electromagnetic energy converting cells 18. In some embodiments, electricity is extracted at a voltage that is determined based on the battery. In some embodiments, voltage or current converters are used as part of the power extraction process.

In some embodiments, adjusting a configuration characteristic of the electromagnetic energy converter 14 is done based on electrical output of the electromagnetic energy converter. In some embodiments, the method further comprises measuring electrical output of the electromagnetic energy converter 14 after adjusting the electromagnetic energy converter 14 from a first configuration to a second configuration. In some embodiments, electrical output of the electromagnetic energy converter 14 is measured using a multimeter.

In some embodiments, the method further comprises comparing the measured electrical outputs of the electromagnetic energy converter 14 before and after adjusting the electromagnetic energy converter 14 from a first configuration to a second configuration. In some embodiments, the electromagnetic energy input or electrical output of the electromagnetic energy converter 14 of a first configuration is first determined, using direct measurement or existing data. In some embodiments, the electromagnetic energy input or electrical output of the electromagnetic energy converter 14 of a second configuration is then determined, using direct measurement or existing data. In some embodiments, the electromagnetic energy converter 14 is adjusted from the first configuration into a second configuration, based on the determined first and second determinations of the electromagnetic energy input or electrical output of the electromagnetic energy converter 14.

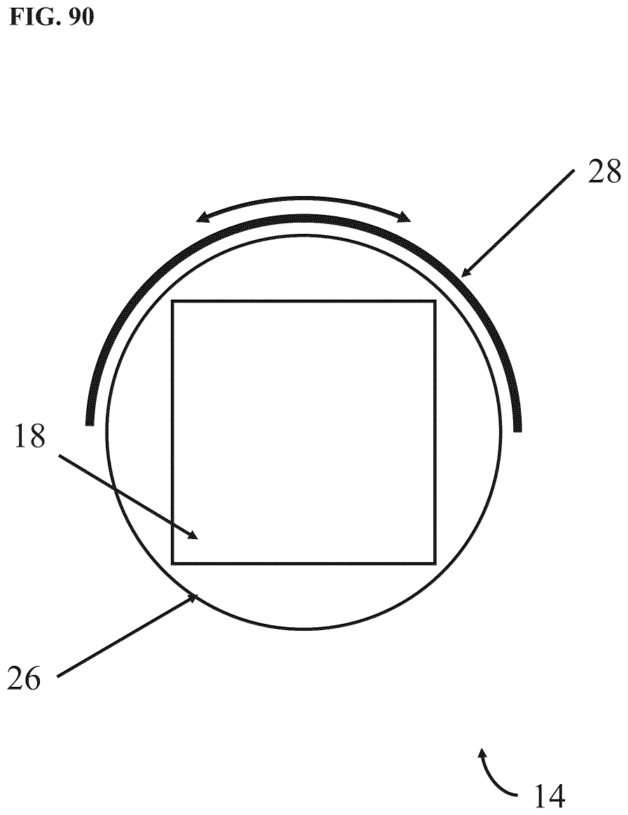

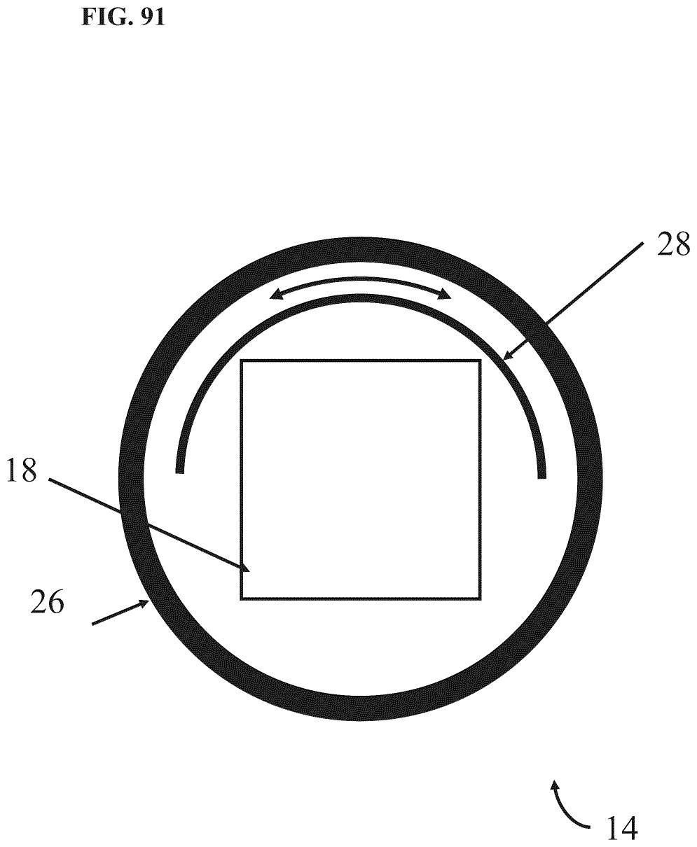

In reference to FIGS. 90-91, in some embodiments, the electromagnetic energy converter 14 further comprises a layer 28 selected from the group consisting of conductive, dielectric, luminescent, transmissive, absorptive, diffusive, refractive, and dispersive materials, or a combination thereof. In some embodiments, the layer or a plurality of layers is placed between the plurality of electromagnetic energy converting cells 18. In some embodiments, the layer or a plurality of layers is placed inside the transparent body. In some embodiments, the layer or a plurality of layers is placed outside the transparent body.

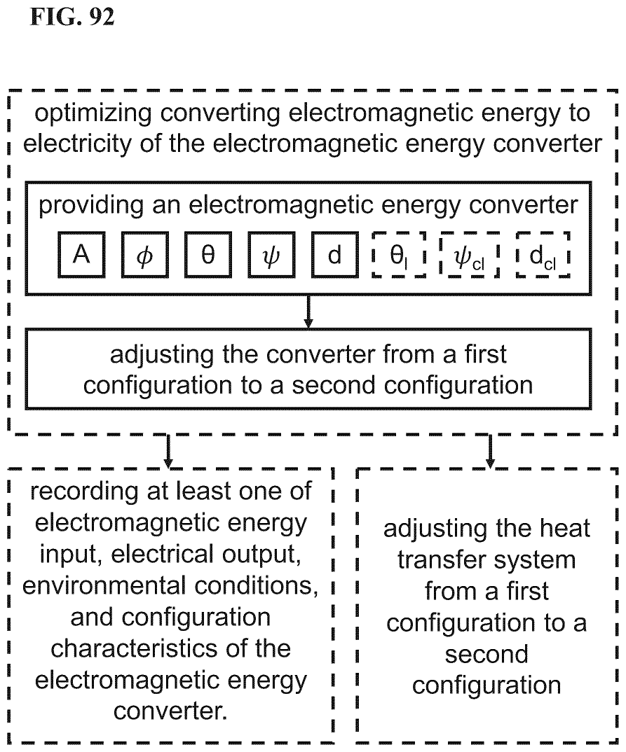

In reference to FIG. 92, in some embodiments, the layer 28 or a plurality of layers is adjusted. In some embodiments, the method for optimizing converting electromagnetic energy to electricity of an electromagnetic energy converter 14 further comprises adjusting a layer configuration characteristic, the “layer configuration characteristic” comprising:
an angle ψ_{cl} between an electromagnetic energy converting cell of the plurality of electromagnetic energy converting cells 18 and the layer,
an angle θₗ between the layer and an incoming electromagnetic energy, and
a spacing d_{cl} between an electromagnetic energy converting cell of the plurality of electromagnetic energy converting cells 18 and the layer.

In some embodiments, the “electromagnetic energy converter configuration characteristics” comprise:
an electromagnetic energy collection area A of the body of transparent insulating material, 26 an orientation ϕ of the body of transparent insulating material 26 relative to an incoming electromagnetic energy, an angle ψ between each adjacent electromagnetic energy converting cell of the plurality of stacked identical electromagnetic energy converting cells 18, an angle θ between the plurality of stacked identical electromagnetic energy converting cells 18 relative to the incoming electromagnetic energy, and a spacing d between each adjacent electromagnetic energy converting cell of the plurality of stacked identical electromagnetic energy converting cells 18, and
an angle ψ_{cl} between an electromagnetic energy converting cell of the plurality of electromagnetic energy converting cells 18 and the layer, an angle θₗ between the layer and an incoming electromagnetic energy, and a spacing d_{cl} between an electromagnetic energy converting cell of the plurality of electromagnetic energy converting cells 18 and the layer.

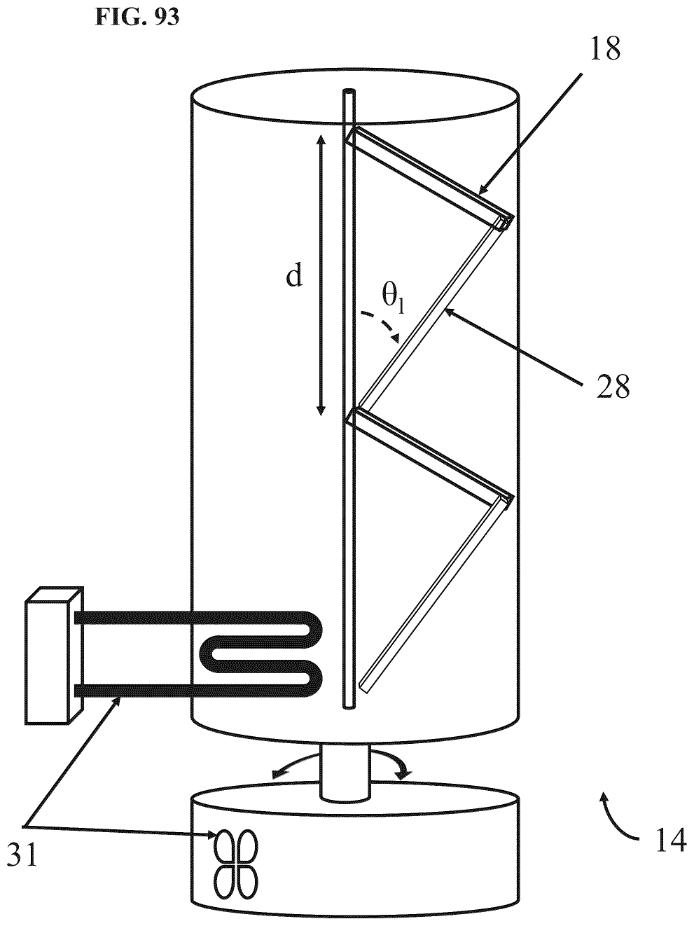

In reference to FIG. 93, in some embodiments, electromagnetic energy input or electrical output of the electromagnetic energy converter 14 further comprising the layer is determined before or after adjusting the electromagnetic energy converter 14 from a first configuration to a second configuration. In some embodiments, electromagnetic energy input or electrical output of the electromagnetic energy converter 14 further comprising the layer is determined before or after adjusting the layer configuration characteristic from a first configuration to a second configuration. In some embodiments, the second configuration electrical output of the electromagnetic energy converter 14 is determined by adjusting the layer of the electromagnetic energy converter 14 from a first configuration to the second configuration and measuring the electrical output of the second configuration of the electromagnetic energy converter 14. In some embodiments, the electromagnetic energy converter 14 is returned to the first configuration from the second configuration, after measuring the electrical output of the second configuration of the electromagnetic energy converter 14, and comparing it with the electrical output of the first configuration of the electromagnetic energy converter 14. In some embodiments, one or a subset of layers is adjusted to determine electrical output of the second configuration. In some embodiments, one or a plurality of “dummy” layers is adjusted to determine electrical output of the second configuration. In some embodiments, the adjustment is done numerically, thus using historical data, physical model, or simulation to determine estimated electrical output of the second configuration.

In some embodiments, the electromagnetic energy converting cells 18 and the layer or plurality of layers are coupled, wherein adjusting the cell configuration further results in an adjustment of the layer configuration. In some embodiments, electromagnetic energy input is adjusted by adjusting either a physical or chemical property of the layer. In some embodiments, electromagnetic energy input is increased by adjusting the layer to collect or direct more electromagnetic energy onto the electromagnetic energy converting cells 18. In some embodiments, the layer is adjusted automatically. In some embodiments, the layer is the transparent body of a nearby electromagnetic energy converter 14 reflecting light. In some embodiments, the layer is material covering an installation area, such as concrete base reflecting light. In some embodiments, the layer is adjusted chemically, such as electric current through gel.

In reference to FIG. 92, in some embodiments, the method for optimizing converting electromagnetic energy to electricity of an electromagnetic energy converter 14 further comprises recording at least one of electromagnetic energy input, electrical output, environmental conditions, and configuration characteristics of the electromagnetic energy converter 14. In some embodiments, the recording of information is done locally or virtually, such as in the cloud. In some embodiments, the environmental condition includes the ambient temperature, humidity, pressure, clarity, precipitation, snow cover, gust, and particulate concentration. In some embodiments, the environmental condition includes wind characteristics, such as wind speed and direction. In some embodiments, the environmental condition refers to traffic, canopy, vegetation, or shadowing.

In some embodiments, adjusting the electromagnetic energy converter 14 from a first configuration to a second configuration is based on environmental conditions, the environmental conditions selected from a list of wind speed, wind direction, cloud coverage, shading, shadowing, glare, surface reflectivity, temperature, debris, and precipitation. In some embodiments, the electromagnetic energy further comprises a sensor selected to detect a physical parameter impacting electrical output of the electromagnetic energy converter 14, the method further comprising measuring output of the sensor. In some embodiments, the sensor is a light sensor. In some embodiments, the sensor is a thermometer. In some embodiments, the sensor is selected from a list of electromechanical sensors, such as a wind speed sensor. In some embodiments, the sensor is selected from a list of photoelectric, thermoelectric, electrochemical, Electromagnetic, thermooptic sensors.

In some embodiments, the method for optimizing converting electromagnetic energy to electricity of an electromagnetic energy converter 14 further comprises adjusting the heat transfer system 31. In some embodiments, the heat transfer system 31 is adjusted to regulate temperature. In some embodiments, the heat transfer system 31 transfers the heat into a heat storage unit. In some embodiments, the heat transfer system 31 is adjusted to regulate humidity. In some embodiments, the heat transfer system 31 helps with air circulation. In some embodiments, the heat transfer system 31 is adjusted to regulate radiative transfer. In some embodiments, the heat transfer system 31 is automatic. In some embodiments, the heat transfer system 31 is passive. In some embodiments, wax is used to capture and release heat. In some embodiments, the heat transfer system 31 is active. In some embodiments, one or a plurality of cells 18 or layers is adjusted, wherein the adjustment further changes a thermal characteristic of the electromagnetic energy converter 14. In some embodiments, the heat transfer system 31 comprises a circulating material, such as a gas or liquid, to transfer heat in or out of the electromagnetic energy converter 14. In some embodiments, adjusting the heat transfer system 31 refers to changing a thermal characteristic of the electromagnetic energy converter 14. In some embodiments, adjusting the heat transfer system 31 refers to changing a characteristic configuration of the electromagnetic energy converter 14, which can further change a thermal property of the electromagnetic energy converter 14. In some embodiments, the heat transfer system 31 comprises an electromechanical unit. In some embodiments, the heat transfer system 31 comprises a dehumidifier. In some embodiments, the heat transfer system 31 comprises desiccant.

In some embodiments, the method further comprises a communication system configured to communicate output of the electromagnetic energy converter 14, the method further comprising communicating at least one of electromagnetic energy input, electrical output, environmental conditions, and configuration characteristics of the electromagnetic energy converter 14. In some embodiments, the communication is done via text, phone call, digital message. In some embodiments, communication is done wirelessly. In some embodiments, a central processing unit is equipped with a communication system. In some embodiments, communication is done using a flashing light, speaker, display, etc.

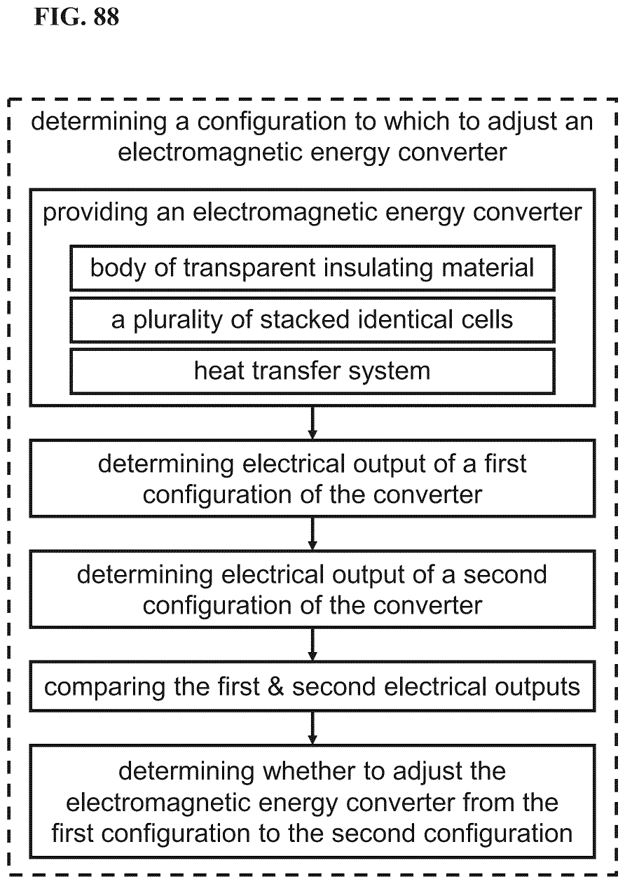

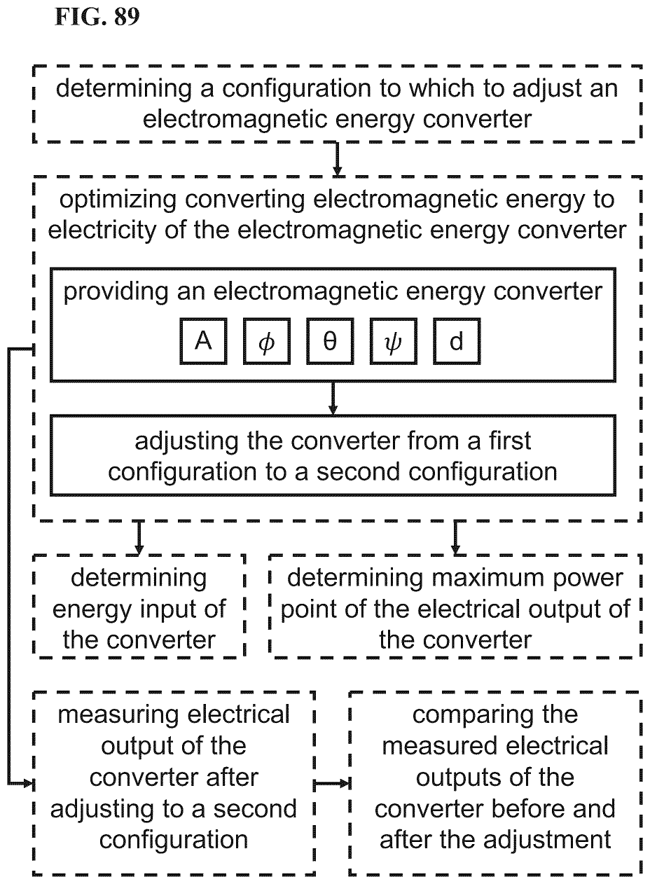

In reference to FIG. 88, in some embodiments, a method for determining a configuration to which to adjust an electromagnetic energy converter 14, the electromagnetic energy converter 14 comprising a body of transparent insulating material 26, a plurality of stacked identical electromagnetic energy converting cells 18, and a heat transfer system 31, wherein characteristics of the electromagnetic energy converter 14 configuration comprising an electromagnetic energy collection area of the body of transparent insulating material 26, an orientation of the body of transparent insulating material 26 relative to an incoming electromagnetic energy, an angle between each adjacent electromagnetic energy converting cell 18 of the plurality of stacked identical electromagnetic energy converting cells 18, an angle between the plurality of stacked identical electromagnetic energy converting cells 18 relative to the incoming electromagnetic energy, and a spacing between each adjacent electromagnetic energy converting cell 18 of the plurality of stacked identical electromagnetic energy converting cells 18, the method comprising:
determining electrical output of the electromagnetic energy converter 14 configured in a first configuration,
determining electrical output of the electromagnetic energy converter 14 of a second configuration,
comparing the first configuration electrical output and the second configuration electrical output of the electromagnetic energy converter 14, determining whether to adjust the electromagnetic energy converter 14 from the first configuration to the second configuration and outputting a control signal.

In some embodiments, the configuration electrical output of the electromagnetic energy converter 14 is determined using reference data. In some embodiments, reference data refers to existing datasets such as physical model or historical data. In some embodiments, data from the National Renewable Energy Laboratory is used as reference data. In some embodiments, reference data refers to collected data. In some embodiments, reference data refers to a physical model, such as the position of the Sun in the sky or voltage-current curve of an electromagnetic energy converting cell.

In some embodiments, the second configuration electrical output of the electromagnetic energy converter 14 is determined by adjusting the electromagnetic energy converter 14 from a first configuration to the second configuration and measuring the electrical output of the second configuration of the electromagnetic energy converter 14. In some embodiments, the electromagnetic energy converter 14 is returned to the first configuration from the second configuration, after measuring the electrical output of the second configuration of the electromagnetic energy converter 14, and comparing it with the electrical output of the first configuration of the electromagnetic energy converter 14. In some embodiments, one or a subset of electromagnetic energy converting cells 18 is adjusted to determine electrical output of the second configuration. In some embodiments, one or a plurality of “dummy” cells 18 is adjusted to determine electrical output of the second configuration. In some embodiments, the adjustment is done numerically, thus using historical data, physical model, or simulation to determine estimated electrical output of the second configuration.

In some embodiments, amount of energy needed for adjusting the electromagnetic energy converter 14 from a first configuration to a second configuration is determined. In some embodiments, electrical energy needed to adjust the electromagnetic energy converter 14 from a first configuration to second configuration is greater than the electrical output of the electromagnetic energy converter 14 in the second configuration. In some embodiments, electrical energy needed to adjust the electromagnetic energy converter 14 from a first configuration to second configuration is greater than the difference between the electrical outputs of the two configurations of the electromagnetic energy converter 14. In some embodiments, the adjustment is voted inappropriate based on the amount of energy needed to make the adjustment. In some embodiments, the adjustment is determined inappropriate based on complexity of an adjustment. In some embodiments, an adjustment is recommended. In some embodiments, a recommended adjustment is recommended. In some embodiments, a recommended adjustment is deployed manually. In some embodiments, the configuration is not adjusted since the ‘determined’ or ‘projected’ electrical outputs do not justify an adjustment, because either the second configuration generates less power than the first configuration, or the amount of energy required to adjust the configuration between the two configurations is greater than the difference in energy between the electrical outputs of the two configurations.

In some embodiments, the method for determining a configuration to which to adjust an electromagnetic energy converter 14 further comprises determining electromagnetic energy input of the electromagnetic energy converter. In some embodiments, the electromagnetic energy input of the electromagnetic energy converter 14 is determined using reference data.

In some embodiments, the method for determining a configuration to which to adjust an electromagnetic energy converter 14 further comprises adjusting the electromagnetic energy converter 14 in response to the control signal. In some embodiments, the control signal is binary output. In some embodiments, the control signal is a vote. In some embodiments, the control signal is a positive voltage. In some embodiments, the control signal is a text. In some embodiments, the control signal refers to a pulse or frequency of electricity or light that represents a control command as it travels over a network, a computer channel or wireless. In some embodiments, the control signal is a verbal command. In some embodiments, the control signal is a command. In some embodiments, a control unit receives the control signal. In some embodiments, the control signal is communicated. In some embodiments, a central processing unit relays the control signal. In some embodiments, adjusting the electromagnetic energy converter 14 in response to the control signal is done by a control unit.

In some embodiments, electrical output of an electromagnetic energy converter 14 is smaller than expected value. In some embodiments, smaller than expected electrical output indicates reduced electromagnetic energy input. In some embodiments, smaller than expected electrical output indicates that at least one or a plurality of electromagnetic energy converting cells is faulty. In some embodiments, smaller than expected electrical output indicates that the body of transparent insulating material 26 is faulty.

In some embodiments, the body of transparent insulating material 26 is yellowed due to UV exposure, thus resulting in reduced transparency and the resulting reduction in electromagnetic energy transmission. In some embodiments, the body of transparent insulating material 26 is coated with material, such as dirt, thus reducing electromagnetic energy transmission.

In some embodiments, the body of transparent insulating material 26 is treated. In some embodiments, the body of transparent insulating material 26 is treated with UV-protection material. In some embodiments, the body of transparent insulating material 26 is cleaned. In some embodiments, the body of transparent insulating material 26 is cleaned by pressurized fluid(s) or vacuum. In some embodiments, the body of transparent insulating material 26 is cleaned manually. In some embodiments, the body of transparent insulating material 26 is cleaned somewhat or fully autonomously. In some embodiments, the body of transparent insulating material 26 is cleaned by an automatic wiper. In some embodiments, the body of transparent insulating material 26 is cleaned automatically by a robot. In some embodiments, the robot can climb an electromagnetic energy converter 14. In some embodiments, a robot can roll up or down an electromagnetic energy converter 14. In some embodiments, the body of transparent insulating material 26 comprises an apparatus, such as railing, to guide a robot. In some embodiments, a robot can take off, land, and/or hover.

### Three-Dimensional Electromagnetic Energy Converter:

In reference to FIG. 93, in some embodiments, a three-dimensional (3D) electromagnetic energy converter 14 is provided having advantageous construction and method of use. In some embodiments, a 3D electromagnetic energy converter 14 can comprise a photovoltaic unit having a plurality of discrete and non-coplanar photovoltaic layers 18. In some embodiments, the photovoltaic layer is a photovoltaic cell, such as a mono or poly-crystalline solar cell.

In some embodiments, a 3D electromagnetic energy converter 14 comprising a photovoltaic unit comprising a plurality of discrete and non-coplanar electromagnetic energy converting cells 18 or photovoltaic layers 18 configured to convert light to electric current, a distance and a relative angle between adjacent layers of the plurality of discrete and non-coplanar photovoltaic layers 18, a power management unit comprising a power control unit, the power management unit configured to receive and manage the electric current from the plurality of discrete and non-coplanar photovoltaic layers 18, a support base receiving the photovoltaic unit and the power management unit, and an at least partially transparent housing at least partially insulating the plurality of discrete and non-coplanar photovoltaic layers 18.

In some embodiments, the plurality of photovoltaic layers 18 is separated at a distance greater than 1 nanometer. The distance refers to the separation between adjacent photovoltaic layers 18. The distance between adjacent photovoltaic layers can be adjusted for optimal power output per unit length. Adjacent photovoltaic layers 18 can also be inclined at a relative angle ranging from 0 to 360 degrees. The relative angle refers to the difference in angles of adjacent photovoltaic layers 18 from zenith. For instance, the relative angle between two parallel zenith-facing solar cells 18 stacked on top of each other at a distance is 0 degrees. Similarly, the relative angle between two vertically stacked solar cells 18 facing in opposite directions (one facing toward zenith or photovoltaic (PV)-side up, and the other facing away from zenith or PV-side down) is 180 degrees. In the latter embodiment, the adjacent photovoltaic layers 18 are either facing each other, face-to-face, or positioned to face away from each other, i.e., back-to-back. In the case of bifacial solar cells 18, the cell can be characterized with two complementary angles, each identifying one of the two faces.

In some embodiments, 3D photovoltaic charging system can further comprise a power management unit having a power control unit. The power control unit is configured to manage and control elements and operation of 3D electromagnetic energy converter 14. In some embodiments, the power control unit comprises a maximum power point tracking (MPPT) controller. In some embodiments, the power control unit comprises a pulse width modulation (PWM) controller.

In some embodiments, the power management unit further comprises a power storage unit for receiving and storing power produced. In some embodiments, the power control unit serves to connect a plurality of photovoltaic units. In some embodiments, the power control unit serves to manage a plurality of 3D photovoltaic charging systems and/or electric consumers coupled via a physical or virtual electrical connection. In some embodiments, the power control unit connects one or a plurality of photovoltaic units to a power grid. In some embodiments, the power control unit comprises a battery management system (BMS).

In some embodiments, a support base receives and/or contains the photovoltaic unit and/or the power management unit. In some embodiments, the plurality of photovoltaic layers 18 is insulated in a transparent housing and the plurality of photovoltaic layers 18 convert light to electric current, whereby the electric current is received and managed by the power management unit.

In some embodiments, the support base is selected from a group consisting of mounting pole, post, concrete foundation, bollard, anchor, frame, mounting bracket, clamp, rail, magnetic plate, rope, chain, wire, cable, arms, legs, hook, mast, hanger, strut, mounting fastener, wall mount, and belt.

In some embodiments, 3D electromagnetic energy converter 14 comprises a photovoltaic unit having ten photovoltaic layers 18, in this case commercial polycrystalline solar cells 18, vertically stacked on top of each other at a distance of adjacent cells 18 of 0.1 ft at a 30-degree angle from zenith, i.e., relative angle of 0 degrees, and encased in a transparent polycarbonate tube housing with a reflective back surface 28. In some embodiments, the backside of each individual solar cell is covered with reflective layer 28, in this case a reflective tape 28, to reduce light absorption and enhance light reflection. In some embodiments, the solar cells 18 are connected in series. The photovoltaic unit comprising the plurality of photovoltaic layers 18. The photovoltaic unit can be encased in a transparent housing positioned inside a 3 inch-diameter polyvinyl chloride (PVC) pipe support base with an opening window. The photovoltaic unit receives light through the opening window. The projected area or installation footprint of the photovoltaic unit 110 is 1000 mm².

The opening window of the PVC support base containing the photovoltaic unit was positioned exposed to the Summer (June 2020) sun at a fixed face direction pointing South in Ann Arbor, Mi. The output of the 3D photovoltaic charging system was measured at various load resistances. The output of a reference photovoltaic layer, in this case one polycrystalline solar cell fixed at a 45-degree angle from horizon ‘facing’ South, was also measured. The output of the 3D photovoltaic charging system was found to reach 330 watts per meter squared (average sunlight intensity at Earth 1000 W/m²), compared to an output of 30 W/m² measured from the one fixed reference photovoltaic layer.

The installation of a plurality of photovoltaic layers 18 stacked on top of each other at a distance results in a projected area that is equal to that of individual photovoltaic layers 18. This indicated that the 3D electromagnetic energy converter 14, in this case of only one-foot height, generated ten times the power density of the fixed reference photovoltaic layer 18. In other words, this embodiment generated 330 W/m² per foot height. For comparison, a typical street light post is 6 to 14 feet tall and can significantly improve the power density of solar modules by collecting and converting light vertically resulting in enhanced power output with a small footprint.

In some embodiments, a 3D electromagnetic energy converter 14 provides power to off-the-power grid lighting, charging, communication, chemical reactor, and internet of things (IoT) systems.

Recently, the solar industry has adopted bifacial flat solar panels to take advantage of reflected light from the surrounding environment. As a result, the output of bifacial solar panels remains strongly dependent on the properties of the surrounding environment. This dependence translates into requiring reflective surfaces 28 at bifacial solar installations, such as concrete or painted flooring, further driving up the installation costs. While these similar environmental features can also be used to improve the power output of the 3D electromagnetic energy converter 14, in some embodiments, they are unnecessary.

In some embodiments, a 3D electromagnetic energy converter 14 has a 360 degree optical cross section between adjacent photovoltaic layers 18. In some embodiments, the 3D electromagnetic energy converter 14 has a full sky view. In some embodiments, the transparent body of the 3D electromagnetic energy converter 14 is single-piece, such as a transparent tube, allowing electromagnetic energy converting cells 18 or photovoltaic layers 18 to be exposed to incoming electromagnetic energy from all directions. In some embodiments, ‘all directions’ refers to all horizontal direction. In some embodiments, ‘all directions’ refers to all vertical directions, depending on the orientation of the photovoltaic layers 18 relative to an electromagnetic energy source. In some embodiments, ‘all directions’ refers to all possible directions, including reflected light from the surrounding area.

The term ‘discrete and non-coplanar photovoltaic layers 18’ does not include planar configuration of photovoltaic layers 18, such as flat solar panels, bifacial solar panels, flexible solar panels, and tandem solar cells 18. Bifacial solar panels consist of two-faced solar cells 18 installed in a planar geometry. Flexible solar panels consist of solar cells 18 printed on and supported by a planar and flexible surface. Tandem solar cells 18 consist of a multitude of photovoltaic layers stacked vertically to selectively convert various light frequencies. For the purposes of this application, a tandem solar cell is considered as one electromagnetic energy converting cell or photovoltaic layer 18.

The term ‘discrete and non-coplanar photovoltaic layers’ does not refer to surfaces sprayed and/or printed by a photovoltaic material. A surface printed by a photovoltaic film is considered as one discrete photovoltaic layer 18.

The term ‘transparent’ refers to materials whose light transmission ratio is greater than zero. Transparency in this context is defined as the physical property of allowing electromagnetic energy to propagate within a material, at least partially or in entirety of the electromagnetic spectrum, with or without appreciable scattering. In some embodiments, the transparent housing is a transparent cover to insulate the photovoltaic layers 18. In some embodiments, the photovoltaic layers 18 are positioned inside a light post with an opening window carved out of the light post. In some embodiments, the transparent housing is a transparent access gate, such as a non-glare acrylic covering, that insulates photovoltaic layers. The transparent housing provides light entry and also, in some embodiments, blocks the exposure of photovoltaic layers 18 to environmental damages, including humidity, dew, hail, dust, wind, or even vandalism.

In some embodiments, the transparent housing is a transparent molded slab encasing, at least partially, the photovoltaic layers 18, for improved structural strength. In some embodiments, the transparent housing is vacuumed for insulation. In some embodiments, the transparent housing is filled with a dielectric material, such an inert gas, for insulation to reduce photovoltaic layer corrosion rate, thermal conductivity, and/or electric conductivity.

In some embodiments, the plurality of discrete and non-coplanar photovoltaic layers is at least partially encased in a molded dielectric slab. In some embodiments, the distance between adjacent layers of the plurality of discrete and non-coplanar photovoltaic layers is at least partially filled with a material selected from a group consisting of light-reflective materials, dielectric materials, electrical conductors, thermal conductors, light-transmissive materials, light-absorptive materials, light concentrators, light-diffusive materials, gels, pastes, liquids, oils, water, resins, polymers, thermal-setting polymers, photo-setting polymers, thermal coolant, heat-absorbing materials, heat-dispersing materials, air packets, light-emitting materials, electroluminescent materials, and photoluminescent materials.

In some embodiments, the 3D electromagnetic energy converter 14 comprises a photovoltaic unit having a plurality of non-coplanar photovoltaic layers 18 encased in a transparent body or transparent housing 26 and a reflective surface 28. In some embodiments, the photovoltaic unit is installed on a support base, for instance a street light post, by a fastener. In some embodiments, the fastener can be an adjustable belt that affixes the photovoltaic unit along the outer surface of the light post. In some embodiments, the power management unit is housed inside the light post to provide power for lighting. In some embodiments, the support base is an electric device, such as but not limited to phone chargers, electric scooters, electric bike charger station, and a smart traffic monitor. In some embodiments, the 3D electromagnetic energy converter 14 is integrated into and provides power to outdoor configurable or mosaic hardware, such as an assembly of sensors.

In some embodiments, the support base is the floor and/or ground on which the 3D electromagnetic energy converter 14 rests. In some embodiments, the transparent housing 26 also houses the power management system, and therefore, serves as the support base. In some embodiments, the support base is an electric post, which can facilitate power grid connection.

In some embodiments, the electricity generated by the photovoltaic unit is delivered to the power management unit via wires housed in an electric conduit. The electric conduit can also be used as a support base. In some embodiments, the electric conduit is coated with a reflective material.

In some embodiments, the individual photovoltaic layers 18 of the photovoltaic unit are replaceable. In some embodiments, the photovoltaic layers are pulled out of a transparent, hardened resin molded slab, dielectric gel, or coolant fluid for inspection or replacement.

In some embodiments, the 3D electromagnetic energy converter 14 comprises a plurality of photovoltaic units encased in interlocking transparent housings 26, individually referred to as 3D solar blocks, to create a solar mat. In some embodiments, the 3D electromagnetic energy converter 14 comprises a plurality of photovoltaic layers 18, each photovoltaic layer 18 encased individually in a transparent housing 26. A plurality of individually encased photovoltaic layers 18 are coupled into a photovoltaic unit. In some embodiments, the photovoltaic unit further comprises of individually encased reflective layers 28. In some embodiments, the 3D solar block comprises at least a pair of a photovoltaic layer 18 and reflective layers 28 encased in a transparent housing 26. The 3D solar mat is installed horizontally or vertically. In some cases, a support base, such as a wall mount, is used. In some embodiments, individual 3D solar blocks are replaceable. In some embodiments, a plurality of photovoltaic layers 18, a photovoltaic unit, are encased in a transparent housing 26 to create a 3D solar panel.

In some embodiments, reflective layers 28 are distributed between photovoltaic layers 18. In some embodiments, photovoltaic layers 18 and reflective layers 28 are oriented at an angle. The angle between the photovoltaic layers 18 and the reflective layers 28 can be adjusted for optimal power output.

In reference to FIGS. 90-91, in some embodiments, reflective surfaces 28 are positioned to direct photons toward at least one corresponding photovoltaic layer 18. In some embodiments, a reflective surface 28 is used to limit the angles within which light flux can enter the photovoltaic unit. In some other embodiments, the reflective surface 28 envelops part of the transparent housing 26 to improve light intake. In some embodiments, the reflective surface 28 is stationary and fixed while, in some embodiments, the reflective surface 28 is rotated depending on the position of a light source. In some embodiments, the reflective surface 28 is rotated along an axis of symmetry manually or by a servomotor housed in the support base.

In some embodiments, the transparent housing 26 is a molded slab. In some embodiments, the molded slab is one or a combination of at least partially hardened polymer(s). In some embodiments, the transparent housing 26 also encloses thermal absorber layers intended to convert thermal energy to electricity and/or store thermal energy in a circulating heat absorbing material. In some embodiments, the thermal absorber layer selectively reflects light within a specific wavelength range.

In some embodiments, the 3D electromagnetic energy converter 14 comprises one or a plurality of 3D electromagnetic energy converter 14 mounted on a central 3D electromagnetic energy converter 14.

In some embodiments, the transparent housing 26 also encloses a heating or cooling system to regulate or lower the operational temperature of photovoltaic layers 18 by a circulating heat absorbing or releasing material. In some embodiments, the molded slab is an electric, thermal, and/or humidity insulator.

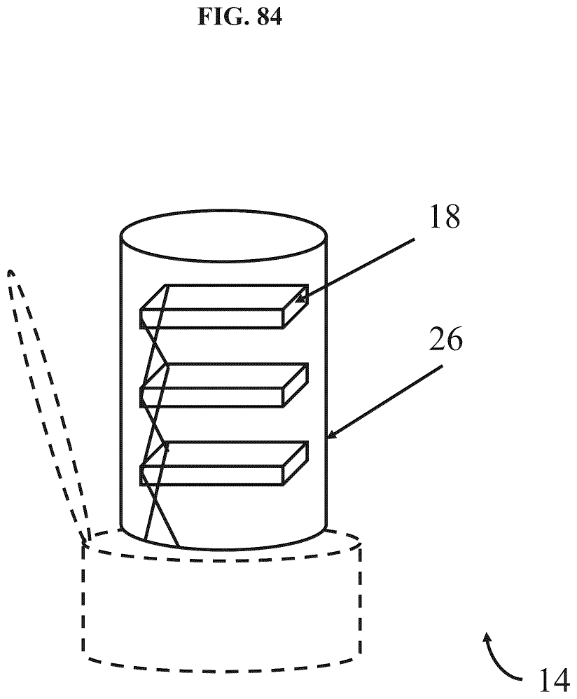

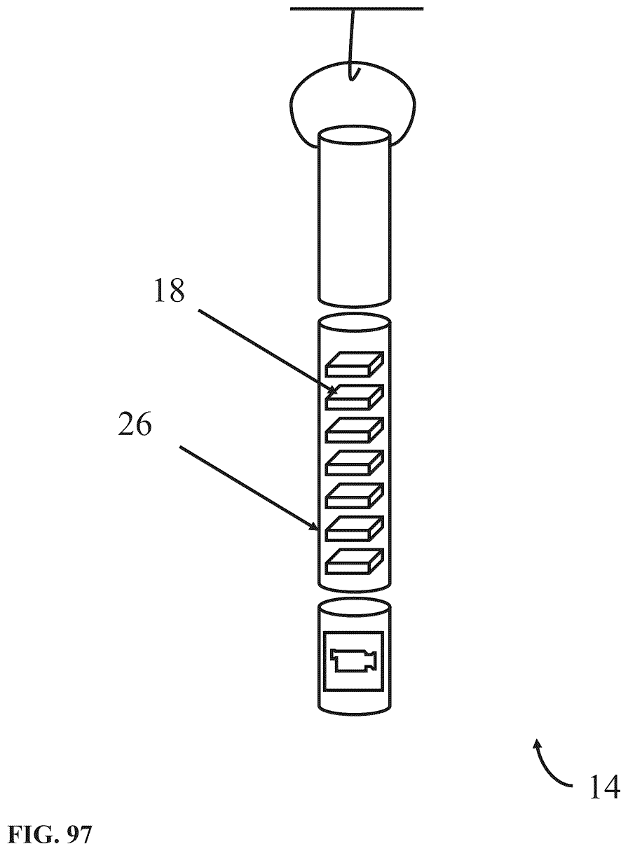

In reference to FIGS. 84-86 and 97, in some embodiments, the 3D electromagnetic energy converter 14 comprises a photovoltaic unit housed in a collapsible, foldable, telescopic, and/or expandable transparent housing 26. In some embodiments, the support base is a helium gas balloon within which the photovoltaic unit is housed. In some embodiments, the transparent housing 26 has a pattern, such as a dome-shaped or prismatic geometry, for improved light collection and/or enhanced light control.

In some embodiments, a 3D electromagnetic energy converter 14 comprising a photovoltaic unit comprising at least one substrate with a serrated surface covered at least partially by a photovoltaic layer 18 configured to convert light to electric current, the serrated surface substrate and the photovoltaic layer 18 having converging surface normals, a power management unit comprising a power control unit, the power management unit configured to receive and manage the electric current from the photovoltaic layer 18, a support base receiving the photovoltaic unit and the power management unit, and an at least partially transparent housing 26 at least partially insulating the photovoltaic layer 18.

In some embodiments, a substrate with a serrated surface covered at least partially by a photovoltaic layer 18 is used to collect and convert light. In some embodiments, a 3D electromagnetic energy converter 14 comprises a photovoltaic unit having a substrate with a serrated surface covered at least partially by a photovoltaic layer 18, a power management unit having a power control unit, and a support base for receiving the photovoltaic unit and the power management unit.

The serrated surface substrate and, therefore, the photovoltaic layer 18 covering can have converging surface normals. The surface normals oriented at relative angles, i.e., relative surface normal angle, ranging between 0 and 180 degrees. Surface normal is defined as a unit vector at any given point P of a surface S that is perpendicular to the tangent plane at P. All surface normals of a planar polygon are parallel, i.e., surface normal relative angle 0 degrees. In contrast, the surface normals of a solid sphere are pointing off in all directions. Two surface normals characterizing two spots on opposite ends of a sphere have a relative angle 180 degrees, i.e., anti-parallel. The orientation of a surface normal indicates the direction the surface ‘faces.’ In some embodiments, the photovoltaic layers 18 are insulated in a transparent housing 26, and the photovoltaic layers 18 convert light to electric current, whereby the electric current is received and managed by the power management unit.

In some embodiments, the parts of the photovoltaic layer 18 with identical surface normals are electrically connected. In some embodiments, the photovoltaic layer 18 is printed on a network of printed conductive surface, i.e., wiring. In some embodiments, the printed wiring is designed to connect parts of the photovoltaic layer 18 with identical surface normals and separate them from other parts with different surface normals. In some embodiments, the power control unit of the power management unit divides and manages different parts of the photovoltaic layer discretely as independent ‘zones.’

The term ‘serrated surface’ herein refers to a plurality of (more than one) indentations cut into and/or created onto a surface. The ‘substrate with a serrated surface covered at least partially by a photovoltaic layer 18’ does not include solar concentrator panels, wherein photovoltaic layers 18 are positioned inside serrated, concave indentations, where the concentrated light is converted. In some embodiments, the surface normals describing the photovoltaic layer 18, are converging and/or diverging. The photovoltaic surface normals in solar concentrator panels are all parallel, co-planar or relative surface normal angle of zero degrees, all oriented radially toward one or a plurality of concentrator lenses.

The term ‘substrate with a serrated surface covered at least partially by a photovoltaic layer 18’ can also refer to smooth and uniform surfaces that change structure and geometry due to external stimuli, such as origami solar structures.

In some embodiments, the ‘substrate with a serrated surface’ supports a thin film photovoltaic layer 18. The thin film photovoltaic layer 18 can be a uniform sprayed-on organic photovoltaic material. In some embodiments, the thin film photovoltaic layer 18 comprises a host of sub-layers, including a rear and/or front conductor layer(s) such as transparent conducting oxide, a back contact such as ZnTe, and an absorbent layer such as CdTe. In some embodiments, the thin film photovoltaic layer 18 is coated with an anti-reflective material. In some embodiments, the transparent housing 26 is coated with an anti-reflective material. In some embodiments, the photovoltaic layer 18 is insulated by an encapsulant layer, such as resin.

In some embodiments, the 3D electromagnetic energy converter 14 is stationary with a fixed ‘face’ direction. The ‘face’ refers to the opening window or aperture through which light enters the converter. In some embodiments, the 3D electromagnetic energy converter 14 is positioned to permanently ‘face’ South in the Northern hemisphere, and vice versa.

In reference to FIG. 93, in some embodiments, an adjustable or photo-tracking, 3D electromagnetic energy converter 14, comprising an at least partially transparent housing 26, a photovoltaic unit having a plurality of non-coplanar electromagnetic energy converting cells 18 or photovoltaic surfaces 18 configured to convert light to electric current, the plurality of non-coplanar photovoltaic surfaces 18 being at least partially insulated in the at least partially transparent housing 26, a power management unit comprising a power control unit, the power management unit configured to receive and manage the electric current from the plurality of non-coplanar photovoltaic surfaces 18, means to cause a change in photo flux, thereby causing a change in the electric current, the change in electric current being monitored by the power control unit.

The term ‘photo flux’ refers to the amount of incident electromagnetic radiation. In some embodiments, a plurality of non-coplanar photovoltaic surfaces 18 converts a fraction of the incident photo flux (electromagnetic energy) to electricity (electrical energy). Some physical parameters determining the fraction of converted energy include radiation frequency, intensity, and incidence angle.

In some embodiments, at least a fraction of the plurality of non-coplanar photovoltaic surfaces 18 changes in orientation causing a change in photo flux. In some embodiments, the change in orientation comprises a change in at least one of relative distance and relative angle between two adjacent layers of the plurality of discrete and non-coplanar photovoltaic layers 18. In some embodiments, the change in photo flux is caused by a change in opening window. In some embodiments, the photovoltaic unit comprises at least one substrate with a serrated surface covered at least partially by a photovoltaic layer 18 configured to convert light to electric current, the serrated surface and the photovoltaic layer 18 having converging surface normals oriented at relative angles.

In reference to FIG. 93, in some embodiments, the 3D electromagnetic energy converter 14 can track a light source and comprises a photovoltaic unit having a plurality of non-coplanar photovoltaic surfaces 18 positioned at a relative distance and a relative surface orientation. The photovoltaic surfaces 18 are insulated in a transparent housing 26. In some embodiments, 3D electromagnetic energy converter 14 can further comprise a power management unit having power control unit. In some embodiments, 3D electromagnetic energy converter 14 can further comprise a power management unit having power storage unit. In some embodiments, 3D electromagnetic energy converter 14 can comprise an anchor base positioned at a relative orientation with the photovoltaic unit, i.e., relative photovoltaic unit to anchor base orientation, wherein the photovoltaic surfaces 18 convert light to electric current and the electric current is received and managed by the power management unit, wherein a change in the relative orientation of the photovoltaic unit and the anchor base, i.e., relative photovoltaic unit to anchor base orientation, causes a change in the electric current due to a change in light flux. The change in electric current is monitored by the power control unit, and the anchor base is fixed firmly to an object.

In some embodiments, the relative photovoltaic unit to anchor base orientation is considered the angle between a reference point on the anchor base and the photovoltaic unit ‘face’ direction.

In one experiment, the output of a 3D electromagnetic energy converter 14 was measured at 9 AM on a July day at a fixed South face direction 143. The same embodiment was then rotated manually along its axis and the output was again measured. It was determined that the single-axis rotation of the embodiment to face from fixed at South to directly along the Sun's path, resulted in doubling its output at that time. The improvement was found to be a function of Sun's position in the sky, i.e., time of day.

In some embodiments, 3D electromagnetic energy converter 14 is a cylindrical structure rotating along the axis of the cylinder to face the Sun in the sky. In some embodiments, there is a reflective surface 28 connected to the anchor base at least partially enveloping the photovoltaic unit. The reflective surface 28 is oriented at a relative orientation with respect to the photovoltaic unit. A change in the relative orientation of the reflective surface 28, changes light flux and causes a change in power generated by the photovoltaic unit.

The term ‘photovoltaic surfaces 18’ in the ‘photo-tracking, 3D electromagnetic energy converter 14’ refers to multi-faceted, non-coplanar photovoltaic surfaces 18. The term refers to the general concept of three-dimensionally stacked photovoltaics, including:
a) A plurality of discrete and non-coplanar photovoltaic layers 18, having a distance greater than 1 nanometer and a relative angle ranging from 0 to 360 degrees, and
b) A substrate with a serrated surface covered at least partially by a photovoltaic layer 18.

In some embodiments, the power control unit of the photo-tracking, 3D electromagnetic energy converter 14 monitors and computes a first maximum power point at a relative photovoltaic unit to anchor base orientation. The power control unit then relays a change in the first relative photovoltaic unit to anchor base orientation and computes a second maximum power point. The power control unit continues this process to determine an optimum relative photovoltaic unit to anchor base orientation.

In some embodiments, for photo-tracking, the power control unit relays a change in the first relative photovoltaic unit to anchor base orientation. In some embodiments, the change is performed by a motor. In some embodiments, the motor is connected to the photovoltaic unit via a support shaft, belt, chain, string, rail, hinge, or piston. In some embodiments, the relative photovoltaic unit to anchor base orientation is changed at a mounting point by a hydraulic piston, spring, or rod.

In some embodiments, the power management unit comprises a power control unit. In some embodiments, the power control unit comprises components selected from a list of internet-of-things (IoT) sub-systems, power inverter sub-systems, electric current switches, circuit breakers, resistors, cables, power transformers, active and passive sensors, power transmitters, electric plugs, displays, light-emitting diodes, and power tracking sub-systems. In some embodiments, the power control unit includes an active solar tracking sub-system, such as a motor. In other embodiments, the power control unit relies on passive solar tracking sub-systems, such as paraffin wax to act as a hydraulic actuator or shape memory alloys.

In other embodiments, the power management unit further comprises a power storage unit. In some embodiments, the power storage unit is selected from a list of electric, electro-mechanical, electro-chemical, electro-biological, and electro-thermal power storages.

In some embodiments, the 3D electromagnetic energy converter 14 comprises a plurality of 3D electromagnetic energy converter 14 mounted on one anchor base with one or a plurality of degrees of freedom, such as a change in the first relative photovoltaic unit to anchor base orientation. The anchor base moves one or a plurality of the 3D electromagnetic energy converter 14 for improved power output. In some embodiments, the 3D electromagnetic energy converter 14 comprises a plurality of 3D electromagnetic energy converter 14 mounted on a central 3D electromagnetic energy converter 14.

### Modular Electromagnetic Energy Converter:

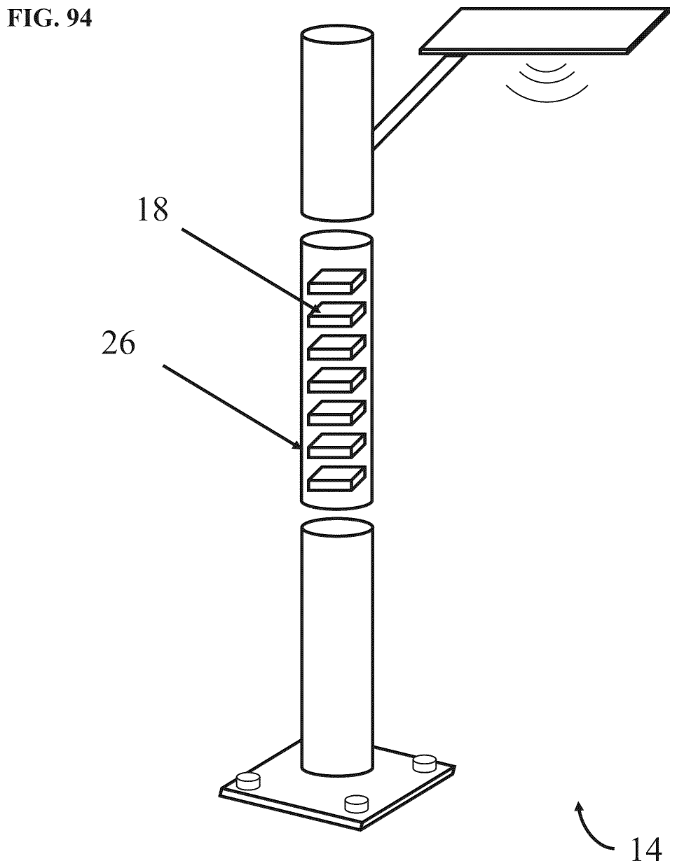

In reference to FIG. 94, in some embodiments, a modular electromagnetic energy converter 14 comprises an optoelectronic module comprising a photovoltaic module having a plurality of electromagnetic energy converting cells 18 arranged within a pole having a transparent window 26. The photovoltaic module converts light to electric current. The modular electromagnetic energy converter 14 further comprises an electric management module that is configured to manage flow of the electric current from the photovoltaic module to an electric device. The modular electromagnetic energy converter 14 also comprises a support module to affix at least the optoelectronic module to a base. In some embodiments, the support module further affixes an arm. In some embodiments, the support module further affixes an item selected from a group consisting of a signage, a traffic signage, a sensor, a mast, a staff, a chain, a cable, a bar, a tag, a barcode, a bird spike, an advertisement, a banner, a display, a decoration, an auxiliary electricity generator, and a charging platform.

In some embodiments, the photovoltaic module comprises an optical cross section, defined as the light collection area A, which is smaller than the cross section of the transparent window 26, referred to as ‘optoelectronic module optical cross section’. In some embodiments, the photovoltaic module optical cross section is smaller than the optoelectronic module optical cross section only at certain sun angles. In some embodiments, the optoelectronic module optical cross section improves the amount of light captured by each photovoltaic cell 18.

The term ‘transparent’ refers to materials whose light transmission ratio is greater than zero. Transparency in this context is defined as the physical property of allowing electromagnetic energy to propagate within a material, at least partially or in entirety of the electromagnetic spectrum, with or without appreciable scattering.

In some embodiments, the photovoltaic module comprises a plurality of photovoltaic cells 18. In some embodiments, a plurality of photovoltaic cells 18 are arranged in a three-dimensional format, wherein a plurality of non-coplanar photovoltaic cells 18 are vertically stacked on top of one another at a distance interval.

In some embodiments, the photovoltaic module comprises a plurality of photovoltaic cells 18, selected from a group consisting of inorganic materials, organic materials, and a combination thereof. In some embodiments, the photovoltaic module comprises a plurality of bifacial photovoltaic cells 18 configured to convert direct and reflected light. In some embodiments, the photovoltaic module comprises a plurality of reflective layers 28. In some embodiments, the photovoltaic module comprises a plurality of light diffusive layers. In some embodiments, the photovoltaic module is a printed layer. In some embodiments, photovoltaic cell 18 refers to a layer of electromagnetic energy converting or photovoltaic material configured to convert light to electric current. In some embodiments, photovoltaic cell 18 refers to a discrete layer of photovoltaic material. In some embodiments, photovoltaic cell 18 refers to a surface within which at least one photovoltaic material is deposited. In some embodiments, the photovoltaic module is an origami photovoltaic layer.

In some embodiments, the electric management module comprises an electric component. In some embodiments, electric component comprises a converter, such as maximum power point tracking unit or micro-inverter, pulse width modulation system, electric current surge protector, battery management system, a switch, a diode, or combinations thereof. In some embodiments, the electric management module comprises a power storage unit, such as an electrochemical cell, electro-thermal cell, electro-mechanical cell, solid-state cell, or supercapacitor.

In some embodiments, the electric management module comprises a configurable controller unit, such as a central processing unit (CPU). In some embodiments, the configurable controller unit comprises analog and/or digital input and output gates. In some embodiments, the electric management module is programmable.

In some embodiments, the electric management module manages flow of current between at least two of the photovoltaic module, the power storage unit, and electric device. In some embodiments, the electric management module changes flow of the electric current to at least one of power storage unit and an electric device, based on a characteristic of the electric current of the photovoltaic module.

In some embodiments, the electric management module comprises a configurable micro-controller unit to which one or a plurality of electric components are connected. In some embodiments, the electric management module comprises a sensor, wherein the electric management module comprises an electric component, namely a sensor generating a signal, wherein the electric management module changes flow of the electric current to an electric device based on the signal from the sensor. In some embodiments, the sensor is selected from a list of an active sensor, a passive sensor, a contact sensor, and a non-contact sensor. In some embodiments, the sensor is selected from a list of an optical sensor, a mechanical sensor, a chemical sensor, a magnetic sensor, a thermal sensor, an electric sensor, and a physical sensor.

In some embodiments, the electric management module comprises an electric component, namely a communication unit. In some embodiments, the communication unit can receive and/or send information. In some embodiments, the information communicated via the communication unit comprises at least one of data, media, text message, signal, and voice message. In some embodiments, the communication unit communicates with a server. In some embodiments, a server coordinates operation(s) of one or a plurality of modular electromagnetic energy converter 14. In some embodiments, an operator in the loop, such as a utility point of contact, coordinates operation(s) of one or a plurality of modular electromagnetic energy converter 14.

In some embodiments, a modular electromagnetic energy converter 14 comprises an optoelectronic module having a photovoltaic module arranged within a pole having a transparent window 26. In this embodiment, the photovoltaic module comprises a plurality of non-coplanar photovoltaic cells 18 all oriented at an angle 45 degrees to horizon. In this embodiment, the angle was determined based on the average solar radiation at Ann Arbor, Mi. A comprehensive list of appropriate average solar angles for various geographical latitudes and time of year are provided by the National Renewable Energy Laboratory (NREL); accordingly, the photovoltaic module can comprise a plurality of non-coplanar photovoltaic cells 18 all oriented at an angle relative to horizon that is based on the appropriate average solar angles for the particular geographical latitude and time of year (or average thereof) provided by the National Renewable Energy Laboratory (NREL). In some embodiments, the plurality of non-coplanar photovoltaic cells 18 are attached to a support structure having discrete slots. The attachment can be achieved using 3D-printed holders, also defined as a locking mechanism. In some embodiments, the distance between adjacent photovoltaic cells 18 can be shorter than the width of the photovoltaic cells 18, allowing to pack more photovoltaic surfaces inside the transparent window 26 than an embodiment in which photovoltaic cells 18 are positioned vertically in a planar configuration.

In some embodiments, the transparent window 26 is configured by encasing a post inside a single-piece body of transparent material, such as a transparent tube. In some embodiments, the transparent window 26 is configured by encasing a body of transparent material within a post.

In some embodiments, the pole is a steel pole. The pole can comprise a transparent pole, herein referred to as a transparent window 26 with a 360-degree view of the surroundings, positioned atop the steel pole. In some embodiments, a transparent window 26 can comprise alternative configurations or less than 360-degree views. Temperature inside the pole can increase with increasing direct solar radiation. Therefore, the top and bottom of the steel pole can be open for air flow. The top of the transparent pole can be covered by a water-proof cap. The cap can enable air flow for temperature regulation.

In some embodiments, the photovoltaic module converts light to electric current via two groups of five photovoltaic cells 18 configured in series, allowing a desired output voltage. The two groups can be connected in parallel. In some embodiments, an additional photovoltaic cell 18 can be included (but not electrically connected to other photovoltaic cells 18) at the top of the photovoltaic module with the same physical characteristics (orientation and distance) to ensure that all the photovoltaic cells 18 have identical optoelectronic module optical cross section. This can enable uniform light input across all photovoltaic cells 18, hence avoiding mismatched electric current outputs.

In some embodiments, the modular electromagnetic energy converter 14 comprises an electric management module that is configured to manage flow of the electric current from the photovoltaic module to a power storage unit and an electric device. In some embodiments, the modular electromagnetic energy converter 14 comprises a maximum power tracking system having three electric terminals for photovoltaic input, power storage, and load. In some embodiments, the maximum power tracking system can send and receive information via Bluetooth, USB, and WiFi/LAN/Internet, enabling remote operation, monitoring, system configuration, and software updates. The maximum power tracking system can further directly connect, using a cable, to monitor and store system performance.

In some embodiments, the power storage unit is a lithium battery. The battery can be directly connected to the power storage plugs of the maximum power tracking system. In some embodiments, the electric device comprises alight emitting diode strip as well as a ground fault circuit interrupter (GFCI) plug having both direct (USB and USB-C) and alternating current outlets. The electric device can connect to the load plugs of the maximum power tracking system via an inverter to convert direct current (DC) to alternating current (AC). In some embodiments, the electric management module, power storage unit, and electric device can be disposed within the steel pole, and can be accessible via removable, water-proof windows.

In some embodiments, the modular electromagnetic energy converter 14 further comprises a support module to affix at least the optoelectronic module to a base. In some embodiments, the support module is a steel plate welded to the steel pole. The modular electromagnetic energy converter 14 can be installed on a concrete floor by drilling four 0.5-inch holes matching those of the steel plate and using four bolts to hold the system in place.

In some embodiments, the electric device is an equipment that utilizes electromagnetic force. In some embodiments, electric device is selected from a group consisting of an electromagnetic system, an electroluminescent system, an electrothermal system, an electromechanical system, and an electrochemical system.

In some embodiments, the pole is configured in a vertical arrangement. In some embodiments, the pole is configured in a columnar structure. In some embodiments, the pole is at least partially transparent. In some embodiments, the pole is at least partially reflective 28. In some embodiments, the pole is at least partially absorptive. In some embodiments, the pole is partitioned into transparent and non-transparent parts. The transparent part, referred to herein as the transparent window 26, has a numerical aperture greater than zero. The photovoltaic module receives light transmitting through the transparent window 26. In some embodiments, the transparent window 26 extends beyond the pole to collect more light. In some embodiments, the transparent window 26 is an optic, such as a cylindrical lens, curved polymer slab, or prismatic glass, configured to guide light. In some embodiments, the transparent window 26 is configured to capture reflected light. In some embodiments, the pole is equipped with excess material for improved structural integrity.

The numerical aperture (NA) of an optical system is a dimensionless number that characterizes the range of angles over which the system can accept or emit light. The numerical aperture of an optical system such as a convex lens is defined by NA=n sin(θ), where n is the index of refraction of the medium in which the optical system is working and θ is the maximal half-angle of the cone of light that can enter or exit the lens.

In some embodiments, the electric management module comprises an electric component shared between a plurality of optoelectronic modules. In some embodiments, the plurality of optoelectronic modules is linked to an electric management module via an electrical conduit, such as a cable.

In some embodiments, the modular electromagnetic energy converter 14 comprises a single or a plurality of auxiliary electricity generators. In some embodiments, the auxiliary electricity generator is selected from a group consisting of a wind turbine, a solar panel, a thermophotovoltaic system, a thermoelectric generator, a piezoelectric generator, and a fossil fuel backup generator.

In some embodiments, the modular electromagnetic energy converter 14 comprises a support module to affix the system to an electric utility pole. In some embodiments, the electric current generated by the modular electromagnetic energy converter 14 is deposited onto a community-wide electric grid or a microgrid to deliver power to an electric device or a power bank. In some embodiments, the electric management module comprises an inverter to convert direct electric current (DC) from the photovoltaic module into alternating electric current (AC). In some embodiments, the modular electromagnetic energy converter 14 is utilized as a node in an electric grid. In some embodiments, the modular electromagnetic energy converter 14 is utilized as an electric utility pole with power generation and storage capabilities. The modular electromagnetic energy converter 14 serving as an electric utility pole provides power resilience to a localized microgrid, especially during power oscillations, such as power outages during natural disasters. In some embodiments, the modular electromagnetic energy converter 14 further comprises a communication module. In some embodiments, a server, such as a utility operator, monitors, configures, and operates the modular electromagnetic energy converter 14.

In some embodiments, the modular electromagnetic energy converter 14 comprises an electric device that is embedded within the pole. In some embodiments, the electric device is a string of light emitting diodes (LEDs). In some embodiments, embedding the electric device within the pole provides a compact packaging of photovoltaic module and electronics.

In some embodiments, the pole with a transparent window 26 has a numerical aperture NA=1, that is 360-degree optical cross section. A pole with NA=1 is also referred to as a ‘transparent pole’ 26.

In some embodiments, the modular electromagnetic energy converter 14 integrates the photovoltaic module within the pole in a way that is cost efficient and reduces maintenance. Specifically, photovoltaic cells 18 of photovoltaic module are deployed within the pole with the transparent window 26 that provides an enclosure for electric devices, such as lights and Internet-of-Things (IoT) sub-systems, as well as the packaging for the photovoltaic cells 18. In some embodiments, the modular electromagnetic energy converter 14 delivers at least one of several advantages over conventional systems:
a. Cost savings:
   i. Manufacturing: a) the heavy and costly glass, back-sheet, and frame of the solar panel are eliminated, b) our columnar design avoids wind load management costs to support a solar panel and battery attached to a pole, and c) modules can be mass-manufactured and affordably assembled.
   ii. Module performance: a) photovoltaic cell 18 efficiency does not degrade under intense sunlight (at 0.4% per degree Celsius) as convective heat transfer dampens the temperature rise in the columnar structure, b) the transparent pole 26 provides latent solar tracking to improve the daily power output of optoelectronic module, and c) photovoltaic cells 18 are homogeneously illuminated resulting in improved power output and enhancing the operational life expectancy of photovoltaic cells 18.
   iii. Maintenance: transparent pole 26 serves as a protective surface that, being vertical, sheds dirt and snow more readily than a solar panel deployed at an angle. Transparent pole 26 further protects the photovoltaic cells 18 and electronics from moisture.
b. Improved reliability: the number of optoelectronic modules can be increased and/or additional modular, photovoltaic utility pole system 100 can be installed and linked to improve total power output and increase power margins, compared to mounting more solar panels on a pole.
c. Improved mobility and versatility: the modular architecture allows for i) easy transportation, and ii) plug and play installations.

In some embodiments, installation instructions are provided for the modular electromagnetic energy converter 14. In some embodiments, the instructions are in the form of a compass. In some embodiments, the support module affixes the optoelectronic module according to at least one of solar noon, shading from surrounding objects, reflectivity from surrounding objects, aesthetic, traffic, and safety. In some embodiments, the support module faces a pre-determined direction. In some embodiments, the direction is determined based on shading patterns. In some embodiments, the ‘transparent pole’ 26 is coated with materials to prevent dirt or snow buildup and avoid partial shading.

Solar noon is the moment when the Sun passes a location's meridian and reaches its highest position in the sky. In most cases, it does not happen at 12 o'clock. A meridian is an imaginary line connecting the North and South Poles along the Earth's surface. It connects all locations that share the same longitude. The line is also referred to as local meridian.

Solar noon happens at a geographical location when the Earth's rotation brings the location's local meridian to the side of the planet that faces the Sun. At Solar Noon, the Sun reaches its highest position in the sky. Since solar time depends on the longitude, solar noon occurs at exactly the same moment in all locations that share the same local meridian. The exact instant of solar noon, when the Sun reaches its highest point in the sky, varies with the seasons. This variation is called the equation of time; the magnitude of variation is about 30 minutes over the course of a year.

In some embodiments the modular electromagnetic energy converter 14, wherein the optoelectronic module is serviceable, comprises an attainable photovoltaic module having a locking mechanism configured to affix the photovoltaic module and a set of attainable terminals. In some embodiments, the photovoltaic module comprises a racking system to affix individual photovoltaic cells 18. In some embodiments, the locking mechanism comprises a holder, such as a receptacle, capable of sliding along a support railing system, i.e., continuous translation. In some embodiments, the locking mechanism comprises a holder to lock a photovoltaic cell 18 into a pre-determined slot. In some embodiments, the slot locations are determined based on a dimension of the photovoltaic cell 18. In some embodiments, the transparent window 26 is removable. In some embodiments, the optoelectronic module is removable. In some embodiments, the optoelectronic module is at least partially replaceable. In some embodiments, the transparent window 26 is sealed after a service is completed. In some embodiments, the optoelectronic module is depressurized after a service is completed. In some embodiments, the photovoltaic module comprises a reflective rear surface 28 whereon photovoltaic cells 18 are mounted.

In some embodiments, the photovoltaic module is encased in a sealed enclosure. In some embodiments, the sealed enclosure is a transparent column 26. In some embodiments, the sealed enclosure is a polymeric slab, such as resin, silicone, or gel. In some embodiments, the photovoltaic cells 18 encased within the sealed enclosure are attainable. In some embodiments, the photovoltaic cells 18 encased within the sealed enclosure can slide in and out of a polymeric mold. In some embodiments, the sealed enclosure has a pre-determined chemical composition, such as pressurized with inert gas. In such embodiments, the sealed enclosure contains materials, such as decanter to remove moisture, to regulate chemical composition. In some embodiments, the photovoltaic cells 18 encased within the sealed enclosure is placed into a pole. In some embodiments, the optoelectronic module comprises photovoltaic cells 18 encased within the sealed enclosure.

In some embodiments, the modular electromagnetic energy converter 14 is equipped with a temperature regulation mechanism or heat transfer system 31. In some embodiments, the temperature regulation mechanism comprises a vent. In some embodiments, the temperature regulation mechanism creates heat convection to regulate the temperature inside the optoelectronic module. In some embodiments, the temperature regulation mechanism is part of an air circulation mechanism. In some embodiments, the air circulation mechanism comprises a fan. In some embodiments, the temperature regulation mechanism comprises a phase change material (PCM), such as wax and fat. In some embodiments, the PCM is selected based on a desired temperature. In some embodiments, the temperature regulation mechanism comprises an active temperature regulation system, which, in some embodiments, comprises an electric pump. In some embodiments, the temperature regulation mechanism comprises a coolant circulation mechanism. In some embodiments, the temperature regulation mechanism comprises a material that also serves as alight guide. In some embodiments, the temperature regulation mechanism comprises a thermal capture mechanism, therefore harvesting thermal energy, also referred to as ‘thermo-photovoltaic’ mechanism.

In some embodiments, the modular electromagnetic energy converter 14 is adjustable. In some embodiments, at least one photovoltaic cell 18 of the optoelectronic module is adjustable. In some embodiments, the photovoltaic cell 18 has at least one of translational and rotational degrees of freedom. In some embodiments, the pole of the modular electromagnetic energy converter 14 is adjustable. In some embodiments, the pole has at least one of translational and rotational degrees of freedom. In some embodiments, the support module of the modular electromagnetic energy converter 14 is adjustable. In some embodiments, the support module has at least one of translational and rotational degrees of freedom.

In some embodiments, at least one of a plurality of modular electromagnetic energy converters 14, a ‘solar forest,’ move to optimize collective power output. In some embodiments, a plurality of modular electromagnetic energy converters 14 are affixed to a base, such as a railing system. In some embodiments, a plurality of modular electromagnetic energy converters 14 are affixed by one support module. In some embodiments, the one support module is adjustable. In some embodiments, the one adjustable support module has at least one translation and rotational degrees of freedom. In some embodiments, the one adjustable support module moves to optimize collective power output. In some embodiments, the base is reflective 28, such as white-painted floor.

In some embodiments, the modular electromagnetic energy converter 14 tracks the Sun in the sky. In some embodiments, the solar tracking is manual. In some embodiments, the solar tracking is automatic. In some embodiments, the solar tracking is powered electro-mechanically. In some embodiments, the solar tracking is done using a thermo-mechanical actuator. In some embodiments, a plurality of photovoltaic cells 18 of the optoelectronic module are adjusted as a group. In some embodiments, each of the plurality of photovoltaic cells 18 of the optoelectronic module is adjusted individually.

In some embodiments, a reflective surface 28, such as a mirror, is arranged vertically along the outer surface of the pole of the optoelectronic module. In some embodiments, the reflective surface 28 is arranged vertically within the pole of the optoelectronic module. In some embodiments, the reflective surface 28 affixes the photovoltaic cells 18. In some embodiments, the reflective surface 28 is adjustable, having at least one of translational and rotational degrees of freedom. In some embodiments, the photovoltaic cells 18 of the optoelectronic module are affixed to the reflective surface 28. In some embodiments, the reflective surface 28 diffuses light. In some embodiments, the reflective surface 28 reflects at least partially. In some embodiments, the reflective surface 28 is configured to converge light. In some embodiments, the reflective surface 28 is configured to diverge light. In some embodiments, only part of the reflective surface 28 is configured to concentrate light. In some embodiments, the reflective surface 28 comprises one or more adjustable discrete reflective surfaces 28.

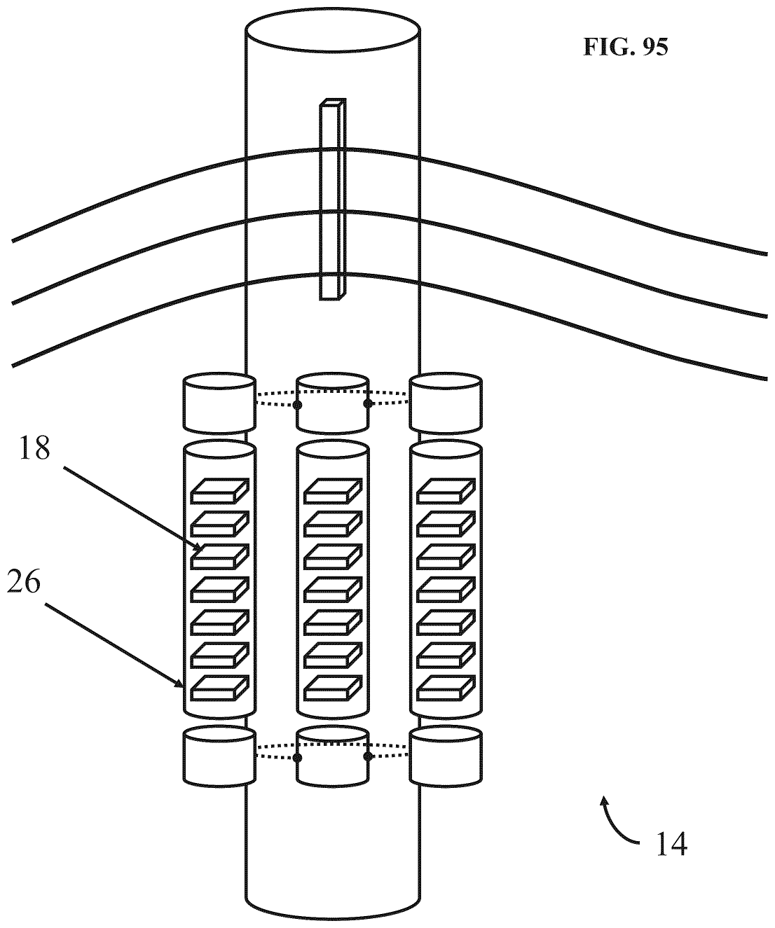

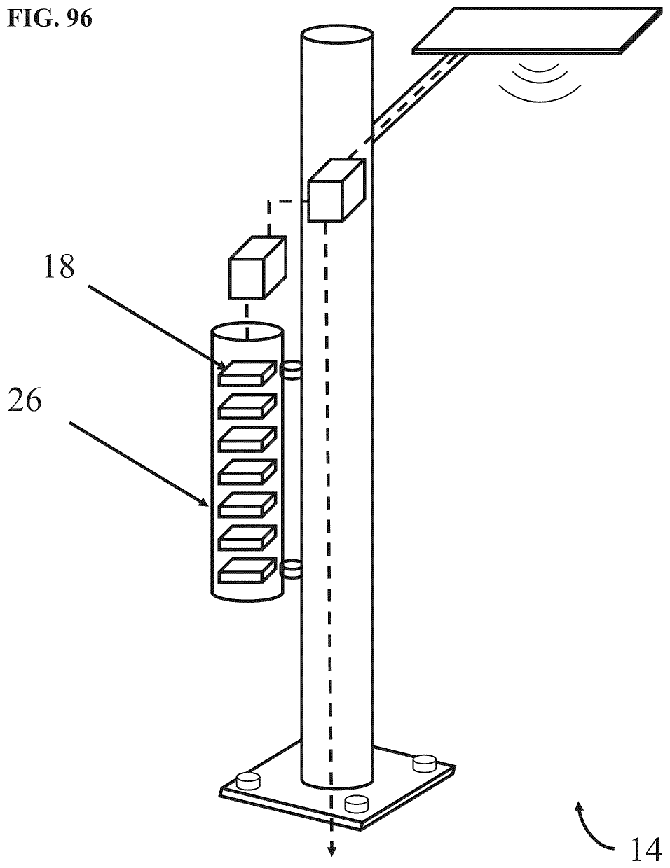

In reference to FIGS. 95, in some embodiments, the modular electromagnetic energy converter 14 is retrofitted to an existing platform as a primary source of electricity. In reference to FIGS. 96, in some embodiments, the modular electromagnetic energy converter 14 is retrofitted to an existing platform as an auxiliary source of electricity, often referred to as a ‘hybrid’ platform. In some embodiments, the existing platform is a light pole, utility pole, a wall, or a traffic signage. In some embodiments, the modular electromagnetic energy converter 14 wraps around the body of an existing platform, commonly referred to as a ‘sleeve.’

In some embodiments, a modular electromagnetic energy converter 14 comprises an optoelectronic module comprising a photovoltaic module arranged within a pole having a transparent window 26 was constructed. In some embodiments, the photovoltaic module comprises a plurality of non-coplanar photovoltaic cells 18 all oriented at an angle. In some embodiments, the angle is determined based on the inner diameter of the pole. In some embodiments, the support module affixes the optoelectronic module according to at least one of solar noon, shading from surrounding objects, reflectivity from surrounding objects, aesthetic, traffic, and safety.

In some embodiments, the plurality of non-coplanar photovoltaic cells 18 are attached to a 3D-printed support structure having discrete mounting slots. In this embodiment, the distance between adjacent photovoltaic cells 18 was shorter than the width of the photovoltaic cells 18, allowing to pack more photovoltaic surfaces inside the transparent window 26 than an embodiment in which photovoltaic cells 18 are positioned vertically in a planar configuration.

In some embodiments, the pole comprises an aluminum back plate and a transparent window 26, a transparent window 26 with a 180-degree view of the surroundings, that is NA=0.5. The top and bottom of the pole can be capped. The aluminum back plate can have a semi-circle cross section with fins, serving both as a light reflector, a reflective surface 28, as well as a heat transfer system 31 or heat sink.

In some embodiments, the photovoltaic module converting light to electric current is arranged in three groups of three photovoltaic cells 18 configured in series, allowing a desired output voltage. The three groups were then connected in parallel. In this embodiment, an additional photovoltaic cell 18 is included (but not electrically connected to other photovoltaic cells 18) at the top of the photovoltaic module with the same physical characteristics (orientation and distance) to ensure that all of the photovoltaic cells 18 had identical optoelectronic module optical cross section. This allows for uniform light input across all photovoltaic cells 18, hence avoiding mismatched electric current outputs.

In some embodiments, the modular electromagnetic energy converter 14 further comprises an electric management module, comprising a diode, positioned within the bottom cap, that is configured to manage flow of the electric current from the photovoltaic module to a power storage unit, a battery pack of eight AA Nickel metal hydride rechargeable batteries. In some embodiments, the electric management module further comprises a configurable and programmable microcontroller. The microcontroller connects the battery pack to an electric device, a light emitting diode (LED).

In some embodiments, the electric management module further comprises a sensor generating a signal, wherein the electric management module changes flow of the electric current to an electric device based on the signal from the sensor. In some embodiments, the electric management module further comprises a motion detection sensor. The micro-controller can be programmed to provide small average (root-mean squared (RMS)) current to the LED when no motion was detected, hence ‘dim’ illumination. The illumination brightness can be controlled using a pulsed width modulation (PWM) technique. The LED became ‘bright’ for a pre-determined duration as soon as motion was detected. This configuration allows electricity conservation, and therefore, increases reliability.

In some embodiments, the electric management module enables the flow of current to an electric device when solar radiation falls under a threshold brightness, resulting in reduced output voltage of the photovoltaic module. In some embodiments, the flow of electric current to an electric device is shut off when solar radiation reaches a threshold brightness, resulting in the output voltage of the photovoltaic module 104 reaching a pre-determined value. In some embodiments, this is referred to as the ‘dusk-to-dawn’ operation.

In some embodiments, the electric management module, power storage unit, and electric device is stored inside the top and bottom caps, accessible through removable, water-proof windows.

In some embodiments, a modular electromagnetic energy converter 14 further comprises a support module to affix at least the optoelectronic module to a base. In some embodiments, the support module is a mounting pad that is installed on a wall using two screws. The optoelectronic module is then slid over the pad and the height is adjusted for optimal configuration.

In some embodiments, the modular electromagnetic energy converter 14 provides electricity to an electro-chemical plant, such as a carbon capture system, an electro-thermal energy storage plant, a water desalination plant, or a water collection system. In some embodiments, the modular electromagnetic energy converter 14 provides electricity for ‘vertical farming’ sub-systems. In some embodiments, the modular electromagnetic energy converter 14 further provides housing for ‘vertical farming’ sub-systems.

In some embodiments, the modular electromagnetic energy converter 14 is configured to provide electricity for electric operations, such as an electric fence, a motion-sensitive fence, a surveillance fence, or a geofence.

In some embodiments, the modular electromagnetic energy converter 14 is utilized to provide electricity to a charging platform. In some embodiments, the charging platform delivers electricity with or without a cable (wireless, such as via inductive charging platform). In some embodiments, the modular electromagnetic energy converter 14 provides charging to a micro-mobility platform, such as an electric scooter charging platform, smart bike locker platform, unmanned aerial vehicle charging platform, electric device charging platform, smart parking platform. In some embodiments, the modular electromagnetic energy converter 14 comprises communications sub-systems, such as a mesh network sub-systems, telecommunication sub-systems, cellular (such as 5G network) communication sub-systems, wireless communication sub-systems, or internet access sub-systems (such as a hotspot).

In some embodiments, the modular electromagnetic energy converter 14 is configured to also provide natural light to an indoor space during the day. In some embodiments, the modular electromagnetic energy converter 14 converts sunlight to electricity for an electric device, such as indoor lighting.

In reference to FIGS. 84-86, in some embodiments, the modular electromagnetic energy converter 14 the optoelectronic module is positioned inside a lattice structure. In some embodiments, a lattice structure is utilized to affix the photovoltaic cells 18. In some embodiments, the pole is a lattice structure. In some embodiments, a lattice structure is utilized to provide structural strength to the optoelectronic module. In some embodiments, a lattice structure helps to reduce weight, therefore save on construction material costs. In some embodiments, a lattice structure offers flexible configuration with improved transportation and fabrication advantages. In some embodiments, a lattice structure significantly reduces wind load.

In some embodiments, the modular electromagnetic energy converter 14 is configured to be assembled on site. In some embodiments, at least one of the support module and optoelectronic module is designed with an interlocking mechanism amongst modules for easy assembly.

In some embodiments, at least one electric component of the electric management module is positioned inside the support module. In some embodiments, at least one electric component of the electric management module is positioned inside the base. In some embodiments, at least one electric component of the electric management module is positioned inside a pole concrete base to avoid theft. In some embodiments, at least one electric component of the electric management module is positioned underground for temperature regulation. In some embodiments, an electric component, such as a magnetometer sensor, is placed inside the pole or buried underground within the base to reduce electromagnetic noise.

In some embodiments, support module is selected from a group consisting of a mounting pole, a utility pole, a light pole, a post, a bracket, a concrete foundation, a bollard, an anchor, a frame, a mounting bracket, a clamp, a rail, a magnetic plate, a rope, a chain, a wire, a cable, an arm, a leg, a hook, a hanger, a strut, a mounting fastener, a wall mount, and a belt.

In some embodiments, the base is selected from a group consisting of a floor, a ground, a surface, a wall, a mounting pole, a utility pole, a light pole, a post, a bracket, a bucket, a container, a flowerpot, a structure, a bollard, an anchor, and a frame.

In some embodiments, the modular electromagnetic energy converter 14 is utilized as a node on a power distribution line. In some embodiments, a plurality of modular electromagnetic energy converters 14 are installed along a road to provide electricity for dynamic electric vehicle charging, lighting, etc. In some embodiments, installing a plurality of modular electromagnetic energy converters 14 along a road helps to avoid land acquisition requirements. In some embodiments, a plurality of modular electromagnetic energy converters 14 are part of a microgrid, configured to provide electricity to electric consumers throughout the day. In some embodiments, a plurality of modular electromagnetic energy converters 14 are utilized as a backup power generator during power outages. In some embodiments, a plurality of modular electromagnetic energy converters 14 are utilized to provide electricity to an off-grid operation, such as an electric vehicle charging station.

In some embodiments, a modular electromagnetic energy converter 14 does not include embodiments in which one or a plurality of photovoltaic cells 18 are arranged approximately vertically on at least one portion of peripheral wall of the pole, as described by Yoshida and Fujii (U.S. Pat. No. 6,060,658).

### Retrofit, Modular Electromagnetic Energy Converter:

In reference to FIGS. 95-96, in some embodiments, a retrofit, modular electromagnetic energy converter 14, comprises an at least partially insulating transparent column 26, a support module, and an optoelectronic module having a photovoltaic module, the photovoltaic module having a plurality of electromagnetic energy converting cells 18 arranged within the at least partially insulating transparent column 26, the photovoltaic module having an optical cross section, the at least partially insulating transparent column 26 configured to enlarge the optical cross section of the photovoltaic module, the optoelectronic module configured to be mounted to a utility pole via the support module.

In some embodiments, a retrofit, modular electromagnetic energy converter 14 further comprises a utility pole, the utility pole is connected to an electric grid. In some embodiments, the at least partially insulating transparent column has a numerical aperture greater than zero. In some embodiments, the at least partially insulating transparent column is selected from a group consisting of glass and polymer. In some embodiments, the at least partially insulating transparent column is configured to transmit a selective range of light wavelengths. In some embodiments, the photovoltaic module comprises a locking mechanism and a set of attainable terminals.

In some embodiments, the optoelectronic module further comprises a reflective surface 28. In some embodiments, the photovoltaic module is sealed within an enclosure. In some embodiments, a retrofit, modular electromagnetic energy converter 14 further comprises an electric management module. In some embodiments, the electric management module comprises an item selected from a group consisting of a central processing unit, a maximum power point tracking subsystem, a charge controller, a switch, a battery, a capacitor, a diode, a fuel cell, an auxiliary electricity generator, an inverter, a micro-inverter, a converter, a resistor, an inductor, and a transformer. In some embodiments, the electric management module is attached to an electric grid. In some embodiments, the optoelectronic module further comprises a heat transfer system 31 or climate control mechanism. In some embodiments, the optoelectronic module further comprises a light tracking mechanism. In some embodiments, a retrofit, modular electromagnetic energy converter 14 further comprises an electric device. In some embodiments, the electric device is on an electric grid.

In some embodiments, a retrofit, modular electromagnetic energy converter 14, wherein the photovoltaic module comprises a plurality of non-coplanar photovoltaic cells 18, each adjacent non-coplanar photovoltaic cells 18 having a non-zero distance therebetween. In some embodiments, each photovoltaic cell 18 of the plurality of non-coplanar photovoltaic cells 18 has a width, a length, and a thickness, wherein adjacent photovoltaic cells 18 having a non-zero distance therebetween, and wherein the non-zero distance between the photovoltaic cells 18 is equal or shorter than the width and the length of the non-coplanar photovoltaic cells 18.

In some embodiments, a retrofit, modular electromagnetic energy converter 14, wherein the support module further affixes an item selected from a group consisting of a signage, a traffic signage, a sensor, an arm, a mast, a staff, a chain, a cable, a bar, a tag, a barcode, a bird spike, an advertisement, a banner, a display, a decoration, an auxiliary electricity generator, and a charging platform.

In some embodiments, a retrofit, modular electromagnetic energy converter 14, wherein the support module affixes the optoelectronic module in response to at least one of solar noon, shading from surrounding objects, reflectivity from surrounding objects, aesthetics, traffic, and safety. In some embodiments, the support module movably affixes the optoelectronic module to the utility pole.

### Collapsible Electromagnetic Energy Converter:

In reference to FIGS. 84-86, and 97, in some embodiments, a collapsible electromagnetic energy converter 14, comprises an at least partially insulating, body of transparent material or transparent column 26, and an optoelectronic module configured to be expandable between a first volume and a second volume, the optoelectronic module having a photovoltaic module, the photovoltaic module having a plurality of photovoltaic cells 18 arranged within the at least partially insulating transparent column 26.

In some embodiments, the collapsible electromagnetic energy converter 14 further comprising a housing. In some embodiments, the transparent column has a numerical aperture greater than zero. In some embodiments, the transparent column 26 is selected from a group consisting of glass and polymer. In some embodiments, the transparent column 26 is configured to transmit a selective range of light wavelengths.

In some embodiments, the photovoltaic module of a collapsible electromagnetic energy converter 14 comprises a locking mechanism and a set of attainable terminals. In some embodiments, the optoelectronic module further comprises a reflective surface 28. In some embodiments, the photovoltaic module is sealed within an enclosure. In some embodiments, a collapsible electromagnetic energy converter 14 further comprises an electric management module. In some embodiments, the electric management module comprises an item selected from a group consisting of a central processing unit, a maximum power point tracking subsystem, a charge controller, a switch, a battery, a capacitor, a diode, a fuel cell, an auxiliary electricity generator, an inverter, a micro-inverter, a converter, a resistor, an inductor, and a transformer. In some embodiments, the electric management module is attached to an electric grid.

In some embodiments, the optoelectronic module of a collapsible electromagnetic energy converter 14 further comprises a heat transfer system 31 or climate control mechanism. In some embodiments, the optoelectronic module further comprises alight tracking mechanism. In some embodiments, a collapsible electromagnetic energy converter 14 further comprises an electric device. In some embodiments, the photovoltaic module of a collapsible electromagnetic energy converter 14 further comprises a support mechanism. In some embodiments, the photovoltaic module comprises a plurality of non-coplanar photovoltaic cells 18, each adjacent non-coplanar photovoltaic cells 18 having non-zero distance therebetween. In some embodiments, each photovoltaic cell 18 of the plurality of non-coplanar photovoltaic cells 18 has a width, a length, and a thickness, wherein adjacent photovoltaic cells 18 has a non-zero distance therebetween, and wherein the non-zero distance between the photovoltaic cells 18 is equal or shorter than the width and the length of the non-coplanar photovoltaic cells 18.

In reference to FIG. 84, in some embodiments, a collapsible electromagnetic energy converter 14 further comprises a housing, such as a canister inside which the optoelectronic module collapses. In some embodiments, the housing has a lid, or a shutter mechanism. In some embodiments, the canister further comprises an expansion-contraction mechanism, such as a fan, motor, inflator, or a hydraulic lift. In some embodiments, the housing further comprises an electric component, such as a control unit. In some embodiments, the housing comprises an electric management module. In some embodiments, the housing further comprises a power storage unit. In some embodiments, the housing comprises an active solar tracking mechanism, such as a motor. In some embodiments, the expansion-contraction mechanism is used to actively track the Sun. In some embodiments, the housing is water floatable. In some embodiments, only one of the body of insulating transparent material 26 and the plurality of electromagnetic energy converting cells 18 is collapsible. In some embodiments, the optoelectronic module comprises a telescopic extension mechanism. In some embodiments, external power is required to expand the optoelectronic module. In some embodiments, electro-chemical or electro-mechanical mechanisms are utilized to compress or expand a collapsible electromagnetic energy converter 14. In some embodiments, passive mechanisms, such as gravity, magnetism, compressed air, fluid pressure, loaded spring, thermal shape memory, or other forms of storage and release of potential energy are utilized to increase or decrease light collection area of a collapsible electromagnetic energy converter 14.

In some embodiments, a collapsible electromagnetic energy converter 14 comprises an inflatable body of insulating transparent material 26. In some embodiments, the body of insulating transparent material is foldable, spring-loaded, telescopic, or helical. In some embodiments, spacing between the plurality of electromagnetic energy converting cells 18 can be reduced to store a collapsible electromagnetic energy converter 14 in a housing. In some embodiments, the compression or expansion of a collapsible electromagnetic energy converter 14 requires electric energy.

In some embodiments, the support module of a collapsible electromagnetic energy converter 14 further affixes an item selected from a group consisting of a signage, a traffic signage, a sensor, an arm, a mast, a staff, a chain, a cable, a bar, a tag, a barcode, a bird spike, an advertisement, a banner, a display, a decoration, an auxiliary electricity generator, and a charging platform. In some embodiments, the support module affixes the optoelectronic module in response to at least one of solar noon, shading from surrounding objects, reflectivity from surrounding objects, aesthetics, traffic, and safety. In some embodiments, the support module movably affixes the optoelectronic module to base.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method for optimizing converting electromagnetic energy to electricity of an electromagnetic energy converter, the method comprising:
providing an electromagnetic energy converter having a body of transparent insulating material, a plurality of stacked identical electromagnetic energy converting cells, and a heat transfer system, the electromagnetic energy converter defining an electromagnetic energy collection area of the body of transparent insulating material, an orientation of the body of transparent insulating material relative to an incoming electromagnetic energy, an angle between each adjacent electromagnetic energy converting cell of the plurality of stacked identical electromagnetic energy converting cells, an angle between the plurality of stacked identical electromagnetic energy converting cells relative to the incoming electromagnetic energy, and a spacing between each adjacent electromagnetic energy converting cell of the plurality of stacked identical electromagnetic energy converting cells; and
adjusting the electromagnetic energy converter from a first configuration to a second configuration.

2. The method for optimizing converting electromagnetic energy to electricity of an electromagnetic energy converter according to claim 1, further comprising receiving input electromagnetic energy as solar radiation.

3. The method for optimizing converting electromagnetic energy to electricity of an electromagnetic energy converter according to claim 1, wherein the providing an electromagnetic energy converter comprises providing an electromagnetic energy converter further having a solar tracking system, the solar tracking system having electrical drives and mechanical gear trains,
wherein the adjusting the electromagnetic energy converter from the first configuration to the second configuration comprises adjusting the electromagnetic energy converter from the first configuration to the second configuration using the solar tracking system.

4. The method for optimizing converting electromagnetic energy to electricity of an electromagnetic energy converter according to claim 1, the method further comprising determining electromagnetic energy input of the electromagnetic energy converter.

5. The method for optimizing converting electromagnetic energy to electricity of an electromagnetic energy converter according to claim 4, wherein the determining electromagnetic energy input of the electromagnetic energy converter comprises determining electromagnetic energy input of the electromagnetic energy converter using reference data.

6. The method for optimizing converting electromagnetic energy to electricity of an electromagnetic energy converter according to claim 4, wherein the determining electromagnetic energy input of the electromagnetic energy converter comprises determining electromagnetic energy input of the electromagnetic energy converter using measurement.

7. The method for optimizing converting electromagnetic energy to electricity of an electromagnetic energy converter according to claim 1, the method further comprising determining maximum power point of the electrical output of the electromagnetic energy converter.

8. The method for optimizing converting electromagnetic energy to electricity of an electromagnetic energy converter according to claim 1, the method further comprising measuring electrical output of the electromagnetic energy converter after the step of adjusting the electromagnetic energy converter from the first configuration to the second configuration.

9. The method for optimizing converting electromagnetic energy to electricity of an electromagnetic energy converter according to claim 8, the method further comprising measuring electrical output of a first configuration of the electromagnetic energy converter; and
comparing the measured electrical output of the electromagnetic energy converter with the measured electrical output after the step of adjusting the electromagnetic energy converter from the first configuration to the second configuration.

10. The method for optimizing converting electromagnetic energy to electricity of an electromagnetic energy converter according to claim 1, wherein the providing an electromagnetic energy converter comprises providing the electromagnetic energy converter further having a layer selected from the group consisting of conductive, dielectric, luminescent, transmissive, absorptive, diffusive, refractive, and dispersive materials, or a combination thereof, the electromagnetic energy converter further defining an angle between an electromagnetic energy converting cell of the plurality of electromagnetic energy converting cells and the layer, an angle between the layer and an incoming electromagnetic energy, and a spacing between an electromagnetic energy converting cell of the plurality of electromagnetic energy converting cells and the layer; and
adjusting the electromagnetic energy converter from a first configuration to a second configuration.

11. The method for optimizing converting electromagnetic energy to electricity of an electromagnetic energy converter according to claim 1, the method further comprising recording at least one of electromagnetic energy input, electrical output, environmental conditions, and configuration characteristics of the electromagnetic energy converter.

12. The method for optimizing converting electromagnetic energy to electricity of an electromagnetic energy converter according to claim 1, wherein the adjusting the electromagnetic energy converter from the first configuration to the second configuration is based on environmental conditions, the environmental conditions selected from a group of wind speed, wind direction, cloud coverage, shading, shadowing, glare, surface reflectivity, temperature, debris, and precipitation.

13. The method for optimizing converting electromagnetic energy to electricity of an electromagnetic energy converter according to claim 1, the method further comprising adjusting the heat transfer system from a first configuration to a second configuration.

14. The method for optimizing converting electromagnetic energy to electricity of an electromagnetic energy converter according to claim 1, wherein the providing an electromagnetic energy converter comprises providing the electromagnetic energy converter having a sensor selected to detect a physical parameter impacting electrical output of the electromagnetic energy converter; and measuring output of the sensor.

15. The method for optimizing converting electromagnetic energy to electricity of an electromagnetic energy converter according to claim 1, wherein providing an electromagnetic energy converter comprises providing the electromagnetic energy converter having a communication system configured to communicate output of the electromagnetic energy converter; and
communicating at least one of electromagnetic energy input, electrical output, environmental conditions, and configuration characteristics of the electromagnetic energy converter using the communication system.

16. A method for determining a configuration to which to adjust an electromagnetic energy converter, the method comprising:
providing an electromagnetic energy converter having a body of transparent insulating material, a plurality of stacked identical electromagnetic energy converting cells, and a heat transfer system;
determining electrical output of a first configuration of the electromagnetic energy converter;
determining electrical output of a second configuration of the electromagnetic energy converter;
comparing the electrical output of the first configuration of the electromagnetic energy converter and the electrical output of the second configuration of the electromagnetic energy converter;
determining whether to adjust the electromagnetic energy converter from the first configuration to the second configuration and outputting a control signal.

17. The method for determining a configuration to which to adjust an electromagnetic energy converter of claim 16, the method further comprising adjusting the electromagnetic energy converter in response to the control signal.

18. The method for determining a configuration to which to adjust an electromagnetic energy converter of claim 16, wherein the determining electrical output of at least one of the first configuration and the second configuration of the electromagnetic energy converter is determined using reference data.

19. The method for determining a configuration to which to adjust an electromagnetic energy converter of claim 16, wherein the determining electrical output of the second configuration of the electromagnetic energy converter is determined by the adjusting the electromagnetic energy converter from a first configuration to the second configuration; and
measuring the electrical output of the second configuration of the electromagnetic energy converter.

20. The method for determining a configuration to which to adjust an electromagnetic energy converter of claim 16, the method further comprising determining electromagnetic energy input of the electromagnetic energy converter.
